(19) United States
(12) Patent Application Publication
(10) Pub. No.: US 2026/0013352 A1
(43) Pub. Date: Jan. 8, 2026

(54) DISPLAY DEVICE AND ELECTRONIC DEVICE INCLUDING THE SAME

(71) Applicant: Samsung Display Co., Ltd., Yongin-si (KR)

(72) Inventors: CHUNG SOCK CHOI, Yongin-si (KR); YOOMIN KO, Yongin-si (KR); SUNHO KIM, Yongin-si (KR); Hyewon Kim, Yongin-si (KR); JUCHAN PARK, Yongin-si (KR); Yerim Son, Yongin-si (KR); PILSUK LEE, Yongin-si (KR); SUNGJIN HONG, Yongin-si (KR)

(21) Appl. No.: 19/257,924

(22) Filed: Jul. 2, 2025

(30) Foreign Application Priority Data
Jul. 4, 2024 (KR) 10-2024-0088425

(51) Int. Cl. H10K 59/131; H10K 59/122

(52) U.S. Cl. CPC H10K 59/131; H10K 59/122

(57) ABSTRACT

The present application relates to a display device and an electronic device including the same. The display device includes: a first light-emitting element in a first light-emitting area on a substrate, a second light-emitting element in a second light-emitting area on the substrate, a first power voltage line to apply a first power voltage to the second electrode of the first light-emitting element, and a second power voltage line to apply a second power voltage to the second electrode of the second light-emitting element. The first light-emitting element includes a first electrode, an intermediate layer on the first electrode and a second electrode on the intermediate layer. The second light-emitting area emits light of a different color from the first light-emitting area. The second light-emitting element includes a first electrode, an intermediate layer on the first electrode, and a second electrode on the intermediate layer.

### CROSS-REFERENCE TO RELATED APPLICATION

The present application claims priority to and benefits of Korean Patent Application No. 10-2024-0088425, filed on Jul. 4, 2024, in the Korean Intellectual Property Office, (the entire content of which is incorporated by reference herein.

### BACKGROUND

### 1. Field

The present disclosure relates to a display device and an electronic device including the same. More particularly, the present disclosure relates to a display device providing visual information and an electronic device including the same.

### 2. Description of the Related Art

A display device is a device that displays an image for providing visual information to a user. Among display devices, an organic light-emitting diode (OLED) display device has recently attracted attention.

The display device may include a plurality of pixels. Each of the plurality of pixels may include a pixel driving circuit portion and a light-emitting element. The light-emitting element may emit light with a selected luminance corresponding to a driving current provided from the pixel driving circuit portion.

### SUMMARY

Embodiments of the present disclosure provide a display device with improved power consumption.

Embodiments of the present disclosure provide an electronic device including the display device.

A display device according to one or more embodiments includes a first light-emitting area and a second light-emitting area spaced from the first light-emitting area in a plan view and includes a substrate, a first light-emitting element located in the first light-emitting area on the substrate, a second light-emitting element located in the second light-emitting area on the substrate, a first power voltage line configured to apply a first power voltage to the second electrode of the first light-emitting element, and a second power voltage line configured to apply a second power voltage to the second electrode of the second light-emitting element.

In one or more embodiments, the first light-emitting element may include a first electrode, an intermediate layer located on the first electrode of the first light-emitting element, and a second electrode located on the intermediate layer of the first light-emitting element.

In one or more embodiments, the second light-emitting area may be configured to emit light of a different color from the first light-emitting area.

In one or more embodiments, the second light-emitting element may include a first electrode, an intermediate layer located on the first electrode of the second light-emitting element, and a second electrode located on the intermediate layer of the second light-emitting element.

In one or more embodiments, the second power voltage line may be spaced from the first power voltage line in a plan view.

In one or more embodiments, a voltage level of the first power voltage and a voltage level of the second power voltage may be different from each other.

In one or more embodiments, the display device may further include a connection pattern spaced from the first light-emitting area in a plan view.

In one or more embodiments, the second electrode of the first light-emitting element may be electrically connected to the first power voltage line through the connection pattern.

In one or more embodiments, the connection pattern may be around at least a portion of the first light-emitting area in a plan view.

In one or more embodiments, the display device may further include a third light-emitting area spaced from each of the first light-emitting area and the second light-emitting area in a plan view and configured to emit light of a different color from each of the first light-emitting area and the second light-emitting area.

In one or more embodiments, the display device may further include a third light-emitting element located in the third light-emitting area on the substrate and including a first electrode, an intermediate layer located on the first electrode of the third light-emitting element, and a second electrode located on the intermediate layer of the third light-emitting element.

In one or more embodiments, the first power voltage line may be configured to apply the first power voltage to the second electrode of the third light-emitting element.

In one or more embodiments, the display device may further include a third power voltage line configured to apply a third power voltage to the second electrode of the third light-emitting element and is spaced from each of the first power voltage line and the second power voltage line in a plan view.

In one or more embodiments, a voltage level of the first power voltage and a voltage level of the second power voltage may be different from each other.

In one or more embodiments, the voltage level of the second power voltage and a voltage level of the third power voltage may be different from each other.

In one or more embodiments, the display device may further include a separator separating the second electrode of the first light-emitting element and the second electrode of the second light-emitting element from each other.

In one or more embodiments, the separator may be around each of the second electrode of the first light-emitting element and the second electrode of the second light-emitting element in a plan view.

In one or more embodiments, the display device may further include a pixel defining layer located on the substrate and covering a side portion of the first electrode of the first light-emitting element.

In one or more embodiments, the pixel defining layer may define an opening that is spaced from the first light-emitting area in a plan view.

In one or more embodiments, the second electrode of the first light-emitting element and the second electrode of the second light-emitting element may be separated from each other by the opening of the pixel defining layer.

In one or more embodiments, in a cross-sectional view, the first power voltage line may include a first conductive layer, a second conductive layer located on the first conductive layer, and a third conductive layer located on the second conductive layer.

In one or more embodiments, the second electrode of the first light-emitting element may contact the second conductive layer.

A display device according to one or more embodiments includes a first light-emitting area and a second light-emitting area spaced from the first light-emitting area in a plan view and includes a substrate, a first light-emitting element located in the first light-emitting area on the substrate, a second light-emitting element located in the second light-emitting area on the substrate, a first power voltage line configured to apply a first power voltage to the first electrode of the first light-emitting element, and a second power voltage line configured to apply a second power voltage to the first electrode of the second light-emitting element.

In one or more embodiments, the first light-emitting element may include a first electrode, an intermediate layer located on the first electrode of the first light-emitting element, and a second electrode located on the intermediate layer of the first light-emitting element.

In one or more embodiments, the second light-emitting area may be configured to emit light of a different color from the first light-emitting area.

In one or more embodiments, the second light-emitting element may include a first electrode, an intermediate layer located on the first electrode of the second light-emitting element, and a second electrode located on the intermediate layer of the second light-emitting element.

In one or more embodiments, the second power voltage line may be spaced from the first power voltage line in a plan view.

In one or more embodiments, a voltage level of the first power voltage and a voltage level of the second power voltage may be different from each other.

In one or more embodiments, the display device may further include a third light-emitting area spaced from each of the first light-emitting area and the second light-emitting area in a plan view and configured to emit light of a different color from each of the first light-emitting area and the second light-emitting area.

In one or more embodiments, the display device may further include a third light-emitting element located in the third light-emitting area on the substrate and including a first electrode, an intermediate layer located on the first electrode of the third light-emitting element, and a second electrode located on the intermediate layer of the third light-emitting element and a third power voltage line configured to apply a third power voltage to the first electrode of the third light-emitting element and is spaced from each of the first power voltage line and the second power voltage line in a plan view.

In one or more embodiments, the display device may further include a transistor located on the substrate and electrically connected to the second electrode of the first light emitting element.

In one or more embodiments, a voltage level of the first power voltage and a voltage level of the second power voltage may be different from each other.

An electronic device according to one or more embodiments includes a first light-emitting area and a second light-emitting area spaced from the first light-emitting area in a plan view and includes a substrate, a first light-emitting element located in the first light-emitting area on the substrate, a second light-emitting element located in the second light-emitting area on the substrate, a first power voltage line configured to apply a first power voltage to the second electrode of the first light-emitting element, a second power voltage line configured to apply a second power voltage to the second electrode of the second light-emitting element, and a memory configured to store data information.

In one or more embodiments, the first light-emitting element may include a first electrode, an intermediate layer located on the first electrode of the first light-emitting element, and a second electrode located on the intermediate layer of the first light-emitting element.

In one or more embodiments, the second light-emitting area may be configured to emit light of a different color from the first light-emitting area.

In one or more embodiments, the second light-emitting element may include a first electrode, an intermediate layer located on the first electrode of the second light-emitting element, and a second electrode located on the intermediate layer of the second light-emitting element.

In one or more embodiments, the second power voltage line may be spaced from the first power voltage line in a plan view.

A display device according to one or more embodiments includes a first light-emitting area and a second light-emitting area spaced from the first light-emitting area in a plan view and includes a substrate, a first light-emitting element located in the first light-emitting area on the substrate, a second light-emitting element located in the second light-emitting area on the substrate, a first power voltage line configured to apply a first power voltage to the second electrode of the first light-emitting element, and a second power voltage line configured to apply a second power voltage to the second electrode of the second light-emitting element. The first light-emitting element may include a first electrode, an intermediate layer located on the first electrode of the first light-emitting element, and a second electrode located on the intermediate layer of the first light-emitting element. The second light-emitting area may be configured to emit light of a different color from the first light-emitting area. The second light-emitting element may include a first electrode, an intermediate layer located on the first electrode of the second light-emitting element, and a second electrode located on the intermediate layer of the second light-emitting element. The second power voltage line may be spaced from the first power voltage line in a plan view.

Accordingly, power voltages having different voltage levels from each other may be applied to a plurality of light-emitting elements, respectively. For example, the first power voltage and the second power voltage having different voltage levels from each other may be applied to the second electrode of the first light-emitting element and the second electrode of the second light-emitting element, respectively. For example, an optimized power voltage may be applied to each of the plurality of light-emitting elements. Therefore, power consumption of the display device may be improved.

### BRIEF DESCRIPTION OF THE DRAWINGS

Illustrative, non-limiting embodiments will be more clearly understood from the following detailed description in conjunction with the accompanying drawings.

FIG. 1A is a plan view illustrating a display device according to one or more embodiments.

FIG. 1B is a plan view illustrating a display device according to one or more embodiments.

FIG. 2A is a circuit diagram illustrating an example of a circuit structure of a pixel included in the display device of FIGS. 1A and 1B.

FIG. 2B is a circuit diagram illustrating another example of a circuit structure of a pixel included in the display device of FIGS. 1A and 1B.

FIG. 2C is a circuit diagram illustrating still another example of a circuit structure of a pixel included in the display device of FIGS. 1A and 1B.

FIGS. 3, 4, and 5 are plan views schematically illustrating an example of a partial area of the display device of FIGS. 1A and 1B.

FIG. 6 is an enlarged view illustrating one unit light-emitting area from among unit light-emitting areas of FIG. 5.

FIG. 7 is a cross-sectional view taken along the line I-I′ of FIG. 6.

FIG. 8 is a cross-sectional view illustrating a display device according to one or more embodiments.

FIG. 9 is a cross-sectional view illustrating a display device according to still another embodiment.

FIGS. 10, 11, and 12 are plan views schematically illustrating another example of a partial area of the display device of FIGS. 1A and 1B.

FIG. 13 is a schematic plan view illustrating still another example of a partial area of the display device of FIGS. 1A and 1B.

FIGS. 14, 15, 16, and 17 are plan views schematically illustrating still another example of a partial area of the display device of FIGS. 1A and 1B.

FIG. 18 is an enlarged view illustrating one unit light-emitting area from among unit light-emitting areas of FIG. 17.

FIG. 19 is a cross-sectional view taken along the line II-II′ of FIG. 18.

FIG. 20 is a block diagram illustrating an electronic device according to one or more embodiments.

FIG. 21 is a schematic diagram of an electronic device according to various embodiments.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that the present disclosure will be thorough and complete, and will fully convey the scope of the present disclosure to those skilled in the art. In the drawings, the sizes and relative sizes of layers and regions may be exaggerated for clarity.

In the present disclosure, various modifications can be made, various forms can be used, and specific embodiments will be illustrated in the drawings and described in detail in the text. However, this is not intended to limit the present disclosure to a specific form disclosed, and it will be understood that all changes, equivalents, or substitutes which fall in the spirit and technical scope of the present disclosure should be included.

It will be understood that, although the terms first, second, third, and/or the like may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

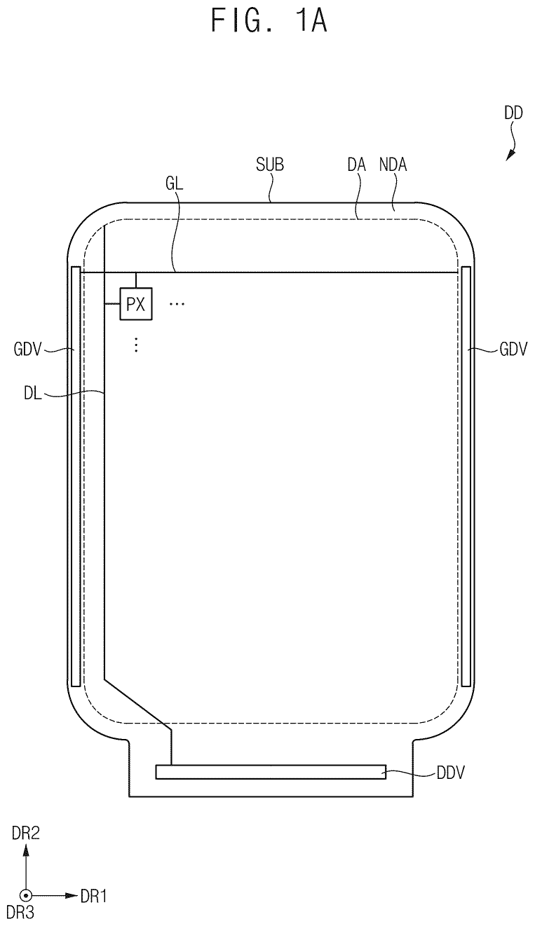

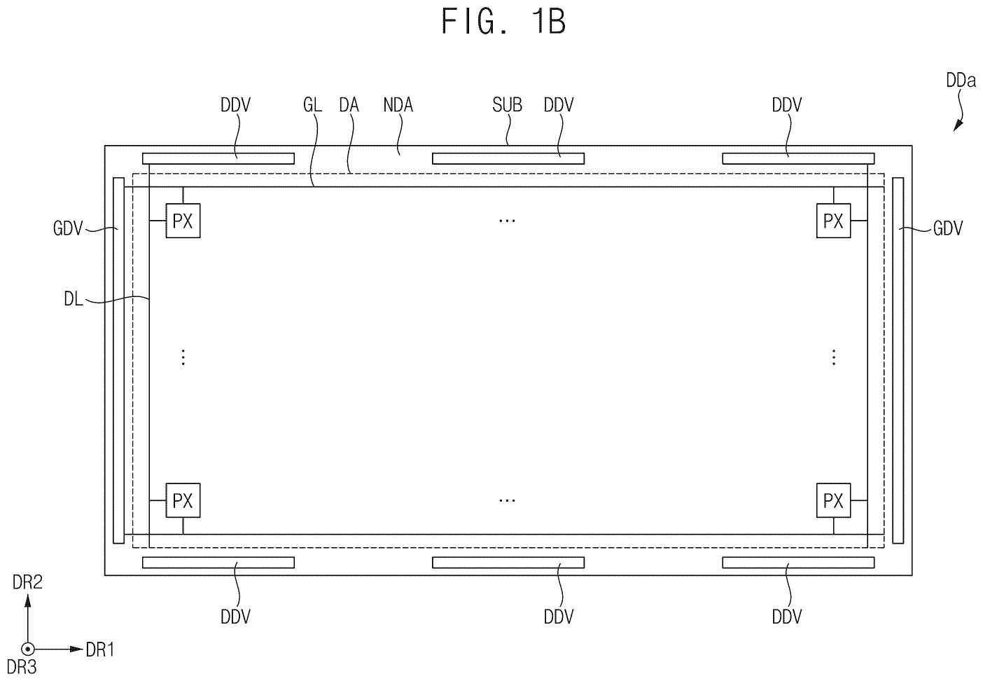

FIG. 1A is a plan view illustrating a display device according to one or more embodiments. FIG. 1B is a plan view illustrating a display device according to one or more embodiments.

Referring to FIGS. 1A and 1B, a display device DD and DDa may be activated by an electrical signal. For example, the display device DD may be a small display device used in small electronic device such as smartphone, mobile phone, smart watches, game console, cameras, and/or the like. In addition, the display device DDa may be a medium to large-sized display device used in medium to large-sized electronic device such as laptops, tablet PCs, televisions, computer monitors, vehicle monitors, external billboards, and/or the like. In FIG. 1A, the display device DDa is illustrated as an example of the small display device, and in FIG. 1B, the display device DDa is illustrated as an example of the medium to large-sized display device.

The display device DD and DDa may include a display area DA and a surrounding area NDA. The display area DA may be an area that generates light or adjusts a transmittance of light provided from an external light source to display an image. The surrounding area NDA may be located around the display area DA along an edge or a periphery of the display area DA. For example, the surrounding area NDA may surround at least a portion of the display area DA. In one or more embodiments, the surrounding area NDA may be an area that does not display an image. However, the present disclosure is not limited thereto, and an image may be displayed in at least a portion of the surrounding area NDA. For example, a light-emitting-element emitting light may be located in at least a portion of the surrounding area NDA. The display device DD and DDa may include a substrate SUB, pixels PX, a gate line GL, a data line DL, a data driver DDV, and a gate driver GDV.

The substrate SUB may be a base of the display device DD and DDa. In one or more embodiments, examples of materials that may be used as the substrate SUB may include glass, quartz, silicon, polymer, and/or the like. These materials may be used alone or in combination with each other. In addition, the substrate SUB may have a single layer structure or a multilayer structure in which a plurality of layers including different materials are stacked.

The pixels PX may be located in the display area DA on the substrate SUB. The pixels PX may be electrically connected to the gate line GL and the data line DL. For example, the pixels PX may be located in a matrix form along a first direction DR1 and a second direction DR2 crossing the first direction DR1. For example, the pixels PX may be arranged along rows and columns of a matrix along the first direction DR1 and the second direction DR2. Each of the pixels PX may include a pixel driving circuit portion and a light-emitting element. The light-emitting element may emit light. The light-emitting element may be an organic light-emitting diode (OLED) or an inorganic light-emitting diode.

The gate line GL and the data line DL may cross each other. For example, the gate line GL generally extends in the first direction DR1 and may be arranged along the second direction DR2. The data line DL generally extends in the second direction DR2 and may be arranged along the first direction DR1. However, the present disclosure is not limited thereto.

The data driver DDV may be located in the surrounding area NDA on the substrate SUB. The data driver DDV may generate a data voltage. The data driver DDV may output the data voltage to the data line DL. The data voltage may be applied to the pixels PX through a data line DL.

In one or more embodiments, the data driver DDV may be mounted on the substrate SUB. However, the present disclosure is not limited thereto, and the data driver DDV may be located on a flexible film coupled to the substrate SUB. For example, the display device DD may have a structure of a chip-on-film (“COF”).

In one or more embodiments, the display device DDa of FIG. 1B may include a plurality of data drivers DDV. For example, the data drivers DDV may be located at opposite sides of the display area DA in the second direction DR2. For example, the data drivers DDV may be located along a long side of the display area DA.

The gate driver GDV may be located in the surrounding area NDA on the substrate SUB. The gate driver GDV may generate a gate signal. The gate driver GDV may output the gate signal to the gate line GL. The gate signal may be applied to the pixels PX through a gate line GL. In one or more embodiments, the gate driver GDV may be located at opposite sides of the display area DA in the first direction DR1. However, the present disclosure is not necessarily limited thereto.

In one or more embodiments, a light-emitting driver for generating a light-emitting control signal may be further located in the surrounding area NDA. The light-emitting control signal may be applied to the pixels PX through a light-emitting control line.

Number or arrangement relationship of the data drivers DDV and number or arrangement relationship of the gate drivers GDV illustrated in FIGS. 1A and 1B are only examples, and the present disclosure is not necessarily limited thereto.

In addition, in FIG. 1A, the display device DD may have a substantially rectangular planar shape having a short side extending in the first direction DR1 and a long side extending in the second direction DR2, but the present disclosure is not necessarily limited thereto. In addition, in FIG. 1B, the display device DDa may have a rectangular planar shape having a long side extending in the first direction DR1 and a short side extending in the second direction DR2, but the present disclosure is not necessarily limited thereto. For example, shape of the display device DD and DDa in a plan view may be variously changed according to one or more embodiments.

Descriptions referring to following drawings may be equally applied to the display device DD of FIG. 1A and the display device DDa of FIG. 1B. Therefore, hereinafter, for convenience of description, expression is unified with the display device DD.

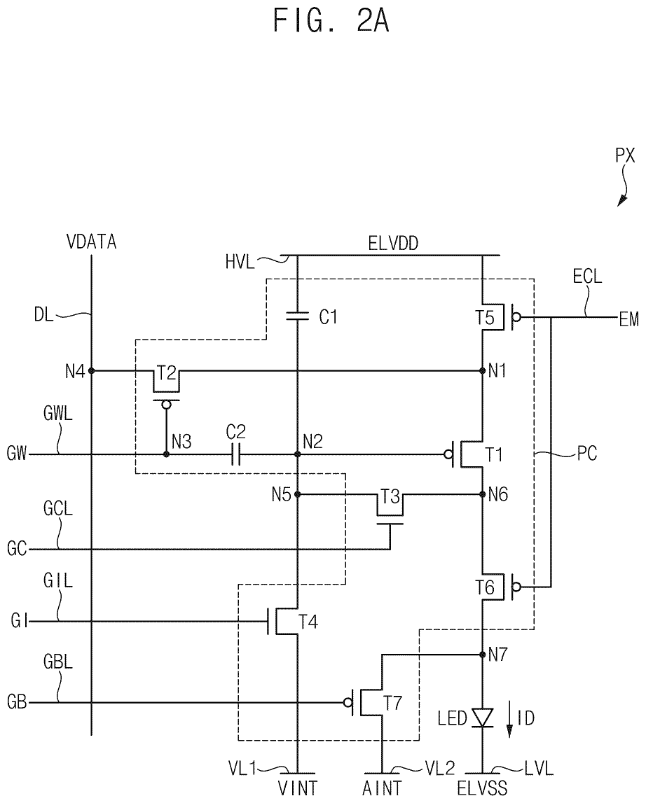

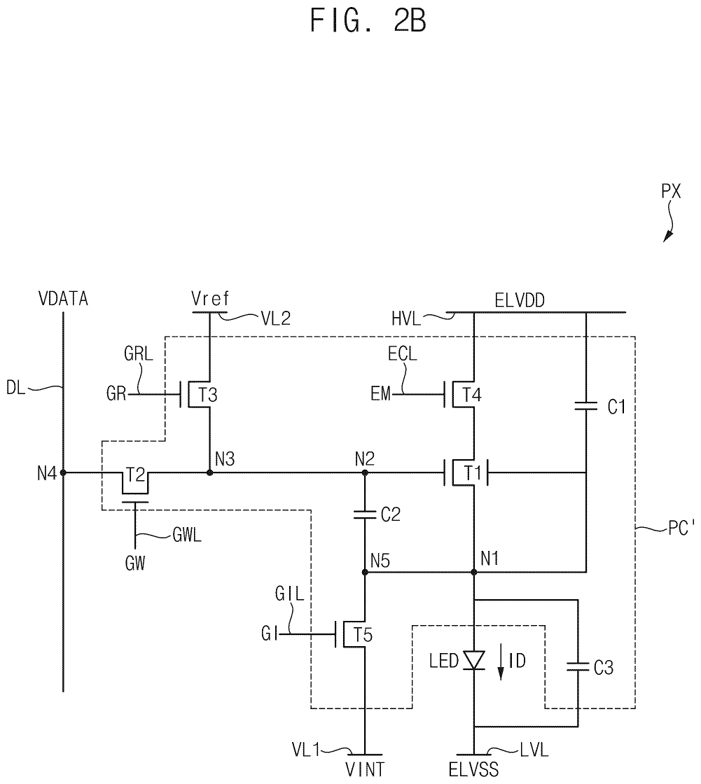

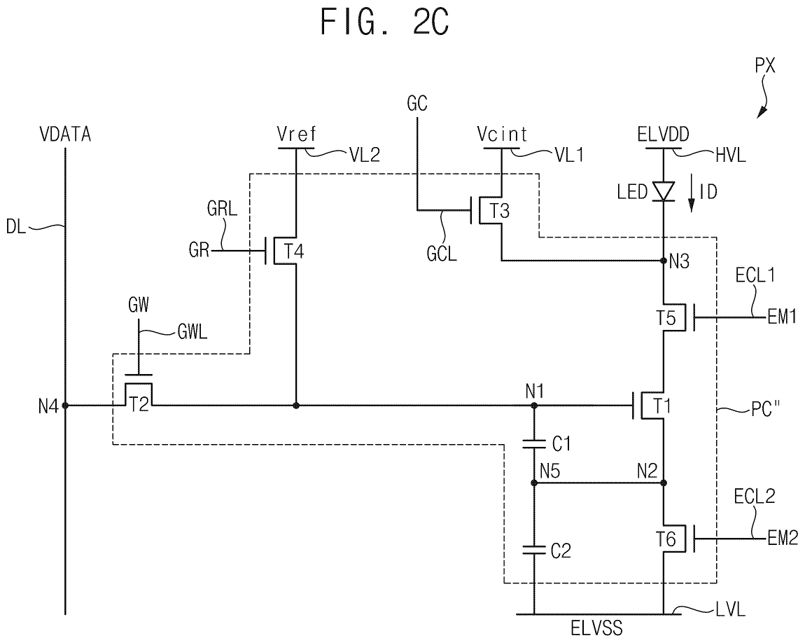

FIG. 2A is a circuit diagram illustrating an example of a circuit structure of a pixel included in the display device of FIGS. 1A and 1B.

Referring to FIG. 2A, the pixel PX may include a light-emitting element LED and a pixel driving circuit portion PC electrically connected to the light-emitting element LED. In one or more embodiments, the pixel driving circuit portion PC may include a first transistor T1, a second transistor T2, a third transistor T3, a fourth transistor T4, a fifth transistor T5, a sixth transistor T6, a seventh transistor T7, a first capacitor C1, and a second capacitor C2. In FIG. 2A, each of the first transistor T1, the second transistor T2, the fifth transistor T5, the sixth transistor T6, and the seventh transistor T7 may be illustrated as a p-type transistor, and each of the third transistor T3 and the fourth transistor T4 may be illustrated as an n-type transistor. However, the present disclosure is not limited thereto.

An active pattern of the n-type transistor may include an oxide semiconductor material, and an active pattern of the p-type transistor may include a silicon semiconductor material. However, the presents disclosure is not necessarily limited thereto, and each of the active pattern of the n-type transistor and the active pattern of the p-type transistor may include a silicon semiconductor material.

The pixel driving circuit portion PC may be electrically connected to a first power voltage line HVL, a second power voltage line LVL, a data line DL, a first gate line GWL, a second gate line GCL, a third gate line GIL, a fourth gate line GBL, a first voltage line VL1, a second voltage line VL2, and a light-emitting control line ECL.

The data line DL may apply a data voltage VDATA. The first power voltage line HVL may apply a first power voltage ELVDD having a relatively high voltage level. The second power voltage line LVL may apply a second power voltage ELVSS having a relatively low voltage level. The first voltage line VL1 may apply a first initialization voltage VINT. The second voltage line VL2 may apply a second initialization voltage AINT. The first gate line GWL may apply a first gate signal GW. The second gate line GCL may apply a second gate signal GC. The third gate line GIL may apply a third gate signal GI. The fourth gate line GBL may apply a fourth gate signal GB. The light-emitting control line ECL may apply a light-emitting control signal EM.

The first transistor T1 may include a gate electrode, a first electrode, and a second electrode. In one or more embodiments, the first electrode of the first transistor T1 may be a drain electrode, and the second electrode of the first transistor T1 may be a source electrode. The gate electrode of the first transistor T1 may be connected to a second node N2. The first electrode of the first transistor T1 may be connected to the sixth transistor T6, and the second electrode of the first transistor T1 may be connected to the fifth transistor T5. The first transistor T1 may provide a driving current ID to the light-emitting element LED.

The second transistor T2 may include a gate electrode, a first electrode, and a second electrode. In one or more embodiments, the first electrode of the second transistor T2 may be a drain electrode, and the second electrode of the second transistor T2 may be a source electrode. However, the present disclosure is not necessarily limited thereto, and the first electrode of the second transistor T2 may be a source electrode, and the second electrode of the second transistor T2 may be a drain electrode. The gate electrode of the second transistor T2 may be connected to the first gate line GWL. The first electrode of the second transistor T2 may be connected to a first node N1. The second electrode of the second transistor T2 may be connected to the data line DL through a fourth node N4.

The gate electrode of the second transistor T2 may receive the first gate signal GW through the first gate line GWL. The second transistor T2 may be turned on or off in response to the first gate signal GW. For example, when the second transistor T2 is a p-type transistor, the second transistor T2 may be turned off when the first gate signal GW has a positive voltage level, and may be turned on when the first gate signal GW has a negative voltage level. In addition, when the second transistor T2 is an n-type transistor, the second transistor T2 may be turned off when the first gate signal GW has a negative voltage level, and may be turned on when the first gate signal GW has a positive voltage level. The second electrode of the second transistor T2 may receive a data voltage VDATA through the data line DL. The first electrode of the second transistor T2 may provide the data voltage VDATA to the first node N1 during a period in which the second transistor T2 is turned on. Accordingly, the second transistor T2 may drive the first transistor T1.

The third transistor T3 may include a gate electrode, a first electrode, and a second electrode. In one or more embodiments, the first electrode of the third transistor T3 may be a source electrode, and the second electrode of the third transistor T3 may be a drain electrode. However, the present disclosure is not necessarily limited thereto, and the first electrode of the third transistor T3 may be a drain electrode, and the second electrode of the third transistor T3 may be a source electrode. The gate electrode of the third transistor T3 may be connected to the second gate line GCL. The first electrode of the third transistor T3 may be connected to a fifth node N5. The second electrode of the third transistor T3 may be connected to a sixth node N6.

The gate electrode of the third transistor T3 may receive the second gate signal GC through the second gate line GCL. The third transistor T3 may be turned on or off in response to the second gate signal GC. For example, when the third transistor T3 is an n-type transistor, the third transistor T3 may be turned off when the second gate signal GC has a negative voltage level (e.g., a low level voltage), and may be turned on when the second gate signal GC has a positive voltage level (e.g., a high level voltage). In addition, when the third transistor T3 is a p-type transistor, the third transistor T3 may be turned off when the second gate signal GC has a positive voltage level, and may be turned on when the second gate signal GC has a negative voltage level (e.g., a low level voltage).

The fourth transistor T4 may include a gate electrode, a first electrode, and a second electrode. In one or more embodiments, the first electrode of the fourth transistor T4 may be a source electrode, and the second electrode of the fourth transistor T4 may be a drain electrode. However, the present disclosure is not necessarily limited thereto, and the first electrode of the fourth transistor T4 may be a drain electrode, and the second electrode of the fourth transistor T4 may be a source electrode. The gate electrode of the fourth transistor T4 may be connected to the third gate line GIL. The first electrode of the fourth transistor T4 may be connected to the first voltage line VL1. The second electrode of the fourth transistor T4 may be connected to the fifth node N5.

The gate electrode of the fourth transistor T4 may receive the third gate signal GI through the third gate line GIL. The fourth transistor T4 may be turned on or off in response to the third gate signal GI. For example, when the fourth transistor T4 is an n-type transistor, the fourth transistor T4 may be turned off when the third gate signal GI has a negative voltage level, and may be turned on when the third gate signal GI has a positive voltage level. In addition, when the fourth transistor T4 is a p-type transistor, the fourth transistor T4 may be turned off when the third gate signal GI has a positive voltage level, and may be turned on when the third gate signal GI has a negative voltage level. During a period in which the fourth transistor T4 is turned on, the fourth transistor T4 may provide the first initialization voltage VINT to the fifth node N5.

The fifth transistor T5 may include a gate electrode, a first electrode, and a second electrode. In one or more embodiments, the first electrode of the fifth transistor T5 may be a drain electrode. The second electrode of the fifth transistor T5 may be a source electrode. However, the present disclosure is not necessarily limited thereto, and the first electrode of the fifth transistor T5 may be a source electrode, and the second electrode of the fifth transistor T5 may be a drain electrode. The gate electrode of the fifth transistor T5 may be connected to the light-emitting control line ECL. The first electrode of the fifth transistor T5 may be connected to the first power voltage line HVL. The second electrode of the fifth transistor T5 may be connected to the first node N1.

The gate electrode of the fifth transistor T5 may receive the light-emitting control signal EM through the light-emitting control line ECL. The fifth transistor T5 may be turned on or off in response to the light-emitting control signal EM. For example, when the fifth transistor T5 is a p-type transistor, the fifth transistor T5 may be turned off when the light-emitting control signal EM has a positive voltage level, and may be turned on when the light-emitting control signal EM has a negative voltage level. In addition, when the fifth transistor T5 is an n-type transistor, the fifth transistor T5 may be turned off when the light-emitting control signal EM has a negative voltage level, and may be turned on when the light-emitting control signal EM has a positive voltage level. During a period in which the fifth transistor T5 is turned on, the fifth transistor T5 may provide the first power voltage ELVDD to the first node N1.

The sixth transistor T6 may include a gate electrode, a first electrode, and a second electrode. In one or more embodiments, the first electrode of the sixth transistor T6 may be a drain electrode, and the second electrode of the sixth transistor T6 may be a source electrode. However, the present disclosure is not necessarily limited thereto, and the first electrode of the sixth transistor T6 may be a source electrode, and the second electrode of the sixth transistor T6 may be a drain electrode. The gate electrode of the sixth transistor T6 may be connected to the light-emitting control line ECL. The first electrode of the sixth transistor T6 may be connected to the sixth node N6. The second electrode of the sixth transistor T6 may be connected to a seventh node N7.

The gate electrode of the sixth transistor T6 may receive the light-emitting control signal EM through the light-emitting control line ECL. The sixth transistor T6 may be turned on or off in response to the light-emitting control signal EM. For example, when the sixth transistor T6 is a p-type transistor, the sixth transistor T6 may be turned off when the light-emitting control signal EM has a positive voltage level, and may be turned on when the light-emitting control signal EM has a negative voltage level. In addition, when the sixth transistor T6 is an n-type transistor, the sixth transistor T6 may be turned off when the light-emitting control signal EM has a negative voltage level, and may be turned on when the light-emitting control signal EM has a positive voltage level.

The seventh transistor T7 may include a gate electrode, a first electrode, and a second electrode. The first electrode of the seventh transistor T7 may be a drain electrode, and the second electrode of the seventh transistor T7 may be a source electrode. However, the present disclosure is not necessarily limited thereto, and the first electrode of the seventh transistor T7 may be a source electrode, and the second electrode of the seventh transistor T7 may be a drain electrode. The gate electrode of the seventh transistor T7 may be connected to the fourth gate line GBL. The first electrode of the seventh transistor T7 may be connected to the second voltage line VL2. The second electrode of the seventh transistor T7 may be connected to the seventh node N7.

The gate electrode of the seventh transistor T7 may receive the fourth gate signal GB through the fourth gate line GBL. The seventh transistor T7 may be turned on or off in response to the fourth gate signal GB. For example, when the seventh transistor T7 is a p-type transistor, the seventh transistor T7 may be turned off when the fourth gate signal GB has a positive voltage level, and may be turned on when the fourth gate signal GB has a negative voltage level. In addition, when the seventh transistor T7 is an n-type transistor, the seventh transistor T7 may be turned off when the fourth gate signal GB has a negative voltage level, and may be turned on when the fourth gate signal GB has a positive voltage level. During a period in which the seventh transistor T7 is turned on, the seventh transistor T7 may provide the second initialization voltage AINT to the seventh node N7.

The first capacitor C1 may include a first electrode and a second electrode. The first electrode of the first capacitor C1 may be connected to the first power voltage line HVL. The second electrode of the first capacitor C1 may be connected to the second node N2. A charge corresponding to a difference between a voltage of the gate electrode of the first transistor T1 and the first power voltage ELVDD may be stored in the first capacitor C1.

The second capacitor C2 may include a first electrode and a second electrode. The first electrode of the second capacitor C2 may be connected to a third node N3. The second electrode of the second capacitor C2 may be connected to the second node N2. The second capacitor C2 may allow a voltage of the gate electrode of the first transistor T1 to change in a same direction when the first gate signal GW changes.

The light-emitting element LED may include a first electrode and a second electrode. The first electrode of the light-emitting element LED may be connected to the seventh node N7. The second electrode of the light-emitting element LED may be connected to the second power voltage line LVL. For example, the first electrode of the light-emitting element LED may be an anode electrode, and the second electrode of the light-emitting element LED may be a cathode electrode.

FIG. 2B is a circuit diagram illustrating another example of a circuit structure of a pixel included in the display device of FIGS. 1A and 1B.

Referring to FIG. 2B, the pixel PX may include a light-emitting element LED and a pixel driving circuit portion PC′ electrically connected to the light-emitting element LED. In one or more embodiments, the pixel driving circuit portion PC′ may include a first transistor T1, a second transistor T2, a third transistor T3, a fourth transistor T4, a fifth transistor T5, a first capacitor C1, a second capacitor C2 and a third capacitor C3. In FIG. 2B, each of the first transistor T1, the second transistor T2, the third transistor T3, the fourth transistor T4, and the fifth transistor T5 may be illustrated as a n-type transistor. However, the present disclosure is not necessarily limited thereto, and some of the first transistor T1, the second transistor T2, the third transistor T3, the fourth transistor T4, and the fifth transistor T5 may be n-type transistors, and others may be p-type transistors. For example, the first transistor T1 may be an n-type transistor, and some of the second transistor T2, the third transistor T3, the fourth transistor T4, and the fifth transistor T5 may be n-type transistors, and others may be p-type transistors.

The pixel driving circuit portion PC′ may be electrically connected to a first power voltage line HVL, a second power voltage line LVL, a data line DL, a first gate line GWL, a second gate line GRL, a third gate line GIL, a first voltage line VL1, a second voltage line VL2, and a light-emitting control line ECL.

The data line DL may apply a data voltage VDATA. The first power voltage line HVL may apply a first power voltage ELVDD having a relatively high voltage level. The second power voltage line LVL may apply a second power voltage ELVSS having a relatively low voltage level. The first voltage line VL1 may apply a first initialization voltage VINT. The second voltage line VL2 may apply a reference voltage Vref. The first gate line GWL may apply a first gate signal GW. The second gate line GRL may apply a second gate signal GR. The third gate line GIL may apply a third gate signal GI. The light-emitting control line ECL may apply a light-emitting control signal EM.

The first transistor T1 may include a first gate electrode, a second gate electrode, a first electrode, and a second electrode. In one or more embodiments, the first electrode of the first transistor T1 may be a source electrode, and the second electrode of the first transistor T1 may be a drain electrode. The first gate electrode of the first transistor T1 may be connected to a second node N2. The second gate electrode of the first transistor T1 may be connected to the first capacitor C1. For example, the first gate electrode of the first transistor T1 may be an upper gate electrode, and the second gate electrode of the first transistor T1 may be a lower gate electrode. The second electrode of the first transistor T1 may be connected to the fourth transistor T4. The first electrode of the first transistor T1 may be connected to a first node N1. The first transistor T1 may provide a driving current ID to the light-emitting element LED.

The second transistor T2 may include a gate electrode, a first electrode, and a second electrode. In one or more embodiments, the first electrode of the second transistor T2 may be a source electrode, and the second electrode of the second transistor T2 may be a drain electrode. However, the present disclosure is not necessarily limited thereto, and the first electrode of the second transistor T2 may be a drain electrode, and the second electrode of the second transistor T2 may be a source electrode. The gate electrode of the second transistor T2 may be connected to the first gate line GWL. The first electrode of the second transistor T2 may be connected to the data line DL through a fourth node N4. The second electrode of the second transistor T2 may be connected to a third node N3.

The gate electrode of the second transistor T2 may receive the first gate signal GW through the first gate line GWL. The second transistor T2 may be turned on or off in response to the first gate signal GW. For example, when the second transistor T2 is an n-type transistor, the second transistor T2 may be turned off when the first gate signal GW has a negative voltage level, and may be turned on when the first gate signal GW has a positive voltage level. In addition, when the second transistor T2 is a p-type transistor, the second transistor T2 may be turned off when the first gate signal GW has a positive voltage level, and may be turned on when the first gate signal GW has a negative voltage level. The first electrode of the second transistor T2 may receive the data voltage VDATA through the data line DL. The second electrode of the second transistor T2 may provide the data voltage VDATA to the second node N2 during a period in which the second transistor T2 is turned on. Accordingly, the second transistor T2 may drive the first transistor T1.

The third transistor T3 may include a gate electrode, a first electrode, and a second electrode. In one or more embodiments, the first electrode of the third transistor T3 may be a source electrode, and the second electrode of the third transistor T3 may be a drain electrode. However, the present disclosure is not necessarily limited thereto, and the first electrode of the third transistor T3 may be a drain electrode, and the second electrode of the third transistor T3 may be a source electrode. The gate electrode of the third transistor T3 may be connected to the second gate line GRL. The first electrode of the third transistor T3 may be connected to the third node N3. The second electrode of the third transistor T3 may be connected to the second voltage line VL2.

The gate electrode of the third transistor T3 may receive the second gate signal GR through the second gate line GRL. The third transistor T3 may be turned on or off in response to the second gate signal GR. For example, when the third transistor T3 is an n-type transistor, the third transistor T3 may be turned off when the second gate signal GR has a negative voltage level, and may be turned on when the second gate signal GR has a positive voltage level. In addition, when the third transistor T3 is a p-type transistor, the third transistor T3 may be turned off when the second gate signal GR has a positive voltage level, and may be turned on when the second gate signal GR has a negative voltage level. During a period in which the third transistor T3 is turned on, the third transistor T3 may provide the reference voltage Vref to the third node N3.

The fourth transistor T4 may include a gate electrode, a first electrode, and a second electrode. In one or more embodiments, the first electrode of the fourth transistor T4 may be a source electrode, and the second electrode of the fourth transistor T4 may be a drain electrode. However, the present disclosure is not necessarily limited thereto, and the first electrode of the fourth transistor T4 may be a drain electrode, and the second electrode of the fourth transistor T4 may be a source electrode. The gate electrode of the fourth transistor T4 may be connected to the light-emitting control line ECL. The first electrode of the fourth transistor T4 may be connected to the first transistor T1. The second electrode of the fourth transistor T4 may be connected to the first power voltage line HVL.

The gate electrode of the fourth transistor T4 may receive the light-emitting control signal EM through the light-emitting control line ECL. The fourth transistor T4 may be turned on or off in response to the light-emitting control signal EM. For example, when the fourth transistor T4 is an n-type transistor, the fourth transistor T4 may be turned off when the light-emitting control signal EM has a negative voltage level, and may be turned on when the light-emitting control signal EM has a positive voltage level. In addition, when the fourth transistor T4 is a p-type transistor, the fourth transistor T4 may be turned off when the light-emitting control signal EM has a positive voltage level, and may be turned on when the light-emitting control signal EM has a negative voltage level. During a period in which the fourth transistor T4 is turned on, the fourth transistor T4 may provide the first power voltage ELVDD to the first transistor T1.

The fifth transistor T5 may include a gate electrode, a first electrode, and a second electrode. The first electrode of the fifth transistor T5 may be a source electrode, and the second electrode of the fifth transistor T5 may be a drain electrode. However, the present disclosure is not necessarily limited thereto, and the first electrode of the fifth transistor T5 may be a drain electrode. The second electrode of the fifth transistor T5 may be a source electrode. The gate electrode of the fifth transistor T5 may be connected to the third gate line GIL. The first electrode of the fifth transistor T5 may be connected to the first voltage line VL1. The second electrode of the fifth transistor T5 may be connected to a fifth node N5.

The gate electrode of the fifth transistor T5 may receive the third gate signal GI through the third gate line GIL. The fifth transistor T5 may be turned on or off in response to the third gate signal GI. For example, when the fifth transistor T5 is an n-type transistor, the fifth transistor T5 may be turned off when the third gate signal GI has a negative voltage level, and may be turned on when the third gate signal GI has a positive voltage level. In addition, when the fifth transistor T5 is a p-type transistor, the fifth transistor T5 may be turned off when the third gate signal GI has a positive voltage level, and may be turned on when the third gate signal GI has a negative voltage level. During a period in which the fifth transistor T5 is turned on, the fifth transistor T5 may provide the first initialization voltage VINT to the fifth node N5.

The first capacitor C1 may include a first electrode and a second electrode. The first electrode of the first capacitor C1 may be connected to the first power voltage line HVL. The second electrode of the first capacitor C1 may be connected to the first node N1. The first capacitor C1 may prevent a voltage difference between the first power voltage ELVDD and the first transistor T1 from being rapidly changed. For example, the first capacitor C1 may prevent a voltage difference between the first power voltage ELVDD and the second gate electrode of the first transistor T1 from being rapidly changed.

The second capacitor C2 may include a first electrode and a second electrode. The first electrode of the second capacitor C2 may be connected to the second node N2. The second electrode of the second capacitor C2 may be connected to the fifth node N5. The second capacitor C2 may be charged and discharged according to the data voltage VDATA transferred to the second node N2.

The third capacitor C3 may include a first electrode and a second electrode. The first electrode of the third capacitor C3 may be connected to a first electrode of the light-emitting element LED. The second electrode of the third capacitor C3 may be connected to a second electrode of the light-emitting element LED. The third capacitor C3 may be omitted.

The light-emitting element LED may include a first electrode and a second electrode. The first electrode of the light-emitting element LED may be connected to the first node N1. The second electrode of the light-emitting element LED may be connected to the second power voltage line LVL. For example, the first electrode of the light-emitting element LED may be an anode electrode, and the second electrode of the light-emitting element LED may be a cathode electrode.

FIG. 2C is a circuit diagram illustrating still another example of a circuit structure of a pixel included in the display device of FIGS. 1A and 1B.

Referring to FIG. 2C, the pixel PX may include a light-emitting element LED and a pixel driving circuit portion PC″ electrically connected to the light-emitting element LED. In one or more embodiments, the pixel driving circuit portion PC″ may include a first transistor T1, a second transistor T2, a third transistor T3, a fourth transistor T4, a fifth transistor T5, a sixth transistor T6, a first capacitor C1, and a second capacitor C2. In FIG. 2C, each of the first transistor T1, the second transistor T2, the third transistor T3, the fourth transistor T4, the fifth transistor T5, and the sixth transistor T6 is illustrated as an n-type transistor. However, the present disclosure is not limited thereto, and some of the first transistor T1, the second transistor T2, the third transistor T3, the fourth transistor T4, the fifth transistor T5, and the sixth transistor T6 may be an n-type transistor, and others may be a p-type transistor. For example, the first transistor T1 may be an n-type transistor, and some of the second transistor T2, the third transistor T3, the fourth transistor T4, the fifth transistor T5, and the sixth transistor T6 may be n-type transistors, and others may be p-type transistors.

The pixel driving circuit portion PC″ may be connected to a first gate line GWL, a second gate line GCL, a third gate line GRL, a data line DL, a first power voltage line HVL, a second power voltage line LVL, a first voltage line VL1, a second voltage line VL2, a first light-emitting control line ECL1, and a second light-emitting control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first power voltage line HVL may transfer the first power voltage ELVDD having a relatively high voltage level. The second power voltage line LVL may transfer the second power voltage ELVSS having a relatively low voltage level. The first voltage line VL1 may transfer a first initialization voltage Vcint. The second voltage line VL2 may transfer a reference voltage Vref. The reference voltage Vref may have a voltage level lower than a voltage of the first power voltage ELVDD.

The first transistor T1 may include a gate electrode, a first electrode, and a second electrode. In one or more embodiments, the first electrode of the first transistor T1 may be a source electrode, and the second electrode of the first transistor T1 may be a drain electrode. The gate electrode of the first transistor T1 may be connected to a first node N1. The second electrode of the first transistor T1 may be connected to the fifth transistor T5. The first electrode of the first transistor T1 may be connected to a second node N2. The first transistor T1 may provide a driving current ID to the light-emitting element LED.

The second transistor T2 may include a gate electrode, a first electrode, and a second electrode. In one or more embodiments, the first electrode of the second transistor T2 may be a source electrode, and the second electrode of the second transistor T2 may be a drain electrode. However, the present disclosure is not necessarily limited thereto, and the first electrode of the second transistor T2 may be a drain electrode, and the second electrode of the second transistor T2 may be a source electrode. The gate electrode of the second transistor T2 may be connected to the first gate line GWL. The first electrode of the second transistor T2 may be connected to the data line DL through a fourth node N4. The second electrode of the second transistor T2 may be connected to the first node N1.

The gate electrode of the second transistor T2 may receive the first gate signal GW through the first gate line GWL. The second transistor T2 may be turned on or off in response to the first gate signal GW. For example, when the second transistor T2 is an n-type transistor, the second transistor T2 may be turned off when the first gate signal GW has a negative voltage level, and may be turned on when the first gate signal GW has a positive voltage level. In addition, when the second transistor T2 is a p-type transistor, the second transistor T2 may be turned off when the first gate signal GW has a positive voltage level, and may be turned on when the first gate signal GW has a negative voltage level. The first electrode of the second transistor T2 may receive the data voltage VDATA through the data line DL. The second electrode of the second transistor T2 may provide the data voltage VDATA to the first node N1 during a period in which the second transistor T2 is turned on. Accordingly, the second transistor T2 may drive the first transistor T1.

The third transistor T3 may include a gate electrode, a first electrode, and a second electrode. In one or more embodiments, the first electrode of the third transistor T3 may be a source electrode, and the second electrode of the third transistor T3 may be a drain electrode. However, the present disclosure is not necessarily limited thereto, and the first electrode of the third transistor T3 may be a drain electrode, and the second electrode of the third transistor T3 may be a source electrode. The gate electrode of the third transistor T3 may be connected to the second gate line GCL. The first electrode of the third transistor T3 may be connected to a third node N3. The second electrode of the third transistor T3 may be connected to the first voltage line VL1.

The gate electrode of the third transistor T3 may receive the second gate signal GC through the second gate line GCL. The third transistor T3 may be turned on or off in response to the second gate signal GC. For example, when the third transistor T3 is an n-type transistor, the third transistor T3 may be turned off when the second gate signal GC has a negative voltage level, and may be turned on when the second gate signal GC has a positive voltage level. In addition, when the third transistor T3 is a p-type transistor, the third transistor T3 may be turned off when the second gate signal GC has a positive voltage level, and may be turned on when the second gate signal GC has a negative voltage level. During a period in which the third transistor T3 is turned on, the third transistor T3 may provide the first initialization voltage Vcint to the third node N3. For example, the third transistor T3 may provide the first initialization voltage Vcint to a cathode of the light-emitting element LED in response to the second gate signal GC to initialize a voltage of the cathode.

The fourth transistor T4 may include a gate electrode, a first electrode, and a second electrode. In one or more embodiments, the first electrode of the fourth transistor T4 may be a source electrode, and the second electrode of the fourth transistor T4 may be a drain electrode. However, the present disclosure is not necessarily limited thereto, and the first electrode of the fourth transistor T4 may be a drain electrode, and the second electrode of the fourth transistor T4 may be a source electrode. The gate electrode of the fourth transistor T4 may be connected to the third gate line GRL. The first electrode of the fourth transistor T4 may be connected to the first node N1. The second electrode of the fourth transistor T4 may be connected to the second voltage line VL2.

The gate electrode of the fourth transistor T4 may receive the third gate signal GR through the third gate line GRL. The fourth transistor T4 may be turned on or off in response to the third gate signal GR. For example, when the fourth transistor T4 is an n-type transistor, the fourth transistor T4 may be turned off when the third gate signal GR has a negative voltage level, and may be turned on when the third gate signal GR has a positive voltage level. In addition, when the fourth transistor T4 is a p-type transistor, the fourth transistor T4 may be turned off when the third gate signal GR has a positive voltage level, and may be turned on when the third gate signal GR has a negative voltage level. During a period in which the fourth transistor T4 is turned on, the fourth transistor T4 may provide the reference voltage Vref to the first node N1.

The fifth transistor T5 may include a gate electrode, a first electrode, and a second electrode. In one or more embodiments, the first electrode of the fifth transistor T5 may be a source electrode, and the second electrode of the fifth transistor T5 may be a drain electrode. However, the present disclosure is not necessarily limited thereto, and the first electrode of the fifth transistor T5 may be a drain electrode, and the second electrode of the fifth transistor T5 may be a source electrode. The gate electrode of the fifth transistor T5 may be connected to the first light-emitting control line ECL1. The first electrode of the fifth transistor T5 may be connected to the second electrode of the first transistor T1. The second electrode of the fifth transistor T5 may be connected to the third node N3. The second electrode of the fifth transistor T5 may be connected to the light-emitting element LED.

The gate electrode of the fifth transistor T5 may receive the first light-emitting control signal EM1 through the first light-emitting control line ECL1. The fifth transistor T5 may be turned on or off in response to the first light-emitting control signal EM1. For example, when the fifth transistor T5 is an n-type transistor, the fifth transistor T5 may be turned off when the first light-emitting control signal EM1 has a negative voltage level, and may be turned on when the first light-emitting control signal EM1 has a positive voltage level. In addition, when the fifth transistor T5 is a p-type transistor, the fifth transistor T5 may be turned off when the first light-emitting control signal EM1 has a positive voltage level, and may be turned on when the first light-emitting control signal EM1 has a negative voltage level. During a period in which the fifth transistor T5 is turned on, the fifth transistor T5 may electrically connect the first transistor T1 to the light-emitting element LED. For example, the fifth transistor T5 may electrically connect the second electrode of the first transistor T1 to the cathode of the light-emitting element LED in response to the first light-emitting control signal EM1.

The sixth transistor T6 may include a gate electrode, a first electrode, and a second electrode. In one or more embodiments, the first electrode of the sixth transistor T6 may be a source electrode, and the second electrode of the sixth transistor T6 may be a drain electrode. However, the present disclosure is not necessarily limited thereto, and the first electrode of the sixth transistor T6 may be a drain electrode, and the second electrode of the sixth transistor T6 may be a source electrode. The gate electrode of the sixth transistor T6 may be connected to a second light-emitting control line ECL2. The first electrode of the sixth transistor T6 may be connected to the second power voltage line LVL. The second electrode of the sixth transistor T6 may be connected to the second node N2.

The gate electrode of the sixth transistor T6 may receive the second light-emitting control signal EM2 through a second light-emitting control line ECL2. The sixth transistor T6 may be turned on or off in response to the second light-emitting control signal EM2. For example, when the sixth transistor T6 is an n-type transistor, the sixth transistor T6 may be turned off when the second light-emitting control signal EM2 has a negative voltage level, and may be turned on when the second light-emitting control signal EM2 has a positive voltage level. In addition, when the sixth transistor T6 is a p-type transistor, the sixth transistor T6 may be turned off when the second light-emitting control signal EM2 has a positive voltage level, and may be turned on when the second light-emitting control signal EM2 has a negative voltage level. During a period in which the sixth transistor T6 is turned on, the sixth transistor T6 may provide the second power voltage ELVSS to the second node N2.

In FIG. 2C, the fifth transistor T5 and the sixth transistor T6 may be independently driven by different light-emitting control signals, but the present disclosure is not limited thereto. For example, the first light-emitting control signal EM1 and the second light-emitting control signal EM2 may be provided as substantially a single light-emitting control signal, and the fifth transistor T5 and the sixth transistor T6 may be concurrently (e.g., simultaneously) turned on/off. In this case, the first light-emitting control line ECL1 and the second light-emitting control line ECL2 may be provided as substantially a single light-emitting control line.

The first capacitor C1 may include a first electrode and a second electrode. The first electrode of the first capacitor C1 may be connected to the first node N1. The second electrode of the first capacitor C1 may be connected to a fifth node N5. The first capacitor C1 may be charged and discharged according to the data voltage VDATA transferred to the first node N1.

The second capacitor C2 may include a first electrode and a second electrode. The first electrode of the second capacitor C2 may be connected to a fifth node N5. The second electrode of the second capacitor C2 may be connected to the second power voltage line LVL. For example, the second capacitor C2 may be connected to the first capacitor C1 in series. The data voltage VDATA may be transferred to the first node N1, and due to the serial connection between the first capacitor C1 and the second capacitor C2, the data voltage VDATA may be divided and transferred to the second node N2. As the first transistor T1 generates a driving current based on a voltage of the first node N1 and a voltage of the second node N2, data range may be extended.

The light-emitting element LED may include a first electrode and a second electrode. The first electrode of the light-emitting element LED may be connected to the first power voltage line HVL. The second electrode of the light-emitting element LED may be connected to the third node N3. For example, the first electrode of the light-emitting element LED may be an anode electrode. The second electrode of the light-emitting element LED may be a cathode electrode. The cathode of the light-emitting element LED may be connected to the second electrode of the first transistor T1 through the fifth transistor T5.

As illustrated in FIG. 2C, according to one or more embodiments of the present disclosure, the anode of the light-emitting element LED may receive the first power voltage ELVDD through the first power voltage line HVL, and the cathode of the light-emitting element LED may be connected to the second electrode of the first transistor T1. For example, the cathode of the light-emitting element LED may be electrically connected to and electric potential thereof may be controlled by the first transistor T1.

As the first power voltage line HVL provides the first power voltage ELVDD having a relatively high voltage level, and the second power voltage line LVL provides the second power voltage ELVSS having a relatively low voltage level, the second electrode of the first transistor T1 may be a drain electrode when the first transistor T1 is an n-type transistor. For example, according to one or more embodiments of the present disclosure, the cathode of the light-emitting element LED may be connected to the drain electrode of the first transistor T1.

When the first transistor T1 is an n-type transistor, when the anode of the light-emitting element LED is connected to the source electrode of the first transistor T1, the gate-source voltage “V_{gs}” of the first transistor T1 may be changed while a source voltage of the first transistor T1 is shifted by deterioration of the light-emitting element LED. Accordingly, variation width of the driving current ID increases, resulting in an afterimage defect and decreasing life of a display device.

According to FIG. 2C, the anode of the light-emitting-element LED may be provided with the first power voltage ELVDD, and the cathode of the light-emitting element LED may be connected to the drain electrode of the first transistor T1. Accordingly, the gate-source voltage “V_{gs}” of the first transistor T1 may not change even when the light-emitting element LED is deteriorated. Accordingly, variation width of the driving current ID due to deterioration of the light-emitting element LED may be reduced. Accordingly, afterimage defect of the display device DD by increase in use time may be reduced, and life of the display device DD may be improved.

Circuit structures of the pixel illustrated in FIGS. 2A, 2B, and 2C (e.g., number or arrangement relationship of transistors, number or arrangement relationship of capacitors) is only an example and may be variously changed according to one or more embodiments.

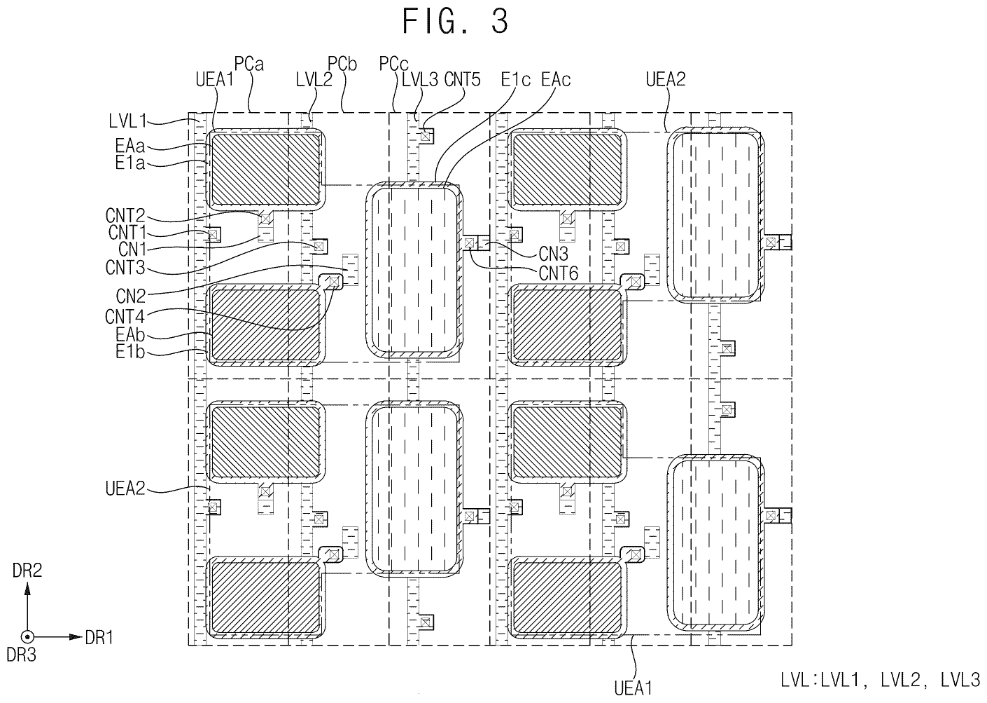

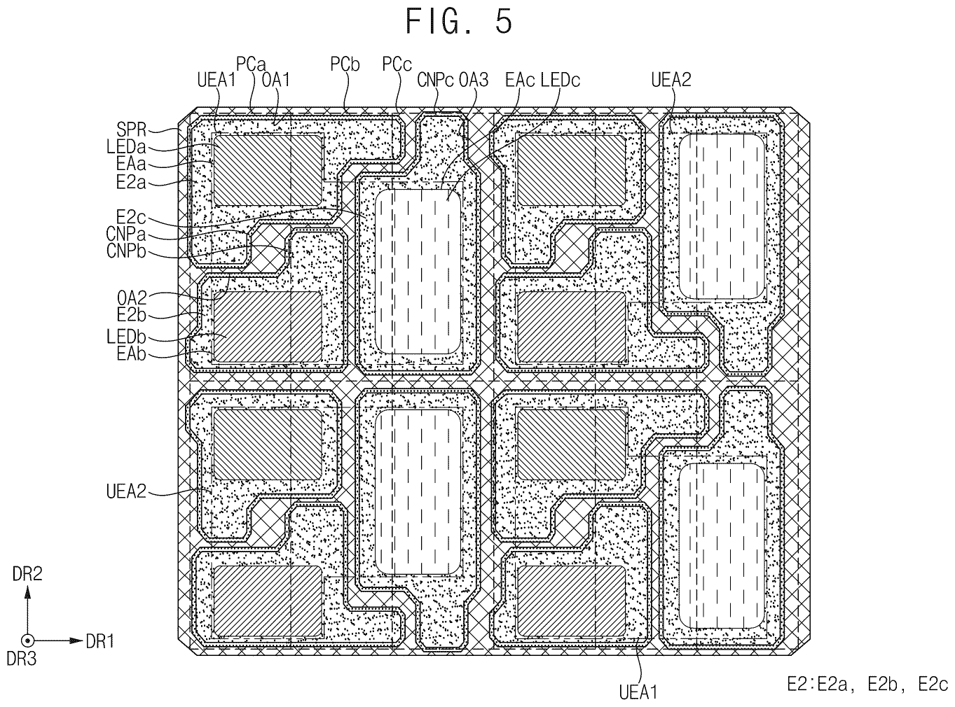

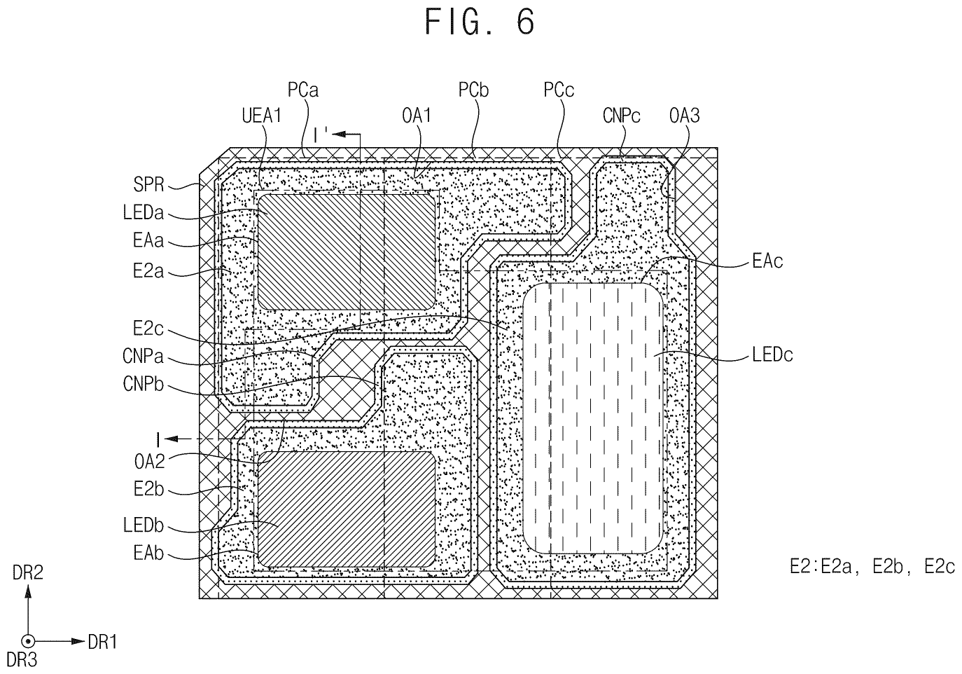

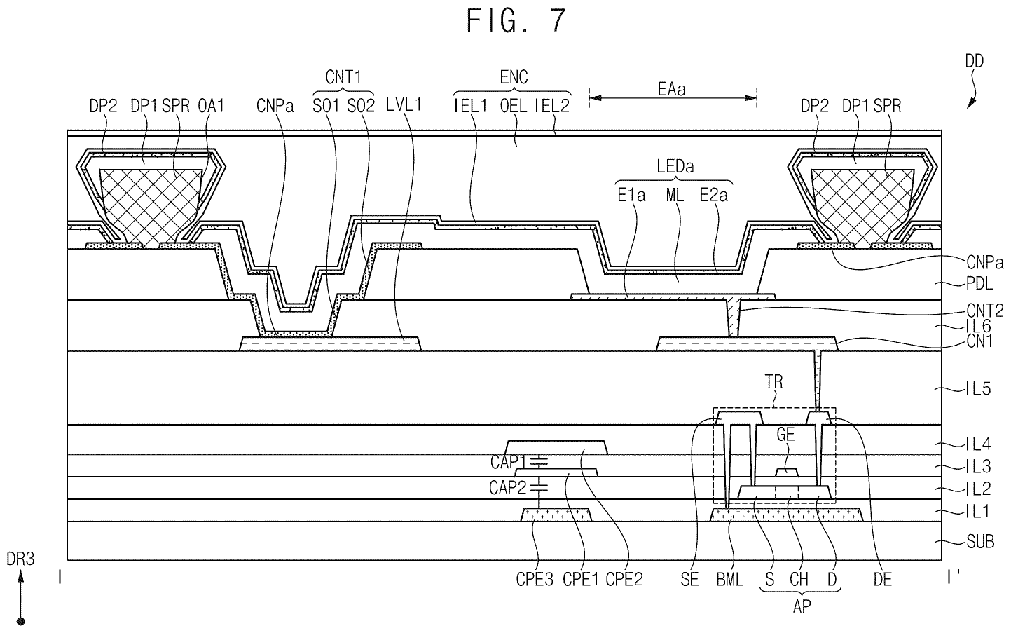

FIGS. 3, 4, and 5 are plan views schematically illustrating an example of a partial area of the display device of FIGS. 1A and 1B. FIG. 6 is an enlarged view illustrating one unit light-emitting area among unit light-emitting areas of FIG. 5. FIG. 7 is a cross-sectional view taken along the line I-I′ of FIG. 6.

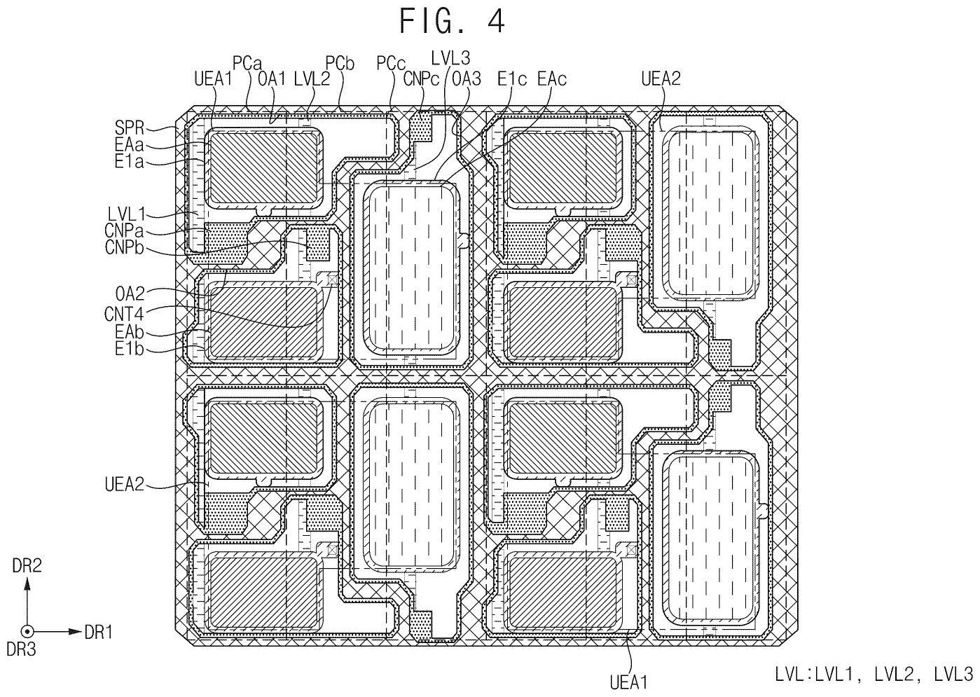

Specifically, in FIGS. 3, 4, and 5, an area in which a total of four unit light-emitting areas UEA1 and UEA2 constituting a matrix of two rows and two columns is arranged may be illustrated. In addition, in FIG. 4, it may be illustrated that a separator SPR and a plurality of connection patterns are located on a plurality of components illustrated in FIG. 3. In addition, in FIG. 5, a plurality of second electrodes may be located on a plurality of components illustrated in FIG. 4. In addition, in FIG. 6, one first unit light-emitting area UEA1 from among unit light-emitting areas UEA1 and UEA2 may be enlarged and shown. For convenience of explanation, some of components illustrated in FIGS. 3, 4, 5, and 6 are omitted or emphasized.

Referring to FIG. 3, the display device (e.g., the display device DD of FIG. 1A) may include a first pixel driving circuit portion PCa, a second pixel driving circuit portion PCb, a third pixel driving circuit portion PCc, a power voltage line LVL, a first connection line CN1, a second connection line CN2, a third connection line CN3, a first electrode E1a, a first electrode E1b, and a first electrode E1c.

Each of the first pixel driving circuit portion PCa, the second pixel driving circuit portion PCb, and the third pixel driving circuit portion PCc may correspond to the pixel driving circuit portions PC and/or PC′ described with reference to FIGS. 2A and 2B. For example, each of the first pixel driving circuit portion PCa, the second pixel driving circuit portion PCb, and the third pixel driving circuit portion PCc may correspond to the pixel driving circuit portion PC described with reference to FIG. 2A. For example, each of the first pixel driving circuit portion PCa, the second pixel driving circuit portion PCb, and the third pixel driving circuit portion PCc may include at least one transistor and at least one capacitor. For example, each of the first pixel driving circuit portion PCa, the second pixel driving circuit portion PCb, and the third pixel driving circuit portion PCc may include a first capacitor CAP1 and a transistor TR illustrated in FIG. 7.

In this case, the transistor TR of FIG. 7 may be a transistor connected to a light-emitting element through a connection pattern. For example, the transistor TR of FIG. 7 may be a transistor connected to the first light-emitting element LEDa through the first connection line CN1. For example, when each of the first pixel driving circuit portion PCa, the second pixel driving circuit portion PCb, and the third pixel driving circuit portion PCc is the pixel driving circuit portion PC of FIG. 2A, the transistor TR of FIG. 7 may be the sixth transistor T6 of FIG. 2A. In addition, when each of the first pixel driving circuit portion PCa, the second pixel driving circuit portion PCb, and the third pixel driving circuit portion PCc is the pixel driving circuit portion PC′ of FIG. 2B, the transistor TR of FIG. 7 may be the first transistor T1 of FIG. 2B. However, the present disclosure is not limited thereto.

In one or more embodiments, the first capacitor CAP1 of FIG. 7 may correspond to the first capacitor C1 of FIGS. 2A and 2B, and the second capacitor CAP2 of FIG. 7 may correspond to the second capacitor C2 of FIGS. 2A and 2B, but this disclosure is not limited thereto. For example, the first capacitor CAP1 of FIG. 7 may correspond to the second capacitor C2 of FIGS. 2A and 2B, and the second capacitor CAP2 of FIG. 7 may correspond to the first capacitor C1 of FIGS. 2A and 2B.

Components of the transistor TR, the first capacitor CAP1, and the second capacitor CAP2 of FIG. 7 will be described in more detail with reference to FIG. 7.

In FIG. 3, the first pixel driving circuit portion PCa, the second pixel driving circuit portion PCb, and the third pixel driving circuit portion PCc may be illustrated to be sequentially arranged along the first direction DR1 in a rectangular shape. However, the present disclosure is not limited thereto, and shapes and arrangements of the first pixel driving circuit portion PCa, the second pixel driving circuit portion PCb, and the third pixel driving circuit portion PCc may be variously changed according to one or more embodiments.

In one or more embodiments, the display device may include a first unit light-emitting area UEA1 and a second unit light-emitting area UEA2. The first unit light-emitting area UEA1 and the second unit light-emitting area UEA2 may be defined in a matrix form along the first direction DR1 and the second direction DR2. For example, the first unit light-emitting area UEA1 and the second unit light-emitting area UEA2 may be defined along rows and columns of a matrix along the first direction DR1 and the second direction DR2. Although four unit light-emitting areas are illustrated in FIG. 3, unit light-emitting areas may be defined in a matrix form in the display area DA (e.g., the display area DA of FIGS. 1A and 1B) as a whole.

A first light-emitting area EAa, a second light-emitting area EAb, and a third light-emitting area EAc may be defined in each of the first unit light-emitting area UEA1 and the second unit light-emitting area UEA2. A first light-emitting element (e.g., the first light-emitting element LEDa of FIG. 5) may be located in the first light-emitting area EAa, a second light-emitting element (e.g., the second light-emitting element LEDb of FIG. 5) may be located in the second light-emitting area EAb, and a third light-emitting element (e.g., the third light-emitting element LEDc of FIG. 5) may be located in the third light-emitting area EAc.

Each of the first light-emitting area EAa, the second light-emitting area EAb, and the third light-emitting area EAc may be defined by a pixel opening of a pixel defining layer (e.g., a pixel defining layer PDL of FIG. 7) to be described later. For example, each of the first light-emitting area EAa, the second light-emitting area EAb, and the third light-emitting area EAc may be an area in which light is emitted by light-emitting element. For example, the first light-emitting area EAa may be an area in which light is emitted by the first light-emitting element. In addition, the second light-emitting area EAb may be an area in which light is emitted by the second light-emitting element. In addition, the third light-emitting area EAc may be an area in which light is emitted by the third light-emitting element.

In one or more embodiments, the first unit light-emitting area UEA1 and the second unit light-emitting area UEA2 may be classified based on an arrangement relationship of the first light-emitting element, the second light-emitting element, and the third light-emitting element (or an arrangement relationship of the first light-emitting area EAa, the second light-emitting area EAb, and the third light-emitting area EAc). For example, the arrangement relationship of the first light-emitting element, the second light-emitting element, and the third light-emitting element (or the first light-emitting area EAa, the second light-emitting area EAb, and the third light-emitting area EAc) may be the same in each first unit light-emitting area UEA1, and the arrangement relationship of the first light-emitting element, the second light-emitting element, and the third light-emitting element (or the first light-emitting area EAa, the second light-emitting area EAb, and the third light-emitting area EAc) may be the same in each second unit light-emitting area UEA2.

As illustrated in FIG. 3, in one or more embodiments, the first unit light-emitting area UEA1 and the second unit light-emitting area UEA2 may be alternately arranged along the first direction DR1 (i.e., a row direction) and the second direction DR2 (i.e., a column direction). However, the present disclosure is not limited thereto, and number of different unit light-emitting areas included in the display device or arrangement relationship of unit light-emitting areas may be variously changed according to one or more embodiments.

It may be illustrated that the first light-emitting area EAa, the second light-emitting area EAb, and the third light-emitting area EAc are arranged in an S-strip type. However, the present disclosure is not limited thereto, and an arrangement relationship of the first light-emitting area EAa, the second light-emitting area EAb, and the third light-emitting area EAc may be variously changed according to one or more embodiments.

The first electrode Ela may be located in the first light-emitting area EAa. The first electrode Ela may be connected to the first connection line CN1 through a second contact hole CNT2. The first electrode E1b may be located in the second light-emitting area EAb. The first electrode E1b may be connected to the second connection line CN2 through a fourth contact hole CNT4. The first electrode E1c may be located in the third light-emitting area EAc. The first electrode E1c may be connected to the third connection line CN3 through a sixth contact hole CNT6.

The power voltage line LVL of FIG. 3 may correspond to the second power voltage line LVL of FIGS. 2A and 2B. For example, the power voltage line LVL of FIG. 3 may apply the low power voltage (e.g., the second power voltage ELVSS of FIGS. 2A and 2B) having a relatively low voltage level.

In one or more embodiments, the power voltage line LVL may include a first power voltage line LVL1, a second power voltage line LVL2, and a third power voltage line LVL3. Each of the first power voltage line LVL1, the second power voltage line LVL2, and the third power voltage line LVL3 may correspond to the second power voltage line LVL of FIGS. 2A and 2B. For example, each of the first power voltage line LVL1, the second power voltage line LVL2, and the third power voltage line LVL3 may extend in the second direction DR2, and may be arranged along the first direction DR1. For example, the second power voltage line LVL2 may be spaced (e.g., spaced apart) from the first power voltage line LVL1 in the first direction DR1, and the third power voltage line LVL3 may be spaced (e.g., spaced apart) from the second power voltage line LVL2 in the first direction DR1.

Referring further to FIGS. 4, 5 and 6, the display device may further include a first connection pattern CNPa, a second connection pattern CNPb, a third connection pattern CNPc, a separator SPR, and a second electrode layer E2.

The second electrode layer E2 may be separated (or disconnected) into a second electrode E2a, a second electrode E2b, and a second electrode E2c by the separator SPR. The second electrode E2a, the second electrode E2b, and the second electrode E2c may be electrically independent of each other.

Each of the first light-emitting element LEDa, the second light-emitting element LEDb, and the third light-emitting element LEDc may correspond to the light-emitting element LED of FIGS. 2A and 2B. For example, the first light-emitting element LEDa may include the first electrode E1a, an intermediate layer (e.g., an intermediate layer ML of FIG. 7) located on the first electrode E1a, and the second electrode E2a located on the intermediate layer. In addition, the second light-emitting element LEDb may include the first electrode E1b, an intermediate layer located on the first electrode E1b, and the second electrode E2b located on the intermediate layer. In addition, the third light-emitting element LEDc may include the first electrode E1c, an intermediate layer located on the first electrode E1c, and the second electrode E2c located on the intermediate layer. Each of the first electrode E1a, the first electrode E1b, and the first electrode E1c may function as an anode, and each of the second electrode E2a, the second electrode E2b, and the second electrode E2c may function as a cathode.

The first light-emitting element LEDa, the second light-emitting element LEDb, and the third light-emitting element LEDc may emit light of different colors from each other. For example, the first light-emitting element LEDa may emit red light, the second light-emitting element LEDb may emit green light, and the third light-emitting element LEDc may emit blue light. For example, the first light-emitting area EAa may emit red light, the second light-emitting area EAb may emit green light, and the third light-emitting area EAc may emit blue light. For example, the first light-emitting area EAa, the second light-emitting area EAb, and the third light-emitting area EAc may emit light of different colors from each other.

The first light-emitting element LEDa, the second light-emitting element LEDb, and the third light-emitting element LEDc may be connected to the first pixel driving circuit portion PCa, the second pixel driving circuit portion PCb, and the third pixel driving circuit portion PCc, respectively. For example, the first light-emitting element LEDa may be connected to the first pixel driving circuit portion PCa, the second light-emitting element LEDb may be connected to the second pixel driving circuit portion PCb, and the third light-emitting element LEDc may be connected to the third pixel driving circuit portion PCc. Accordingly, the first pixel driving circuit portion PCa and the first light-emitting element LEDa may constitute a single pixel, the second pixel driving circuit portion PCb and the second light-emitting element LEDb may constitute a single pixel, and the third pixel driving circuit portion PCc and the third light-emitting element LEDc may constitute a single pixel.

The display device may include the first connection pattern CNPa, the second connection pattern CNPb, and the third connection pattern CNPc. The first connection pattern CNPa may connect the first light-emitting element LEDa to the first power voltage line LVL1. For example, the first connection pattern CNPa may be connected to the first power voltage line LVL1 through a first contact hole CNT1. In addition, the first connection pattern CNPa may be connected to the second electrode E2a of the first light-emitting element LEDa. The second connection pattern CNPb may connect the second light-emitting element LEDb to the second power voltage line LVL2. For example, the second connection pattern CNPb may be connected to the second power voltage line LVL2 through a third contact hole CNT3. In addition, the second connection pattern CNPb may be connected to the second electrode E2b of the second light-emitting element LEDb. The third connection pattern CNPc may connect the third light-emitting element LEDc to the third power voltage line LVL3. For example, the third connection pattern CNPc may be connected to the third power voltage line LVL3 through a fifth contact hole CNT5. In addition, the third connection pattern CNPc may be connected to the second electrode E2c of the third light-emitting element LEDc.

In one or more embodiments, the first power voltage line LVL1 may apply a first power voltage to the second electrode E2a of the first light-emitting element LEDa. For example, the first power voltage line LVL1 may apply the first power voltage to the second electrode E2a of the first light-emitting element LEDa through the first connection pattern CNPa. In one or more embodiments, the second power voltage line LVL2 may apply a second power voltage to the second electrode E2b of the second light-emitting element LEDb. For example, the second power voltage line LVL2 may apply the second power voltage to the second electrode E2b of the second light-emitting element LEDb through the second connection pattern CNPb. In one or more embodiments, the third power voltage line LVL3 may apply a third power voltage to the second electrode E2c of the third light-emitting element LEDc. For example, the third power voltage line LVL3 may apply the third power voltage to the second electrode E2c of the third light-emitting element LEDc through the third connection pattern CNPc.

In one or more embodiments, a voltage level of the first power voltage and a voltage level of the second power voltage may be different from each other. In addition, the voltage level of the second power voltage and a voltage level of the third power voltage may be different from each other. In addition, the voltage level of the first power voltage and the voltage level of the third power voltage may be different from each other.

In FIGS. 2A and 2B, in order to provide sufficient driving current ID to the light-emitting element LED, the light-emitting element LED needs to have a sufficient driving voltage “V_{oled}”. The driving voltage “V_{oled}” may be determined by difference between the power voltages (i.e., ELVDD-ELVSS). The driving voltages “V_{oled}” required for each of the first light-emitting element LEDa, the second light-emitting element LEDb, and the third light-emitting element LEDc may be different from each other. Accordingly, the difference between the power voltages (i.e., ELVDD-ELVSS) required for each of the first light-emitting element LEDa, the second light-emitting element LEDb, and the third light-emitting element LEDc may be different from each other. According to one or more embodiments of the present disclosure, power voltages having different voltage levels from each other may be applied to each of a plurality of light-emitting elements. For example, the first power voltage may be applied to the second electrode E2a of the first light-emitting element LEDa through the first connection pattern CNPa and the first power voltage line LVL1, the second power voltage may be applied to the second electrode E2b of the second light-emitting element LEDb through the second connection pattern CNPb and the second power voltage line LVL2, and the third power voltage may be applied to the second electrode E2c of the third light-emitting element LEDc through the third connection pattern CNPc and the third power voltage line LVL3. Accordingly, difference between the power voltages (i.e., ELVDD-ELVSS) may be differently set depending on driving voltage “V_{oled}” required for each of the plurality of light-emitting elements. With respect to the display device illustrated in FIGS. 3, 4, 5, 6, and 7, the difference between the power voltages (i.e., ELVDD-ELVSS) may be determined by the voltage level of the low power voltage (i.e., the second power voltage ELVSS of FIGS. 2A and 2B) having a relatively low voltage level. For example, optimized power voltage may be applied to each of the plurality of light-emitting elements. For example, optimized low power voltage (i.e., the second power voltage ELVSS of FIGS. 2A and 2B) may be applied to each of the plurality of light-emitting elements. As power consumed to drive the pixel driving circuit portion (i.e., the first pixel driving circuit portion PCa, the second pixel driving circuit portion PCb, and the third pixel driving circuit portion PCc of FIG. 3) is proportional to the difference between the power voltages (i.e., ELVDD-ELVSS), and as described above, the difference between the power voltages (i.e., ELVDD-ELVSS) may be set differently depending on the driving voltage “V_{oled}” required for each of the plurality of light-emitting elements, power consumption of the display device may be improved.

The first connection pattern CNPa may not overlap the first light-emitting area EAa in a plan view. In one or more embodiments, the first connection pattern CNPa may be around (e.g., may surround) at least a portion of the first light-emitting area EAa in a plan view. For example, the first connection pattern CNPa may have a closed ring shape surrounding the first light-emitting area EAa as a whole in a plan view. However, the present disclosure is not necessarily limited thereto.

In one or more embodiments, a profile in a plan view of an area in which the second electrode E2a of the first light-emitting element LEDa contacts the first connection pattern CNPa may be substantially the same as or similar to a profile in a plan view of an edge of the first connection pattern CNPa. For example, when the first connection pattern CNPa has a closed ring shape that entirely surrounds the first light-emitting area EAa in a plan view, an area in which the second electrode E2a of the first light-emitting element LEDa contacts the first connection pattern CNPa may have a closed ring shape in a plan view. For example, the second electrode E2a of the first light-emitting element LEDa and the first connection pattern CNPa may contact each other at a position that does not overlap the first light-emitting area EAa. Accordingly, the second electrode E2a of the first light-emitting element LEDa and the first power voltage line LVL1 may be connected through the first connection pattern CNPa without reducing light-emitting area of the first light-emitting area EAa.

The second connection pattern CNPb may not overlap the second light-emitting area EAb in a plan view. In one or more embodiments, the second connection pattern CNPb may be around (e.g., may surround) at least a portion of the second light-emitting area EAb in a plan view. For example, the second connection pattern CNPb may have a closed ring shape entirely surrounding the second light-emitting area EAb in a plan view. However, the present disclosure is not necessarily limited thereto.

In one or more embodiments, the second connection pattern CNPb may be spaced (e.g., spaced apart) from the first connection pattern CNPa in a plan view. For example, the first connection pattern CNPa and the second connection pattern CNPb may be separate patterns that are distinguished from each other.

In one or more embodiments, a profile in a plan view of an area in which the second electrode E2b of the second light-emitting element LEDb contacts the second connection pattern CNPb may be substantially the same as or similar to a profile in a plan view of an edge of the second connection pattern CNPb. For example, when the second connection pattern CNPb has a closed ring shape that entirely surrounds the second light-emitting area EAb in a plan view, an area in which the second electrode E2b of the second light-emitting element LEDb contacts the second connection pattern CNPb may have a closed ring shape in a plan view. For example, the second electrode E2b of the second light-emitting element LEDb and the second connection pattern CNPb may contact each other at a position that does not overlap the second light-emitting area EAb. Accordingly, the second electrode E2b of the second light-emitting element LEDb and the second power voltage line LVL2 may be connected through the second connection pattern CNPb without reducing light-emitting area of the second light-emitting area EAb.

The third connection pattern CNPc may not overlap the third light-emitting area EAc in a plan view. In one or more embodiments, the third connection pattern CNPc may be around (e.g., may surround) at least a portion of the third light-emitting area EAc in a plan view. For example, the third connection pattern CNPc may have a closed ring shape entirely surrounding the third light-emitting area EAc in a plan view. However, the present disclosure is not necessarily limited thereto.

In one or more embodiments, the third connection pattern CNPc may be spaced (e.g., spaced apart) from the first connection pattern CNPa and the second connection pattern CNPb. For example, the first connection pattern CNPa, the second connection pattern CNPb, and the third connection pattern CNPc may be separate patterns that are distinguished from each other.

In one or more embodiments, a profile in a plan view of an area in which the second electrode E2c of the third light-emitting element LEDc contacts the third connection pattern CNPc may be substantially the same as or similar to a profile in a plan view of an edge of the third connection pattern CNPc. For example, when the third connection pattern CNPc has a closed ring shape that entirely surrounds the third light-emitting area EAc in a plan view, an area in which the second electrode E2c of the third light-emitting element LEDc contacts the third connection pattern CNPc may have a closed ring shape in a plan view. For example, the second electrode E2c of the third light-emitting element LEDc and the third connection pattern CNPc may contact each other at a position that does not overlap the third light-emitting area EAc. Accordingly, the second electrode E2c of the third light-emitting element LEDc and the third power voltage line LVL3 may be connected through the third connection pattern CNPc without reducing light-emitting area of the third light-emitting area EAc.

According to one or more embodiments of the present disclosure, the second electrodes E2a, E2b, and E2c may contact the connection patterns CNPa, CNPb, and CNPc at positions that do not overlap the light-emitting areas EAa, EAb, and EAc in a plan view, respectively. Accordingly, the second electrodes E2a, E2b, and E2c may contact the connection patterns CNPa, CNPb, and CNPc, respectively, without reducing light-emitting area.

In one or more embodiments, each of the first connection pattern CNPa, the second connection pattern CNPb, and the third connection pattern CNPc may include a transparent conductive oxide. Examples of the transparent conductive oxide that may be used in each of the first connection pattern CNPa, the second connection pattern CNPb, and the third connection pattern CNPc may be Indium gallium zinc oxide (“IGZO”), indium tin zinc oxide (“ITZO”), indium tin oxide (“ITO”), indium zinc oxide (“IZO”), indium gallium oxide (“IGO”), zinc oxide (“ZnO”), indium oxide (“InO”), tin oxide (“SnO”), gallium oxide (“GaO”), aluminum zinc oxide (“AZO”), and/or the like. These materials may be used alone or in combination with each other.

However, the present disclosure is not necessarily limited thereto, and each of the first connection pattern CNPa, the second connection pattern CNPb, and the third connection pattern CNPc may include a conductive material such as a metal, an alloy, a conductive metal nitride, and/or the like. Examples of the conductive material that may be used in each of the first connection pattern CNPa, the second connection pattern CNPb, and the third connection pattern CNPc may include gold (“Au”), silver (“Ag”), aluminum (“Al”), platinum (“Pt”), nickel (“Ni”), titanium (“Ti”), palladium (“Pd”), magnesium (“Mg”), calcium (“Ca”), lithium (“Li”), chromium (“Cr”), tantalum (“Ta”), tungsten (“W”), copper (“Cu”), molybdenum (“Mo”), scandium (“Sc”), neodymium (“Nd”), iridium (“Ir”), an alloy containing aluminum (“Al”,) an alloy containing silver (“Ag”), an alloy containing copper (“Cu”), an alloy containing molybdenum (“Mo”), aluminum nitride (“AlN”), tungsten nitride (“WN”), titanium nitride (“TiN”), chromium nitride (“CrN”), tantalum nitride (“TaN”), and/or the like. These materials may be used alone or in combination with each other.

In one or more embodiments, each of the first connection pattern CNPa, the second connection pattern CNPb, and the third connection pattern CNPc may have a single layer structure or a multilayer structure in which a plurality of conductive layers are stacked.

In addition, in each of the first unit light-emitting areas UEA1, shape and/or arrangement of each of the first connection pattern CNPa, the second connection pattern CNPb, and the third connection pattern CNPc may be the same, and arrangement relationship of the first connection pattern CNPa, the second connection pattern CNPb, and the third connection pattern CNPc may be the same. In addition, in each second unit light-emitting area UEA2, shape and/or arrangement of each of the first connection pattern CNPa, the second connection pattern CNPb, and the third connection pattern CNPc, and arrangement relationship of the first connection pattern CNPa, the second connection pattern CNPb, and the third connection pattern CNPc may be the same.

As described above, the display device may include the separator SPR.

The separator SPR may be located on a pixel defining layer (e.g., a pixel defining layer PDL of FIG. 7), the first connection pattern CNPa, the second connection pattern CNPb, and the third connection pattern CNPc. In one or more embodiments, the separator SPR may include an organic insulating material. For example, the separator SPR may include a photosensitive resin (e.g., photoresist). However, the present disclosure is not necessarily limited thereto.

The separator SPR may overlap the first connection pattern CNPa, the second connection pattern CNPb, and the third connection pattern CNPc in a plan view. For example, the separator SPR may cover a portion of each of the first connection pattern CNPa, the second connection pattern CNPb, and the third connection pattern CNPc and areas between adjacent connection patterns. For example, at least a portion of the separator SPR may extend along edges of the first connection pattern CNPa, the second connection pattern CNPb, and the third connection pattern CNPc in a plan view. Accordingly, areas in which the second electrodes E2a, E2b, and E2c contact the first connection pattern CNPa, the second connection pattern CNPb, and the third connection pattern CNPc, respectively, may be adjacent to or overlap an area in which the separator SPR is located in a plan view.

The separator SPR may define a first open area OA1, a second open area OA2, and a third open area OA3 corresponding to the second electrodes E2a, E2b, and E2c, respectively. For example, the separator SPR may have a mesh structure around (e.g., surrounding) the second electrodes E2a, E2b, and E2c in a plan view. The second electrode E2a of the first light-emitting element LEDa may be located in the first open area OA1 of the separator SPR, and the second electrode E2b of the second light-emitting element LEDb may be located in the second open area OA2 of the separator SPR, and the second electrode E2c of the third light-emitting element LEDc may be located in the third open area OA3 of the separator SPR.

In one or more embodiments, a shape in a plan view of the first open area OA1 may be substantially the same as a shape in a plan view of the second electrode E2a of the first light-emitting element LEDa, a shape in a plan view of the second open area OA2 may be substantially the same as a shape in a plan view of the second electrode E2b of the second light-emitting element LEDb, and a shape in a plan view of the third open area OA3 may be substantially the same as a shape in a plan view of the second electrode E2c of the third light-emitting element LEDc.

The first open area OA1, the second open area OA2, and the third open area OA3 of the separator SPR may correspond to the first connection pattern CNPa, the second connection pattern CNPb, and the third connection pattern CNPc, respectively. For example, the first connection pattern CNPa may overlap the first open area OA1 in a plan view, the second connection pattern CNPb may overlap the second open area OA2 in a plan view, and the third connection pattern CNPc may overlap the third open area OA3 in a plan view.

Hereinafter, a cross-sectional structure of the display device DD with respect to the first light-emitting area EAa will be described in more detail with reference to FIG. 7. Following description of the cross-sectional structure of the display device DD may be equally applied to all light-emitting areas.

Referring further to FIG. 7, the display device DD may include a substrate SUB, a lower conductive layer BML, a transistor TR, a first capacitor CAP1, a second capacitor CAP2, a first insulating layer IL1, a second insulating layer IL2, a third insulating layer IL3, a fourth insulating layer IL4, a fifth insulating layer IL5, a sixth insulating layer IL6, a first connection line CN1, a first connection pattern CNPa, a pixel defining layer PDL, a first light-emitting element LEDa, a separator SPR, a first dummy layer DP1, a second dummy layer DP2, and an encapsulation layer ENC.

The transistor TR may include an active pattern AP, a gate electrode GE, a first contact electrode SE, and a second contact electrode DE. The first capacitor CAP1 may include a first capacitor electrode CPE1 and a second capacitor electrode CPE2. The second capacitor CAP2 may include the first capacitor electrode CPE1 and a third capacitor electrode CPE3. The first light-emitting element LEDa may include a first electrode E1a, an intermediate layer ML, and a second electrode E2a.

The transistor TR, the first capacitor CAP1, and the second capacitor CAP2 may be components included in the first pixel driving circuit portion PCa.

The substrate SUB may be a base of the display device DD. In one or more embodiments, examples of materials that may be used as the substrate SUB may include glass, quartz, silicon, polymer, and/or the like. These materials may be used alone or in combination with each other. In addition, the substrate SUB may have a single layer structure or a multilayer structure in which a plurality of layers including different materials are stacked.

The lower conductive layer BML and the third capacitor electrode CPE3 may be located on the substrate SUB. Each of the lower conductive layer BML and the third capacitor electrode CPE3 may include a conductive material such as a metal, an alloy, a conductive metal oxide, a conductive metal nitride, a transparent conductive oxide, and/or the like. These materials may be used alone or in combination with each other.

The first insulating layer IL1 may be located on the substrate SUB while covering the lower conductive layer BML and the third capacitor electrode CPE3. The first insulating layer IL1 may prevent metal atoms or impurities from being diffused from the substrate SUB into the active pattern AP. For example, the first insulating layer IL1 may include an insulating material. Examples of the insulating material that may be used as the first insulating layer IL1 may include silicon oxide, silicon nitride, silicon nitride oxide, and/or the like. These materials may be used alone or in combination with each other.

The active pattern AP may be located on the first insulating layer IL1. In one or more embodiments, the active pattern AP may overlap the lower conductive layer BML in a plan view and/or in a cross sectional view (e.g., the active pattern AP may overlap the lower conductive layer BML in a third direction DR3, which is a thickness direction of the substrate SUB). For example, the active pattern AP may include an oxide semiconductor material, a silicon semiconductor material, and/or an organic semiconductor material. The active pattern AP may include a first contact area S, a second contact area D, and a channel area CH between the first contact area S and the second contact area D. The first contact area S and the second contact area D may have higher conductivity than the channel area CH.

In one or more embodiments, the active pattern AP may include a silicon semiconductor material. However, the present disclosure is not limited thereto, and in another embodiment, the active pattern AP may include an oxide semiconductor material. Examples of the oxide semiconductor material that may be used as the active pattern AP may include indium gallium zinc oxide (“IGZO”), zinc tin oxide (“ZTO”), indium tin zinc oxide (“ITZO”), and/or the like. These materials may be used alone or in combination with each other.

The second insulating layer IL2 may be located on the first insulating layer IL1 while covering the active pattern AP. The second insulating layer IL2 may include an insulating material. Examples of the insulating material that may be used as the second insulating layer IL2 may include silicon oxide, silicon nitride, silicon nitride oxide, and/or the like. These materials may be used alone or in combination with each other.

The gate electrode GE may be located on the second insulating layer IL2. The gate electrode GE may overlap the channel area CH of the active pattern AP in a plan view and/or in a cross sectional view (e.g., in the third direction DR3). For example, the gate electrode GE may include a conductive material such as a metal, an alloy, a conductive metal oxide, a conductive metal nitride, a transparent conductive oxide, and/or the like. These materials may be used alone or in combination with each other. In one or more embodiments, the gate electrode GE may contact the lower conductive layer BML.

The first capacitor electrode CPE1 may be located on the second insulating layer IL2. The first capacitor electrode CPE1 may overlap the third capacitor electrode CPE3 in a plan view and/or in a cross sectional view (e.g., in the third direction DR3). The first capacitor electrode CPE1 and the third capacitor electrode CPE3 may constitute the second capacitor CAP2. The first capacitor electrode CPE1 may include a conductive material such as a metal, an alloy, a conductive metal oxide, a conductive metal nitride, a transparent conductive oxide, and/or the like. These materials may be used alone or in combination with each other.

The third insulating layer IL3 may be located on the second insulating layer IL2 while covering the gate electrode GE and the first capacitor electrode CPE1. The third insulating layer IL3 may include an insulating material. Examples of the insulating material that may be used as the third insulating layer IL3 may include silicon oxide, silicon nitride, silicon nitride oxide, and/or the like. These materials may be used alone or in combination with each other.

The second capacitor electrode CPE2 may be located on the third insulating layer IL3. The second capacitor electrode CPE2 may overlap the first capacitor electrode CPE1 in a plan view and/or in a cross sectional view (e.g., in the third direction DR3). The first capacitor electrode CPE1 and the second capacitor electrode CPE2 may constitute the first capacitor CAP1. The second capacitor electrode CPE2 may include a conductive material such as a metal, an alloy, a conductive metal oxide, a conductive metal nitride, a transparent conductive oxide, and/or the like. These materials may be used alone or in combination with each other.

The fourth insulating layer IL4 may be located on the third insulating layer IL3 while covering the second capacitor electrode CPE2. The fourth insulating layer IL4 may include an insulating material. Examples of the insulating material that may be used as the fourth insulating layer IL4 may include silicon oxide, silicon nitride, silicon nitride oxide, and/or the like. These materials may be used alone or in combination with each other.

The first contact electrode SE and the second contact electrode DE may be located on the fourth insulating layer IL4. The first contact electrode SE may contact the first contact area S of the active pattern AP, and the second contact electrode DE may contact the second contact area D of the active pattern AP. For example, each of the first contact electrode SE and the second contact electrode DE may include a conductive material such as a metal, an alloy, a conductive metal oxide, a conductive metal nitride, a transparent conductive oxide, and/or the like. These materials may be used alone or in combination with each other.

In one or more embodiments, the first contact electrode SE may contact the lower conductive layer BML. However, the present disclosure is not necessarily limited thereto. For example, when the gate electrode GE contacts the lower conductive layer BML, the first contact electrode SE may not contact the lower conductive layer BML.

The fifth insulating layer IL5 may be located on the fourth insulating layer IL4 while covering the first contact electrode SE and the second contact electrode DE. The fifth insulating layer IL5 may include an insulating material. For example, the fifth insulating layer IL5 may include an organic insulating material. Examples of the organic insulating material that may be used as the fifth insulating layer IL5 may include a resin, a siloxane-based resin, an acrylic-based resin, an epoxy-based resin, and/or the like. These materials may be used alone or in combination with each other.

The first power voltage line LVL1 may be located on the fifth insulating layer IL5. For example, the first power voltage line LVL1 may include a conductive material such as a metal, an alloy, a conductive metal oxide, a conductive metal nitride, a transparent conductive oxide, and/or the like. These materials may be used alone or in combination with each other. In one or more embodiments, the first power voltage line LVL1 may have a single layer structure or a multilayer structure in which a plurality of conductive layers are stacked.

The first connection line CN1 may be located on the fifth insulating layer IL5. The transistor TR and the first electrode E1a of the first light-emitting element LEDa may be connected to each other through the first connection line CN1. For example, the first connection line CN1 may be connected to the transistor TR through a contact hole penetrating (or, defining through) the fifth insulating layer IL5. For example, the first connection line CN1 may be connected to the second contact electrode DE of the transistor TR through the contact hole penetrating (or, defining through) the fifth insulating layer IL5. For example, the first connection line CN1 may include a conductive material such as a metal, an alloy, a conductive metal oxide, a conductive metal nitride, a transparent conductive oxide, and/or the like. These materials may be used alone or in combination with each other.

The sixth insulating layer IL6 may be located on the fifth insulating layer IL5 while covering the first power voltage line LVL1 and the first connection line CN1. In one or more embodiments, the sixth insulating layer IL6 may define a first sub-opening SO1 exposing at least a portion of the first power voltage line LVL1. The sixth insulating layer IL6 may include an insulating material. For example, the sixth insulating layer IL6 may include an organic insulating material. Examples of the organic insulating material that may be used as the sixth insulating layer IL6 may include a resin, a siloxane-based resin, an acrylic-based resin, an epoxy-based resin, and/or the like. These materials may be used alone or in combination with each other.

The first electrode E1a of the first light-emitting element LEDa may be located on the sixth insulating layer IL6. The first electrode Ela of the first light-emitting element LEDa may be connected to the first connection line CN1 through a second contact hole CNT2 penetrating (or, defining through) the sixth insulating layer IL6. For example, the first electrode Ela may include a conductive material such as a metal, an alloy, a conductive metal oxide, a conductive metal nitride, a transparent conductive oxide, and/or the like. These materials may be used alone or in combination with each other.

The pixel defining layer PDL may be located on the sixth insulating layer IL6 and the first electrode Ela of the first light-emitting element LEDa. For example, the pixel defining layer PDL may include an insulating material. The pixel defining layer PDL may define a pixel opening exposing at least a portion of the first electrode Ela. A first light-emitting area EAa may be defined by the pixel opening. The pixel defining layer PDL may further define a second sub-opening SO2 corresponding to the first sub-opening SO1 of the sixth insulating layer IL6. The second sub-opening SO2 may overlap the first sub-opening SO1 in a plan view and/or in a cross sectional view (e.g., in the third direction DR3), and the first sub-opening SO1 and the second sub-opening SO2 may be spatially connected to each other. For example, a first contact hole CNT1 may be defined by the first sub-opening SO1 and the second sub-opening SO2, and the first contact hole CNT1 may expose at least a portion of the first power voltage line LVL1.

The first connection pattern CNPa may be located on the first power voltage line LVL1, the sixth insulating layer IL6, and the pixel defining layer PDL. As described above, the first connection pattern CNPa may be connected to the first power voltage line LVL1. For example, the first connection pattern CNPa may contact the first power voltage line LVL1 through the first contact hole CNT1 penetrating (or, defining through) the sixth insulating layer IL6 and the pixel defining layer PDL. In one or more embodiments, the first connection pattern CNPa may have a single layer structure or a multilayer structure in which a plurality of conductive layers are stacked.

The separator SPR may be located on the pixel defining layer PDL and the first connection pattern CNPa. The separator SPR may overlap the first connection pattern CNPa in a plan view and/or in a cross sectional view (e.g., in the third direction DR3). For example, the separator SPR may cover a portion of the first connection pattern CNPa.

The separator SPR may have a shape in which an upper portion width is greater than a lower portion width. For example, a side surface of the separator SPR connecting an upper surface of the separator SPR and a lower surface of the separator SPR may have an inverted tapered inclined surface. For example, a cross section of at least one portion of the separator SPR may be an inverted trapezoid.

In one or more embodiments, as illustrated in FIG. 7, a side surface of the separator SPR may have a plurality of inverted tapered inclined surfaces. For example, the separator SPR may have a double inverted tapered structure. Accordingly, separation (or disconnection) of the second electrode E2a of the first light-emitting element LEDa by the separator SPR may be more easily implemented.

The intermediate layer ML may be located on the first electrode E1a, the pixel defining layer PDL, and the first connection pattern CNPa. A portion of the intermediate layer ML may be located in the pixel opening of the pixel defining layer PDL. In one or more embodiments, the intermediate layer ML may include a first functional layer including an organic material, a light-emitting layer including a light-emitting material, and a second functional layer including an organic material located on the light-emitting layer. For example, the first functional layer may include a hole injection layer, a hole transport layer, and/or the like, and the second functional layer may include an electron transport layer, an electron injection layer, and/or the like.

A shadow area in which the intermediate layer ML is difficult to be deposited may exist around the separator SPR having the inverted tapered inclined surface. Accordingly, around the shadow area and/or in the shadow area, the intermediate layer ML may have a structure that is separated (or disconnected) by the separator SPR. For example, the first functional layer and the second functional layer included in the intermediate layer ML may have a structure that is separated (or disconnected) by the separator SPR. As the intermediate layer ML has a structure that is separated (or disconnected), the intermediate layer ML may not entirely cover the first connection pattern CNPa. For example, the intermediate layer ML may expose a portion of the first connection pattern CNPa at a position adjacent to or overlapping the separator SPR in a plan view and/or in a cross sectional view. Accordingly, the second electrode E2a of the first light-emitting element LEDa may contact the first connection pattern CNPa.

The first dummy layer DP1 may be located on the separator SPR. The first dummy layer DP1 may be formed as the intermediate layer ML has a structure in which the intermediate layer ML is separated (or disconnected) by the separator SPR. For example, the first dummy layer DP1 may be formed in a same process as the intermediate layer ML. In one or more embodiments, the first dummy layer DP1 may be omitted.

The second electrode E2a of the first light-emitting element LEDa may be located on the intermediate layer ML. For example, the second electrode E2a of the first light-emitting element LEDa may include a conductive material such as a metal, an alloy, a conductive metal oxide, a conductive metal nitride, a transparent conductive oxide, and/or the like. These materials may be used alone or in combination with each other. In one or more embodiments, the second electrode E2a of the first light-emitting element LEDa may have a single layer structure. However, the present disclosure is not necessarily limited thereto, and the second electrode E2a of the first light-emitting element LEDa may have a multi-layer structure in which a plurality of conductive layers are stacked. For example, the second electrode E2a of the first light-emitting element LEDa may have a two-layer structure in which a first sub-electrode layer including a metal and a second sub-electrode layer including a transparent conductive oxide are stacked.

A shadow area where the second electrode E2a of the first light-emitting element LEDa is difficult to be deposited may exist around the separator SPR having the inverted tapered inclined surface. Accordingly, the second electrode E2a of the first light-emitting element LEDa may have a structure separated (or disconnected) by the separator SPR in the shadow area and/or around the shadow area. For example, as illustrated in FIG. 6, the second electrode layer E2 may be separated (or disconnected) into the second electrode E2a of the first light-emitting element LEDa located in the first open area OA1 of the separator SPR, the second electrode E2b of the second light-emitting element LEDb located in the second open area OA2 of the separator SPR, and the second electrode E2c of the third light-emitting element LEDc located in the third open area OA3 of the separator SPR. For example, the second electrodes E2a, E2b, and E2c may be electrically independent from each other.

As illustrated in FIG. 7, the second electrode E2a of the first light-emitting element LEDa may be connected to the first connection pattern CNPa. For example, the second electrode E2a of the first light-emitting element LEDa may contact the first connection pattern CNPa at a position adjacent to or overlapping the separator SPR in a plan view and/or in a cross sectional view. For example, when deposition angle of deposition process of forming the second electrode E2a of the first light-emitting element LEDa is greater than deposition angle of deposition process of forming the intermediate layer ML, the second electrode E2a of the first light-emitting element LEDa may be formed to contact the first connection pattern CNPa while covering disconnected side portion of the intermediate layer ML. As a result, the second electrode E2a of the first light-emitting element LEDa may be connected to the first power voltage line LVL1 through the first connection pattern CNPa.

The second dummy layer DP2 may be located on the separator SPR. For example, the second dummy layer DP2 may be located on the first dummy layer DP1. The second dummy layer DP2 may be formed as the second electrode E2a of the first light-emitting element LEDa has a structure in which the second electrode E2a of the first light-emitting element LEDa is separated (or disconnected) by the separator SPR. For example, the second dummy layer DP2 may be formed in a same process as the second electrode E2a of the first light-emitting element LEDa. In one or more embodiments, the second dummy layer DP2 may be omitted.

The encapsulation layer ENC may be located on the second electrode E2a of the first light-emitting element LEDa. The encapsulation layer ENC may entirely cover the second electrode E2a of the first light-emitting element LEDa, the first connection pattern CNPa, the separator SPR, the first dummy layer DP1, and the second dummy layer DP2. In one or more embodiments, the encapsulation layer ENC may include a first inorganic encapsulation layer IEL1 including an inorganic insulating material, an organic encapsulation layer OEL located on the first inorganic encapsulation layer IEL1 and including an organic insulating material, and a second inorganic encapsulation layer IEL2 located on the organic encapsulation layer OEL including an inorganic insulating material.

In one or more embodiments, a touch sensing layer may be located on the encapsulation layer ENC. For example, the touch sensing layer may include a plurality of touch electrode arrays for sensing a user's input in a capacitive manner, a touch pad portion, and a plurality of touch wires electrically connecting the touch pad portion to the touch electrode arrays. However, the present disclosure is not necessarily limited thereto. In one or more embodiments, the touch sensing layer may be omitted.

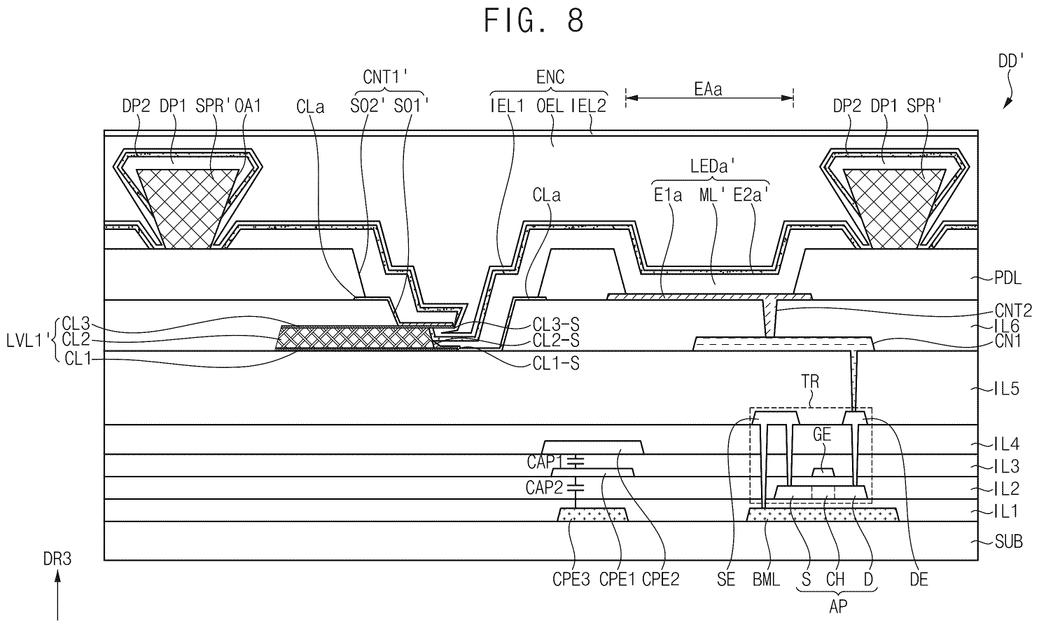

FIG. 8 is a cross-sectional view illustrating a display device according to one or more embodiments.

The display device DD′ according to the embodiment of FIG. 8 may be substantially the same as or similar to the display device DD of FIG. 7 except for configurations of a first power voltage line LVL1′, a first contact hole CNT1′, a first light-emitting element LEDa′, an intermediate electrode CLa, and a separator SPR″. Therefore, redundant descriptions are omitted or simplified.

Referring to FIG. 8, a display device DD′ according to one or more embodiments may include the substrate SUB, the lower conductive layer BML, the transistor TR, the first capacitor CAP1, the second capacitor CAP2, the first insulating layer IL1, the second insulating layer IL2, the third insulating layer IL3, the fourth insulating layer IL4, the fifth insulating layer IL5, the sixth insulating layer IL6, a first power voltage line LVL1′, the first connection line CN1, a first light-emitting element LEDa′, a pixel defining layer PDL, a separator SPR′, the first dummy layer DP1, the second dummy layer DP2, and the encapsulation layer ENC.

The first light-emitting element LEDa′ may include the first electrode E1a, an intermediate layer ML′, and a second electrode E2a′.

The first power voltage line LVL1′ may correspond to the second power voltage line LVL of FIGS. 2A and 2B. In one or more embodiments, the first power voltage line LVL1′ may have a multilayer structure in which a plurality of conductive layers are stacked. For example, the first power voltage line LVL1′ may include a first conductive layer CL1, a second conductive layer CL2, and a third conductive layer CL3, which are sequentially stacked.

In one or more embodiments, the first conductive layer CL1 may include a metal and/or transparent conductive oxide. Examples of the metal that may be used as the first conductive layer CL1 may include titanium (“Ti”), molybdenum (“Mo”), and/or the like. These materials may be used alone or in combination with each other. Examples of the transparent conductive oxide that may be used as the first conductive layer CL1 may include indium tin oxide (“ITO”), indium zinc oxide (“IZO”), zinc oxide (“ZnO”), indium oxide (“InO”), indium gallium oxide (“IGO”), aluminum zinc oxide (“AZO”), and/or the like. These materials may be used alone or in combination with each other. The first conductive layer CL1 may have a relatively thinner thickness than a thickness of the second conductive layer CL2.

The second conductive layer CL2 may include a material different from a material of the first conductive layer CL1. For example, the second conductive layer CL2 may include a metal different from a metal of the first conductive layer CL1. Examples of the metal that may be used as the second conductive layer CL2 may include aluminum (“Al”), copper (“Cu”), and/or the like. These materials may be used alone or in combination with each other. The second conductive layer CL2 may have a relatively thicker thickness than the thickness of the first conductive layer CL1.

The third conductive layer CL3 may include a material different from a material of the second conductive layer CL2. For example, the third conductive layer CL3 may include a metal and/or a transparent conductive oxide different from a metal and/or a transparent conductive oxide of the second conductive layer CL2. Examples of the metal that may be used as the third conductive layer CL3 may include titanium (“Ti”), molybdenum (“Mo”), and/or the like. These materials may be used alone or in combination with each other. Examples of the transparent conductive oxide that may be used as the third conductive layer CL3 may include indium tin oxide (“ITO”), indium zinc oxide (“IZO”), zinc oxide (“ZnO”), indium oxide (“InO”), indium gallium oxide (“IGO”), aluminum zinc oxide (“AZO”), and/or the like. These materials may be used alone or in combination with each other. The third conductive layer CL3 may have a relatively thinner thickness than the thickness of the second conductive layer CL2.

In one or more embodiments, the first conductive layer CL1 and the third conductive layer CL3 may include a same material. However, the present disclosure is not necessarily limited thereto.

A side surface CL2-S of the second conductive layer CL2 may be recessed more toward a center of the first power voltage line LVL1′ than a side surface CL1-S of the first conductive layer CL1 and a side surface CL3-S of the third conductive layer CL3. For example, the side surface CL1-S of the first conductive layer CL1 and the side surface CL3-S of the third conductive layer CL3 may protrude outward than the side surface CL2-S of the second conductive layer CL2. Accordingly, the first power voltage line LVL1′ may have a tip structure by a portion of the third conductive layer CL3 that protrudes from the second conductive layer CL2. For example, when the second conductive layer CL2 is etched using an etching material having a higher etching rate for the second conductive layer CL2 than etching rates for the first conductive layer CL1 and the third conductive layer CL3, the first power voltage line LVL1′ may be formed to have the tip structure.

FIG. 8 may illustrate that the first power voltage line LVL1′ has a three-layer structure in which the first conductive layer CL1, the second conductive layer CL2, and the third conductive layer CL3 are stacked. However, the present disclosure is not limited thereto, and the first power voltage line LVL1′ may have a two-layer structure in which the second conductive layer CL2 and the third conductive layer CL3 are stacked. For example, the first conductive layer CL1 may be omitted.

The sixth insulating layer IL6 may be located on the fifth insulating layer IL5 while partially covering the first power voltage line LVL1. For example, the sixth insulating layer IL6 may define a first sub-opening SO1′ exposing at least a portion of the first power voltage line LVL1′. For example, the first sub-opening SO1′ may expose the tip structure of the first power voltage line LVL1.

The first electrode Ela of the first light-emitting element LEDa′ may be located on the sixth insulating layer IL6. The first electrode Ela of the first light-emitting element LEDa′ may include a conductive material such as a metal, an alloy, a conductive metal oxide, a conductive metal nitride, a transparent conductive material, and/or the like. These materials may be used alone or in combination with each other.

The pixel defining layer PDL may be located on the sixth insulating layer IL6 and the first electrode Ela of the first light-emitting element LEDa′. The pixel defining layer PDL may include an insulating material. The pixel defining layer PDL may define a pixel opening exposing at least a portion of the first electrode Ela of the first light-emitting element LEDa′. The first light-emitting area EAa may be defined by the pixel opening. The pixel defining layer PDL may further define a second sub-opening SO2′ corresponding to the first sub-opening SO1′ of the sixth insulating layer IL6. The second sub-opening SO2′ may overlap the first sub-opening SO1′ in a plan view and/or in a cross sectional view, and the first sub-opening SO1′ and the second sub-opening SO2′ may be spatially connected to each other. For example, a first contact hole CNT1′ may be defined by the first sub-opening SO1′ and the second sub-opening SO2′, and the first contact hole CNT1′ may expose at least a portion of the first power voltage line LVL1′. For example, the first contact hole CNT1′ may expose the tip structure of the first power voltage line LVL1″.

The separator SPR′ may be located on the pixel defining layer PDL. The separator SPR′ may have a shape in which an upper portion width is greater than a lower portion width. For example, a side surface of the separator SPR′ connecting an upper surface of the separator SPR′ and a lower surface of the separator SPR′ may have an inverted tapered inclined surface. For example, a cross section of the separator SPR′ may be an inverted trapezoid.

In FIG. 8, it may be illustrated that the side surface of the separator SPR has one inverted tapered inclined surface. However, the present disclosure is not limited thereto, and the side surface of the separator SPR′ may have a plurality of inverted tapered inclined surfaces. For example, the separator SPR′ may have a double inverted tapered structure.

The intermediate electrode CLa may be located between the pixel defining layer PDL and the sixth insulating layer IL6. The intermediate electrode CLa may contact the first power voltage line LVL1′. For example, the intermediate electrode CLa may contact the first conductive layer CL1 and the second conductive layer CL2. For example, the intermediate electrode CLa may contact the side surface CL1-S of the first conductive layer CL1, an upper surface of the first conductive layer CL1, and the side surface CL2-S of the second conductive layer CL2. The intermediate electrode CLa may be omitted. The intermediate electrode CLa may be separated (or disconnected) by the tip structure of the first power voltage line LVL1′. As the intermediate electrode CLa is separated (or disconnected) by the tip structure of the first power voltage line LVL1′, the intermediate electrode CLa may expose at least a portion of the side surface CL2-S of the second conductive layer CL2. Accordingly, the second electrode E2a′ of the first light-emitting element LEDa′ may contact the side surface CL2-S of the second conductive layer CL2. For example, the intermediate electrode CLa may include a conductive material such as a metal, an alloy, a conductive metal oxide, a conductive metal nitride, a transparent conductive oxide, and/or the like. These materials may be used alone or in combination with each other.

The intermediate layer ML′ may be located on the first electrode Ela of the first light-emitting element LEDa′, and the pixel defining layer PDL. A portion of the intermediate layer ML′ may be located in the pixel opening of the pixel defining layer PDL. In one or more embodiments, the intermediate layer ML′ may include a first functional layer including an organic material, a light-emitting layer including a light-emitting material, and a second functional layer including an organic material located on the light-emitting layer. For example, the first functional layer may include a hole injection layer, a hole transport layer, and/or the like, and the second functional layer may include an electron transport layer, an electron injection layer, and/or the like.

A shadow area in which the intermediate layer ML′ is difficult to be deposited may exist around the separator SPR′ having the inverted tapered inclined surface. Accordingly, the intermediate layer ML′ may have a structure separated (or disconnected) by the separator SPR′ around the shadow area and/or in the shadow area. For example, the first functional layer and the second functional layer included in the intermediate layer ML′ may have a structure separated (or disconnected) by the separator SPR′. The intermediate layer ML′ may also be separated (or disconnected) by the tip structure of the first power voltage line LVL1″.

The first dummy layer DP1 may be located on the separator SPR′. The first dummy layer DP1 may be formed as the intermediate layer ML′ has a structure in which the intermediate layer ML′ is separated (or disconnected) by the separator SPR′. For example, the first dummy layer DP1 may be formed in a same process as the intermediate layer ML. In one or more embodiments, the first dummy layer DP1 may be omitted.

The second electrode E2a′ of the first light-emitting element LEDa′ may be located on the intermediate layer ML. For example, the second electrode E2a′ of the first light-emitting element LEDa′ may include a conductive material such as a metal, an alloy, a conductive metal oxide, a conductive metal nitride, a transparent conductive oxide, and/or the like. These materials may be used alone or in combination with each other. In one or more embodiments, the second electrode E2a′ of the first light-emitting element LEDa′ may have a single layer structure. However, the present disclosure is not necessarily limited thereto, and the second electrode E2a′ of the first light-emitting element LEDa′ may have a multi-layer structure in which a plurality of conductive layers are stacked. For example, the second electrode E2a′ of the first light-emitting element LEDa′ may have a two-layer structure in which a first sub-electrode layer including a metal and a second sub-electrode layer including a transparent conductive oxide are stacked.

A shadow area in which the second electrode E2a′ of the first light-emitting element LEDa′ is difficult to be deposited may exist around the separator SPR′ having the inverted tapered inclined surface. The second electrode E2a′ of the first light-emitting element LEDa′ may have a structure separated (or disconnected) by the separator SPR′ in the shadow area and/or around the shadow area. For example, the second electrode E2a′ of the first light-emitting element LEDa′ may be separated (or disconnected) into the second electrode E2a′ of the first light-emitting element LEDa located in the first open area OA1 of the separator SPR′, the second electrode of the second light-emitting element located in the second open area of the separator SPR′, and the second electrode of the third light-emitting element located in the third open area of the separator SPR′.

As illustrated in FIG. 8, the second electrode E2a′ of the first light-emitting element LEDa′ may be connected to the first power voltage line LVL1′. For example, the second electrode E2a′ of the first light-emitting element LEDa′ may contact the side surface CL2-S of the second conductive layer CL2. For example, when deposition angle of deposition process of forming the second electrode E2a′ of the first light-emitting element LEDa′ is greater than deposition angle of deposition process of forming the intermediate layer ML′, the second electrode E2a′ of the first light-emitting element LEDa′ may be formed to contact the side surface CL2-S of the second conductive layer CL2 while covering the intermediate layer ML′ and the intermediate electrode CLa separated by the tip structure.

In one or more embodiments, the second electrode E2a′ of the first light-emitting element LEDa′ may be separated (or disconnected) by the tip structure of the first power voltage line LVL1′. However, the present disclosure is not limited thereto, and the second electrode E2a′ of the first light-emitting element LEDa′ may be formed to extend without being disconnected by the tip structure.

The second dummy layer DP2 may be located on the separator SPR′. For example, the second dummy layer DP2 may be located on the first dummy layer DP1. The second dummy layer DP2 may be formed as the second electrode E2a′ of the first light-emitting element LEDa′ has a structure in which the second electrode E2a′ is separated (or disconnected) by the separator SPR′. For example, the second dummy layer DP2 may be formed in a same process as the second electrode E2a′ of the first light-emitting element LEDa′. In one or more embodiments, the second dummy layer DP2 may be omitted.

The encapsulation layer ENC may be located on the second electrode E2a′ of the first light-emitting element LEDa′. The encapsulation layer ENC may entirely cover the second electrode E2a′ of the first light-emitting element LEDa′, the separator SPR′, the first dummy layer DP1, and the second dummy layer DP2. In one or more embodiments, the encapsulation layer ENC may include a first inorganic encapsulation layer IEL1 including an inorganic insulating material, an organic encapsulation layer OEL located on the first inorganic encapsulation layer IEL1 and including an organic insulating material, and a second inorganic encapsulation layer IEL2 located on the organic encapsulation layer OEL and including an inorganic insulating material.

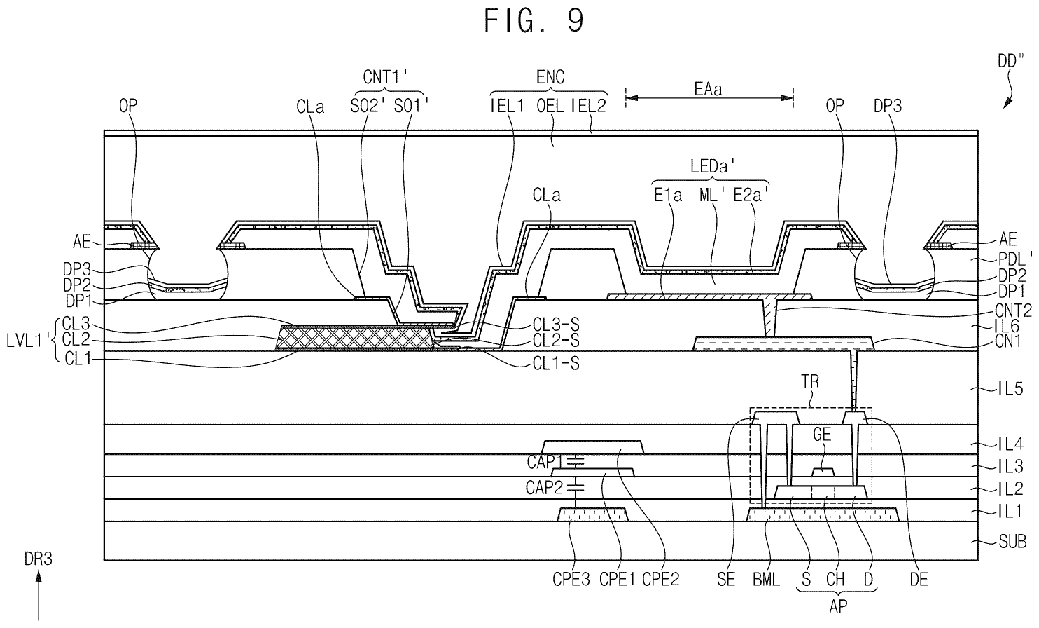

FIG. 9 is a cross-sectional view illustrating a display device according to one or more embodiments.

The display device DD″ of FIG. 9 according to one or more embodiments may be substantially the same as or similar to the display device DD′ of FIG. 8 except for configuration of a pixel defining layer PDL′, an auxiliary electrode AE, and a third dummy layer DP3. Therefore, redundant descriptions are omitted or simplified.

Referring to FIG. 9, a pixel defining layer PDL′ may be located on the sixth insulating layer IL6 and the first electrode Ela of the first light-emitting element LEDa′. The pixel defining layer PDL′ may include an insulating material. The pixel defining layer PDL′ may define a pixel opening exposing at least a portion of the first electrode Ela of the first light-emitting element LEDa′. A first light-emitting area EAa may be defined by the pixel opening. The pixel defining layer PDL′ may further define a second sub-opening SO2′ corresponding to the first sub-opening SO1′ of the sixth insulating layer IL6. The second sub-opening SO2′ may overlap the first sub-opening SO1′ in a plan view and/or in a cross sectional view, and the first sub-opening SO1′ and the second sub-opening SO2′ may be spatially connected to each other. For example, a first contact hole CNT1′ may be defined by the first sub-opening SO1′ and the second sub-opening SO2′, and the first contact hole CNT1′ may expose at least a portion of the first power voltage line LVL1′. For example, the first contact hole CNT1′ may expose the tip structure of the first power voltage line LVL1″.

In one or more embodiments, the pixel defining layer PDL′ may define the opening OP. The opening OP may be located at a position corresponding to the separator SPR′ of FIG. 8. For example, the display device DD″ according to one or more embodiments may include a pixel defining layer PDL′ defining the opening OP instead of including the separator SPR′ of FIG. 8. For example, the opening OP may be spaced (e.g., spaced apart) from each of the first light-emitting area EAa, the second light-emitting area EAb of FIG. 6, and the third light-emitting area EAc of FIG. 6 in a plan view. The intermediate layer ML′ may have a structure separated (or disconnected) by the opening OP. For example, the first functional layer and the second functional layer included in the intermediate layer ML′ may have a structure separated (or disconnected) by the opening OP.

The first dummy layer DP1 may be located in the opening OP. The first dummy layer DP1 may be formed as the intermediate layer ML′ has a structure in which the intermediate layer ML′ is separated (or disconnected) by the opening OP. For example, the first dummy layer DP1 may be formed through a same process as the intermediate layer ML′. In one or more embodiments, the first dummy layer DP1 may be omitted.

The second electrode E2a′ of the first light-emitting element LEDa′ may have a structure separated (or disconnected) by the opening OP. For example, the second electrode E2a′ of the first light-emitting element LEDa′, the second electrode of the second light-emitting element, and the second electrode of the third light-emitting element may be separated (or disconnected).

The second dummy layer DP2 may be located in the opening OP. For example, the second dummy layer DP2 may be located on the first dummy layer DP1. The second dummy layer DP2 may be formed by having a structure in which the second electrode E2a′ of the first light-emitting element LEDa′ is separated (or disconnected) by the opening OP. For example, the second dummy layer DP2 may be formed in a same process as the second electrode E2a′ of the first light-emitting element LEDa′. In one or more embodiments, the second dummy layer DP2 may be omitted.

The encapsulation layer ENC may be separated (or disconnected) by the opening OP. For example, the first inorganic encapsulation layer IEL1 of the encapsulation layer ENC may be separated (or disconnected) by the opening OP.

The third dummy layer DP3 may be located in the opening OP. For example, the third dummy layer DP3 may be located on the second dummy layer DP2. The third dummy layer DP3 may be formed by having a structure in which the first inorganic encapsulation layer IEL1 of the encapsulation layer ENC is separated (or disconnected) by the opening OP. For example, the third dummy layer DP3 may be formed by a same process as the first inorganic encapsulation layer IEL1 of the encapsulation layer ENC. In one or more embodiments, the third dummy layer DP3 may be omitted.

The auxiliary electrode AE may be located on the pixel defining layer PDL″. In one or more embodiments, the auxiliary electrode AE may be around (e.g., may surround) at least a portion of the opening OP in a plan view. For example, the auxiliary electrode AE may include a conductive material such as a metal, an alloy, a conductive metal nitride, and/or the like. These materials may be used alone or in combination with each other. In one or more embodiments, the auxiliary electrode AE may be omitted.

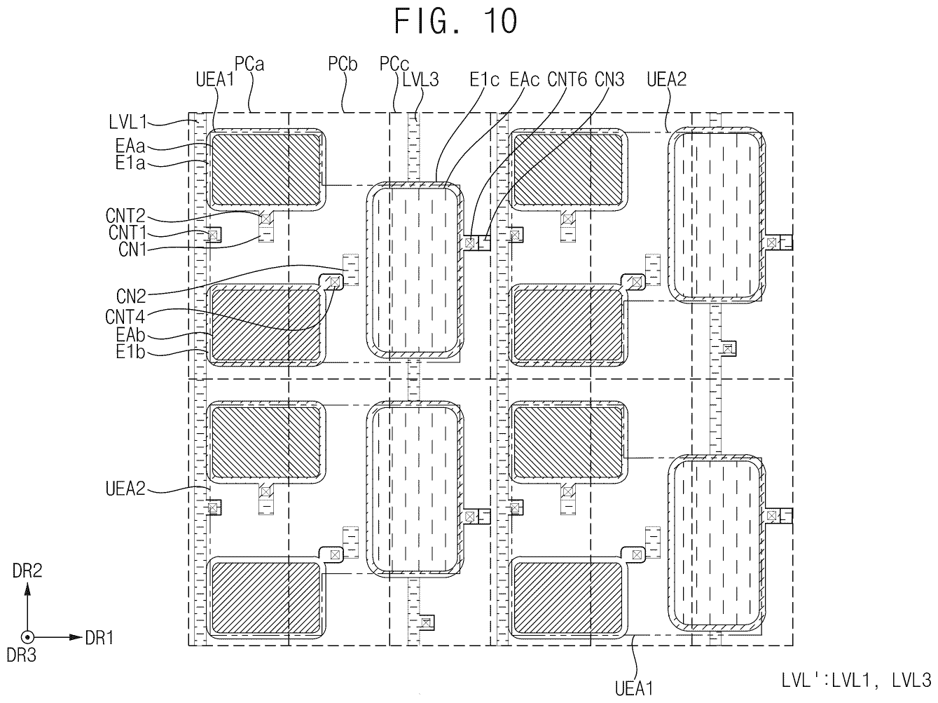

FIGS. 10, 11, and 12 are plan views schematically illustrating another example of a partial area of the display device of FIGS. 1A and 1B.

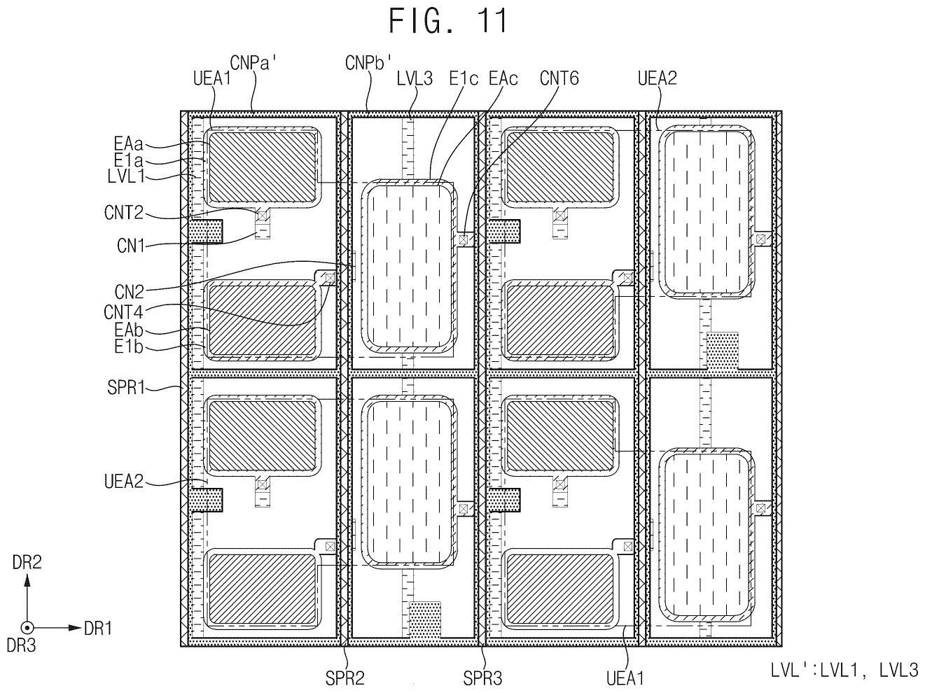

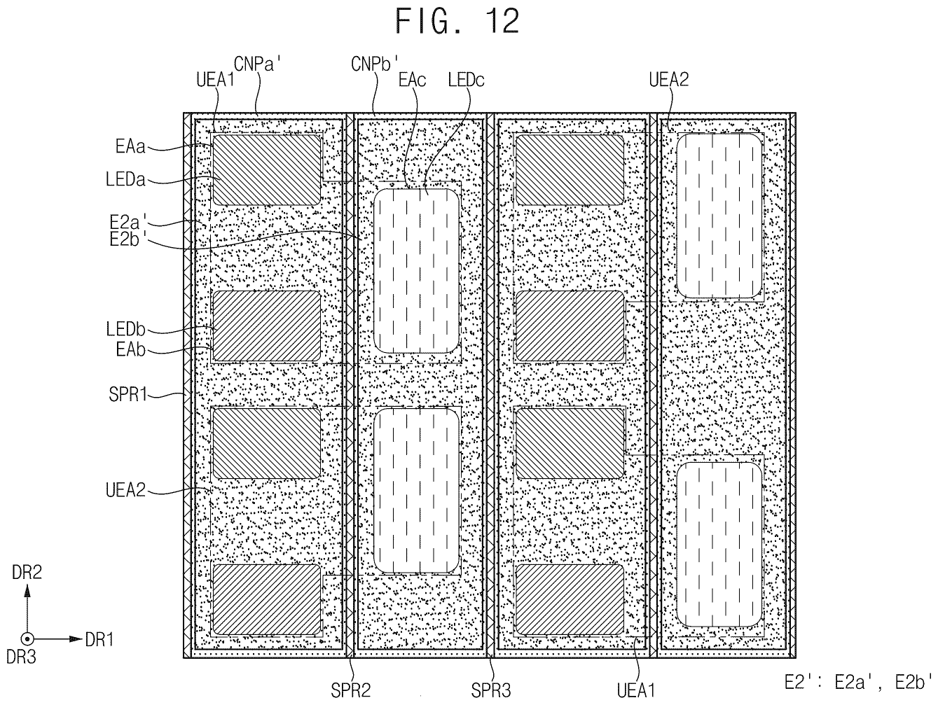

Specifically, in FIGS. 10, 11, and 12, an area in which a total of four unit light-emitting areas UEA1 and UEA2 constituting a matrix of two rows and two columns is arranged may be illustrated. In addition, in FIG. 11, a plurality of separators and a plurality of connection patterns may be located on a plurality of components illustrated in FIG. 10. In addition, in FIG. 12, a plurality of second electrodes may be located on a plurality of components illustrated in FIG. 11.

In describing components illustrated in FIGS. 10, 11, and 12, substantially same reference numerals may be given to components illustrated in FIGS. 3, 4, and 5, and a detailed description thereof may be omitted.

Referring to FIG. 10, the display device (e.g., the display device DD of FIG. 1) may include a first pixel driving circuit portion PCa, a second pixel driving circuit portion PCb, a third pixel driving circuit portion PCc, a power voltage line LVL′, a first connection line CN1, a second connection line CN2, a third connection line CN3, a first electrode E1a, a first electrode E1b, and a first electrode E1c.

Each of the first pixel driving circuit portion PCa, the second pixel driving circuit portion PCb, and the third pixel driving circuit portion PCc may correspond to at least one of the pixel driving circuit portions PC and PC′ described with reference to FIGS. 2A and 2B. For example, each of the first pixel driving circuit portion PCa, the second pixel driving circuit portion PCb, and the third pixel driving circuit portion PCc may correspond to the pixel driving circuit portion PC described with reference to FIG. 2A. For example, each of the first pixel driving circuit portion PCa, the second pixel driving circuit portion PCb, and the third pixel driving circuit portion PCc may include at least one transistor and at least one capacitor. In FIG. 10, the first pixel driving circuit portion PCa, the second pixel driving circuit portion PCb, and the third pixel driving circuit portion PCc may be illustrated to be sequentially arranged along the first direction DR1 in a rectangular shape. However, the present disclosure is not limited thereto, and shapes and arrangements of the first pixel driving circuit portion PCa, the second pixel driving circuit portion PCb, and the third pixel driving circuit portion PCc may be variously changed according to one or more embodiments.

In one or more embodiments, the display device may include a first unit light-emitting area UEA1 and a second unit light-emitting area UEA2. The first unit light-emitting area UEA1 and the second unit light-emitting area UEA2 may be defined in a matrix form along the first direction DR1 and the second direction DR2. Although four unit light-emitting areas are illustrated in FIG. 10, unit light-emitting areas may be defined in a matrix form in the display area DA (e.g., the display area DA of FIGS. 1A and 1B) as a whole.

A first light-emitting area EAa, a second light-emitting area EAb, and a third light-emitting area EAc may be defined in each of the first unit light-emitting area UEA1 and the second unit light-emitting area UEA2. A first light-emitting element (e.g., a first light-emitting element LEDa of FIG. 12) may be located in the first light-emitting area EAa, a second light-emitting element (e.g., a second light-emitting element LEDb of FIG. 12) may be located in the second light-emitting area EAb, and a third light-emitting element (e.g., a third light-emitting element LEDc of FIG. 12) may be located in the third light-emitting area EAc.

Each of the first light-emitting area EAa, the second light-emitting area EAb, and the third light-emitting area EAc may be an area in which light is emitted by light-emitting element. For example, the first light-emitting area EAa may be an area in which light is emitted by the first light-emitting element. In addition, the second light-emitting area EAb may be an area in which light is emitted by the second light-emitting element. In addition, the third light-emitting area EAc may be an area in which light is emitted by the third light-emitting element.

The first electrode Ela may be located in the first light-emitting area EAa. The first electrode Ela may be connected to the first connection line CN1 through a second contact hole CNT2. The first electrode E1b may be located in the second light-emitting area EAb. The first electrode E1b may be connected to the second connection line CN2 through a fourth contact hole CNT4. The first electrode E1c may be located in the third light-emitting area EAc. The first electrode E1c may be connected to the third connection line CN3 through a sixth contact hole CNT6.

The power voltage line LVL′ of FIG. 10 may correspond to the second power voltage line LVL of FIGS. 2A and 2B. For example, the power voltage line LVL′ of FIG. 10 may apply the low power voltage (e.g., the second power voltage ELVSS of FIGS. 2A and 2B) having a relatively low voltage level.

In one or more embodiments, the power voltage line LVL′ may include a first power voltage line LVL1 and a third power voltage line LVL3. Each of the first power voltage line LVL1 and the third power voltage line LVL3 may correspond to the second power voltage line LVL of FIGS. 2A and 2B. For example, each of the first power voltage line LVL1 and the third power voltage line LVL3 may extend in the second direction DR2 and may be arranged along the first direction DR1. For example, the third power voltage line LVL3 may be spaced (e.g., spaced apart) from the first power voltage line LVL1 in the first direction DR1.

The power voltage line LVL′ of FIG. 10 may not include the second power voltage line LVL2 compared to the power voltage line LVL of FIG. 3. For example, the power voltage line LVL′ of FIG. 10 may include two power voltage lines (i.e., the first power voltage line LVL1 and the third power voltage line LVL3). However, the present disclosure is not necessarily limited thereto, and the power voltage line LVL′ of FIG. 10 may not include the first power voltage line LVL1 compared to the power voltage line LVL of FIG. 3. Selectively, the power voltage line LVL′ of FIG. 10 may not include the third power voltage line LVL3 compared to the power voltage line LVL of FIG. 3.

Referring further to FIGS. 11 and 12, the display device may include a first connection pattern CNPa′, a second connection pattern CNPb′, a first separator SPR1, a second separator SPR2, a third separator SPR3, and a second electrode layer E2′.

The second electrode layer E2′ may be separated (or disconnected) into the second electrode E2a′ and the second electrode E2b′ by the second separator SPR2. The second electrode E2a′ and the second electrode E2b′ may be electrically independent from each other.

Each of the first light-emitting element LEDa, the second light-emitting element LEDb, and the third light-emitting element LEDc may correspond to the light-emitting element LED of FIGS. 2A and 2B. For example, the first light-emitting element LEDa may include a first electrode E1a, an intermediate layer located on the first electrode E1a, and a second electrode E2a′ located on the intermediate layer. In addition, the second light-emitting element LEDb may include a first electrode E1b, an intermediate layer located on the first electrode E1b, and a second electrode E2a located on the intermediate layer. In addition, the third light-emitting element LEDc may include a first electrode E1c, an intermediate layer located on the first electrode E1c, and a second electrode E2b′ located on the intermediate layer. Each of the first electrode E1a, the first electrode E1b, and the first electrode E1c may function as an anode, and each of the second electrode E2a′ and the second electrode E2b′ may function as a cathode. The second electrode layer E2′ of FIG. 12 may include only two second electrodes (i.e., the second electrode E2a′ and the second electrode E2b′) compared to the second electrode layer E2 of FIG. 5.

The display device may include the first connection pattern CNPa′ and the second connection pattern CNPb′. The first connection pattern CNPa′ may connect the first light-emitting element LEDa to the first power voltage line LVL1. For example, the first connection pattern CNPa′ may be connected to the first power voltage line LVL1 through a first contact hole CNT1. In addition, the first connection pattern CNPa may be connected to the second electrode E2a′ of the first light-emitting element LEDa. In addition, the first connection pattern CNPa′ may connect the second light-emitting element LEDb to the first power voltage line LVL1. For example, the first connection pattern CNPa′ may be connected to the first power voltage line LVL1 through the first contact hole CNT1 as described above, and may be connected to the second electrode E2a′ of the second light-emitting element LEDb. For example, the first power voltage line LVL1 may apply the low power voltage (e.g., the second power voltage ELVSS of FIGS. 2A and 2B) to two light-emitting elements (e.g., the first light-emitting element LEDa and the second light-emitting element LEDb).

The second connection pattern CNPb′ may connect the third light-emitting element LEDc to the third power voltage line LVL3. For example, the second connection pattern CNPb′ may be connected to the third power voltage line LVL3 through a contact hole. In one or more embodiments, the second connection pattern CNPb′ may be connected to the third power voltage line LVL3 through a contact hole located around a third light-emitting area EAc included in the second unit light-emitting area UEA2 in a second row and a first column. However, the present disclosure is not necessarily limited thereto, and in one or more embodiments, the contact hole connecting the third power voltage line LVL3 and the second connection pattern CNPb′ may be located around the third light-emitting area EAc included in the first unit light-emitting area UEA1 located in a first row and a first column. In addition, the second connection pattern CNPb′ may be connected to the second electrode E2b′ of the third light-emitting element LEDc.

In one or more embodiments, the first power voltage line LVL1 may apply a first power voltage to the second electrode E2a′ of the first light-emitting element LEDa. For example, the first power voltage line LVL1 may apply the first power voltage to the second electrode E2a′ of the first light-emitting element LEDa through the first connection pattern CNPa′. In one or more embodiments, the first power voltage line LVL1 may apply the first power voltage to the second electrode E2a′ of the second light-emitting element LEDb. For example, the first power voltage line LVL1 may apply the first power voltage to the second electrode E2a′ of the second light-emitting element LEDb through the first connection pattern CNPa′. However, in one or more embodiments, the first power voltage line LVL1 may apply the first power voltage to the second electrode E2a′ of the second light-emitting element LEDb through the second connection pattern CNPb′. In one or more embodiments, the third power voltage line LVL3 may apply a second power voltage to the second electrode E2b′ of the third light-emitting element LEDc. For example, the third power voltage line LVL3 may apply the second power voltage to the second electrode E2b′ of the third light-emitting element LEDc through the second connection pattern CNPb′.

In one or more embodiments, a voltage level of the first power voltage and a voltage level of the second power voltage may be different from each other.

In FIGS. 2A and 2B, in order to provide sufficient driving current ID to the light-emitting element LED, the light-emitting element LED needs to have a sufficient driving voltage “V_{oled}”. The driving voltage “V_{oled}” may be determined by difference between the power voltages (i.e., ELVDD-ELVSS). The driving voltages “V_{oled}” required for each of the first light-emitting element LEDa, the second light-emitting element LEDb, and the third light-emitting element LEDc may be different from each other. Accordingly, the difference between the power voltages (i.e., ELVDD-ELVSS) required for each of the first light-emitting element LEDa, the second light-emitting element LEDb, and the third light-emitting element LEDc may be different from each other. According to one or more embodiments of the present disclosure, power voltages having different voltage levels from each other may be applied to each of a plurality of light-emitting elements. For example, the first power voltage may be applied to the second electrode E2a′ of the first light-emitting element LEDa through the first connection pattern CNPa′ and the first power voltage line LVL1, the first power voltage may be applied to the second electrode E2a′ of the second light-emitting element LEDb through the first connection pattern CNPa′ and the first power voltage line LVL1, and the second power voltage may be applied to the second electrode E2b′ of the third light-emitting element LEDc through the second connection pattern CNPb′ and the third power voltage line LVL3. Accordingly, difference between the power voltages (i.e., ELVDD-ELVSS) may be differently set depending on driving voltage “V_{oled}” required for each of the plurality of light-emitting elements. In case of the display devices illustrated in FIGS. 10, 11, and 12, difference between power voltages (i.e., ELVDD-ELVSS) of the third light-emitting element LEDc may be set to be different from difference between power voltages (i.e., ELVDD-ELVSS) of the first light-emitting element LEDa and difference between power voltages (i.e., ELVDD-ELVSS) of the second light-emitting element LEDb. In addition, the difference between the power voltages (i.e., ELVDD-ELVSS) of the first light-emitting element LEDa may be set to be equal to difference between the power voltages (i.e., ELVDD-ELVSS) of the second light-emitting element LEDb. With respect to the display device illustrated in FIGS. 10, 11, and 12, the difference between the power voltages (i.e., ELVDD-ELVSS) may be determined by the voltage level of the low power voltage (i.e., the second power voltage ELVSS of FIGS. 2A and 2B) having a relatively low voltage level. For example, optimized power voltage may be applied to each of the plurality of light-emitting elements. For example, optimized low power voltage (i.e., the second power voltage ELVSS of FIGS. 2A and 2B) may be applied to each of the plurality of light-emitting elements. As power consumed to drive the pixel driving circuit portion (i.e., the first pixel driving circuit portion PCa, the second pixel driving circuit portion PCb, and the third pixel driving circuit portion PCc of FIG. 10) is proportional to the difference between the power voltages (i.e., ELVDD-ELVSS), and as described above, the difference between the power voltages (i.e., ELVDD-ELVSS) may be set differently depending on the driving voltage “V_{oled}” required for each of the plurality of light-emitting elements, power consumption of the display device may be improved.

In one or more embodiments, the first connection pattern CNPa′ may be around (e.g., may surround) at least a portion of the first light-emitting area EAa and at least a portion of the second light-emitting area EAb in a plan view. For example, the first connection pattern CNPa′ may have a closed ring shape that entirely surrounds the first light-emitting area EAa and the second light-emitting area EAb. However, the present disclosure is not necessarily limited thereto.

In one or more embodiments, the second connection pattern CNPb′ may be around (e.g., may surround) at least a portion of the third light-emitting area EAc in a plan view. For example, the second connection pattern CNPb′ may have a closed ring shape entirely surrounding the third light-emitting area EAc. However, the present disclosure is not necessarily limited thereto.

In one or more embodiments, the second connection pattern CNPb′ may be spaced (e.g., spaced apart) from the first connection pattern CNPa′ in a plan view. For example, the first connection pattern CNPa′ and the second connection pattern CNPb″ may be separate patterns that are distinguished from each other.

In one or more embodiments, each of the first connection pattern CNPa′ and the second connection pattern CNPb′ may include a transparent conductive oxide. Examples of the transparent conductive oxide that may be used in each of the first connection pattern CNPa′ and the second connection pattern CNPb′ may be Indium gallium zinc oxide (“IGZO”), indium tin zinc oxide (“ITZO”), indium tin oxide (“ITO”), indium zinc oxide (“IZO”), indium gallium oxide (“IGO”), zinc oxide (“ZnO”), indium oxide (“InO”), tin oxide (“SnO”), gallium oxide (“GaO”), aluminum zinc oxide (“AZO”), and/or the like. These materials may be used alone or in combination with each other.

However, the present disclosure is not necessarily limited thereto, and each of the first connection pattern CNPa′ and the second connection pattern CNPb′ may include a conductive material such as a metal, an alloy, a conductive metal nitride, and/or the like. Examples of the conductive material that may be used in each of the first connection pattern CNPa′ and the second connection pattern CNPb′ may include gold (“Au”), silver (“Ag”), aluminum (“Al”), platinum (“Pt”), nickel (“Ni”), titanium (“Ti”), palladium (“Pd”), magnesium (“Mg”), calcium (“Ca”), lithium (“Li”), chromium (“Cr”), tantalum (“Ta”), tungsten (“W”), copper (“Cu”), molybdenum (“Mo”), scandium (“Sc”), neodymium (“Nd”), iridium (“Ir”), an alloy containing aluminum (“Al”,) an alloy containing silver (“Ag”), an alloy containing copper (“Cu”), an alloy containing molybdenum (“Mo”), aluminum nitride (“AlN”), tungsten nitride (“WN”), titanium nitride (“TiN”), chromium nitride (“CrN”), tantalum nitride (“TaN”), and/or the like. These materials may be used alone or in combination with each other.

In one or more embodiments, each of the first connection pattern CNPa′ and the second connection pattern CNPb′ may have a single layer structure or a multilayer structure in which a plurality of conductive layers are stacked.

In addition, in each of the first unit light-emitting areas UEA1, shape and/or arrangement of each of the first connection pattern CNPa′ and the second connection pattern CNPb′ may be the same, and arrangement relationship of the first connection pattern CNPa′ and the second connection pattern CNPb′ may be the same. In addition, in each second unit light-emitting area UEA2, shape and/or arrangement of each of the first connection pattern CNPa′ and the second connection pattern CNPb and arrangement relationship of the first connection pattern CNPa′ and the second connection pattern CNPb′ may be the same.

As described above, the display device may include the first separator SPR1, the second separator SPR2, and the third separator SPR3.

Each of the first separator SPR1, the second separator SPR2, and the third separator SPR3 may be located on the pixel defining layer, the first connection pattern CNPa′, and the second connection pattern CNPb. In one or more embodiments, each of the first separator SPR1, the second separator SPR2, and the third separator SPR3 may include an organic insulating material. For example, each of the first separator SPR1, the second separator SPR2, and the third separator SPR3 may include a photosensitive resin (for example, a photoresist). However, the present disclosure is not necessarily limited thereto.

Each of the first separator SPR1, the second separator SPR2, and the third separator SPR3 may extend in the second direction DR2. In addition, the first separator SPR1, the second separator SPR2, and the third separator SPR3 may be arranged along the first direction DR1. For example, the second separator SPR2 may be spaced (e.g., spaced apart) from the first separator SPR1 in the first direction DR1, and the third separator SPR3 may be spaced (e.g., spaced apart) from the second separator SPR2 in the first direction DR1.

The first separator SPR1 may at least partially overlap the first connection pattern CNPa′ in a plan view. The second separator SPR2 may at least partially overlap each of the first connection pattern CNPa′ and the second connection pattern CNPb′ in a plan view.

In one or more embodiments, the second electrode E2a′ may be located between the first separator SPR1 and the second separator SPR2 in a plan view. In addition, the second electrode E2b′ may be located between the second separator SPR2 and the third separator SPR3 in a plan view.

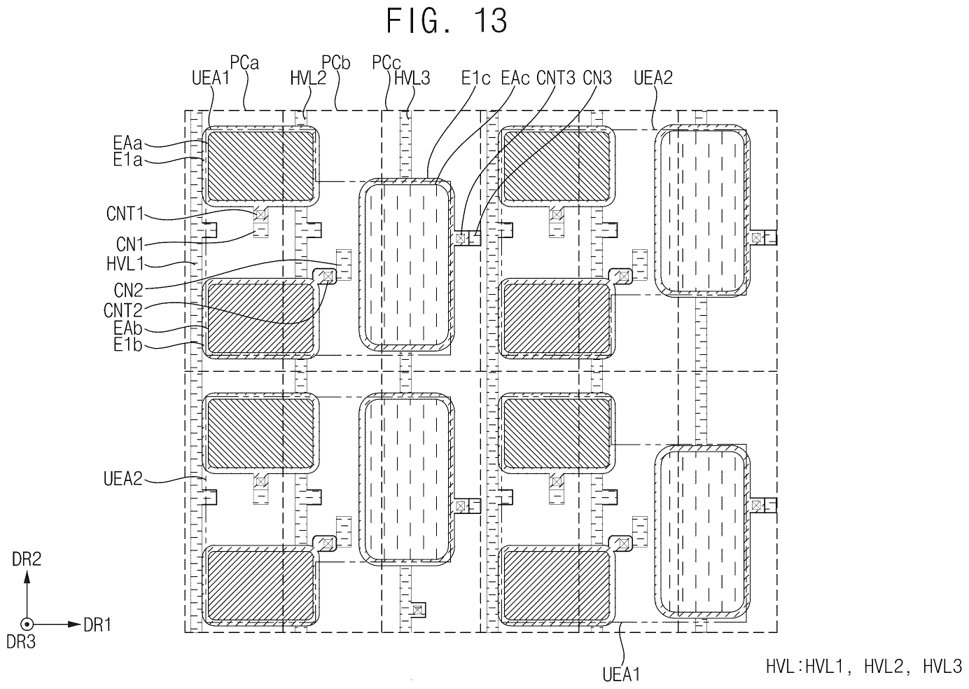

FIG. 13 is a schematic plan view illustrating still another example of a partial area of the display device of FIGS. 1A and 1B.

Specifically, FIG. 13 may illustrate an area in which a total of four unit light-emitting areas UEA1 and UEA2 constituting a matrix of two rows and two columns are arranged.

In describing components illustrated in FIG. 13, same reference numerals may be assigned to components substantially the same as the components illustrated in FIG. 3, and a detailed description thereof may be omitted.

Referring to FIG. 13, the display device (e.g., the display device DD of FIG. 1) may include a first pixel driving circuit portion PCa, a second pixel driving circuit portion PCb, a third pixel driving circuit portion PCc, a power voltage line HVL, a first connection line CN1, a second connection line CN2, a third connection line CN3, a first electrode E1a, a first electrode E1b, and a first electrode E1c.

Each of the first pixel driving circuit portion PCa, the second pixel driving circuit portion PCb, and the third pixel driving circuit portion PCc may correspond to at least one of the pixel driving circuit portions PC and PC′ described with reference to FIGS. 2A and 2B. For example, each of the first pixel driving circuit portion PCa, the second pixel driving circuit portion PCb, and the third pixel driving circuit portion PCc may correspond to the pixel driving circuit portion PC described with reference to FIG. 2A. For example, each of the first pixel driving circuit portion PCa, the second pixel driving circuit portion PCb, and the third pixel driving circuit portion PCc may include at least one transistor and at least one capacitor.

In FIG. 13, the first pixel driving circuit portion PCa, the second pixel driving circuit portion PCb, and the third pixel driving circuit portion PCc may be illustrated to be sequentially arranged along the first direction DR1 in a rectangular shape. However, the present disclosure is not limited thereto, and shapes and arrangements of the first pixel driving circuit portion PCa, the second pixel driving circuit portion PCb, and the third pixel driving circuit portion PCc may be variously changed according to one or more embodiments.

In one or more embodiments, the display device may include a first unit light-emitting area UEA1 and a second unit light-emitting area UEA2. The first unit light-emitting area UEA1 and the second unit light-emitting area UEA2 may be defined in a matrix form along the first direction DR1 and the second direction DR2. Although four unit light-emitting areas are illustrated in FIG. 13, unit light-emitting areas may be defined in a matrix form in the display area DA (e.g., the display area DA of FIGS. 1A and 1B) as a whole. A first light-emitting area EAa, a second light-emitting area EAb, and a third light-emitting area EAc may be defined in each of the first unit light-emitting area UEA1 and the second unit light-emitting area UEA2.

The first electrode Ela may be located in the first light-emitting area EAa. The first electrode Ela may be connected to the first connection line CN1 through a first contact hole CNT1. The first electrode E1b may be located in the second light-emitting area EAb. The first electrode E1b may be connected to the second connection line CN2 through a second contact hole CNT2. The first electrode E1c may be located in the third light-emitting area EAc. The first electrode E1c may be connected to the third connection line CN3 through a third contact hole CNT3.

The power voltage line HVL of FIG. 13 may correspond to the first power voltage line HVL of FIGS. 2A and 2B. That is, for example, the power voltage line HVL of FIG. 13 may apply the high power voltage (e.g., the first power voltage ELVDD of FIGS. 2A and 2B) having a relatively high voltage level.

In one or more embodiments, the power voltage line HVL may include a first power voltage line HVL1, a second power voltage line HVL2, and a third power voltage line HVL3. Each of the first power voltage line HVL1, the second power voltage line HVL2, and the third power voltage line HVL3 may correspond to the first power voltage line HVL of FIGS. 2A and 2B. For example, each of the first power voltage line HVL1, the second power voltage line HVL2, and the third power voltage line HVL3 may extend in the second direction DR2 and may be arranged along the first direction DR1. For example, the second power voltage line HVL2 may be spaced (e.g., spaced apart) from the first power voltage line HVL1 in the first direction DR1, and the third power voltage line HVL3 may be spaced (e.g., spaced apart) from the second power voltage line HVL2 in the first direction DR1.

In one or more embodiments, a first light-emitting element may be located in the first light-emitting area EAa, a second light-emitting element may be located in the second light-emitting area EAb, and a third light-emitting element may be located in the third light-emitting area EAc.

The first light-emitting element may include a first electrode E1a, an intermediate layer located on the first electrode E1a, and a second electrode located on the intermediate layer. The second light-emitting element may include a first electrode E1b, an intermediate layer located on the first electrode E1b, and a second electrode located on the intermediate layer. The third light-emitting element may include a first electrode E1c, an intermediate layer located on the first electrode E1c, and a second electrode located on the intermediate layer. Each of the first electrode E1a, the first electrode E1b, and the first electrode E1c may function as an anode, and each of the second electrode of the first light-emitting element, the second electrode of the second light-emitting element, and the second electrode of the third light-emitting element may function as a cathode.

The first light-emitting element, the second light-emitting element, and the third light-emitting element may emit light of different colors from each other. For example, the first light-emitting element may emit red light, the second light-emitting element may emit green light, and the third light-emitting element may emit blue light. For example, the first light-emitting area EAa may emit red light, the second light-emitting area EAb may emit green light, and the third light-emitting area EAc may emit blue light. For example, the first light-emitting area EAa, the second light-emitting area EAb, and the third light-emitting area EAc may emit light of different colors from each other.

The first light-emitting element, the second light-emitting element, and the third light-emitting element may be connected to the first pixel driving circuit portion PCa, the second pixel driving circuit portion PCb, and the third pixel driving circuit portion PCc, respectively. For example, the first light-emitting element may be connected to the first pixel driving circuit portion PCa, the second light-emitting element may be connected to the second pixel driving circuit portion PCb, and the third light-emitting element may be connected to the third pixel driving circuit portion PCc. Accordingly, the first pixel driving circuit portion PCa and the first light-emitting element may constitute a single pixel, the second pixel driving circuit portion PCb and the second light-emitting element may constitute a single pixel, and the third pixel driving circuit portion PCc and the third light-emitting element may constitute a single pixel.

In one or more embodiments, the first power voltage line HVL1 may apply a first power voltage to the first light-emitting element. For example, the first power voltage line HVL1 may apply the first power voltage to the first electrode Ela of the first light-emitting element. The second power voltage line HVL2 may apply a second power voltage to the second light-emitting element. For example, the second power voltage line HVL2 may apply the second power voltage to the first electrode E1b of the second light-emitting element. The third power voltage line HVL3 may apply a third power voltage to the third light-emitting element. For example, the third power voltage line HVL3 may apply the third power voltage to the first electrode E1c of the third light-emitting element.

When each of the first pixel driving circuit portion PCa, the second pixel driving circuit portion PCb, and the third pixel driving circuit portion PCc is the pixel driving circuit portion PC of FIG. 2A, the first power voltage line HVL1 may apply the first power voltage to the first electrode E1a of the first light-emitting element through the fifth transistor T5, the first transistor T1, and the sixth transistor T6 of FIG. 2A. In addition, the second power voltage line HVL2 may apply the second power voltage to the first electrode E1b of the second light-emitting element through the fifth transistor T5, the first transistor T1, and the sixth transistor T6 of FIG. 2A. In addition, the third power voltage line HVL3 may apply the third power voltage to the first electrode E1c of the third light-emitting element through the fifth transistor T5, the first transistor T1, and the sixth transistor T6 of FIG. 2A.

When each of the first pixel driving circuit portion PCa, the second pixel driving circuit portion PCb, and the third pixel driving circuit portion PCc is the pixel driving circuit portion PC′ of FIG. 2B, the first power voltage line HVL1 may apply the first power voltage to the first electrode Ela of the first light-emitting element through the fourth transistor T4 and the first transistor T1 of FIG. 2B. In addition, the second power voltage line HVL2 may apply the second power voltage to the first electrode E1b of the second light-emitting element through the fourth transistor T4 and the first transistor T1 of FIG. 2B. In addition, the third power voltage line HVL3 may apply the third power voltage to the first electrode E1c of the third light-emitting element through the fourth transistor T4 and the first transistor T1 of FIG. 2B.

In one or more embodiments, a voltage level of the first power voltage and a voltage level of the second power voltage may be different from each other. In addition, the voltage level of the second power voltage and a voltage level of the third power voltage may be different from each other. In addition, the voltage level of the first power voltage and the voltage level of the third power voltage may be different from each other.

In FIGS. 2A and 2B, in order to provide sufficient driving current ID to the light-emitting element LED, the light-emitting element LED needs to have a sufficient driving voltage “V_{oled}”. The driving voltage “V_{oled}” may be determined by difference between the power voltages (i.e., ELVDD-ELVSS). The driving voltages “V_{oled}” required for each of the first light-emitting element, the second light-emitting element, and the third light-emitting element may be different from each other. Accordingly, the difference between the power voltages (i.e., ELVDD-ELVSS) required for each of the first light-emitting element, the second light-emitting element, and the third light-emitting element may be different from each other. According to present disclosure, power voltages having different voltage levels from each other may be applied to each of a plurality of light-emitting elements. For example, in one or more embodiments, the first power voltage may be applied to the second electrode E2a of the first light-emitting element, the second power voltage may be applied to the second electrode E2b of the second light-emitting element, and the third power voltage may be applied to the second electrode E2c of the third light-emitting element. In one or more other embodiments, the first power voltage may be applied to the first electrode E1a of the first light-emitting element, the second power voltage may be applied to the first electrode E1b of the second light-emitting element, and the third power voltage may be applied to the first electrode E1c of the third light-emitting element. Accordingly, difference between the power voltages (i.e., ELVDD-ELVSS) may be differently set depending on driving voltage “V_{oled}” required for each of the plurality of light-emitting elements. With respect to the display device illustrated in FIG. 13, the difference between the power voltages (i.e., ELVDD-ELVSS) may be determined by the voltage level of the high power voltage (i.e., the first power voltage ELVDD of FIGS. 2A and 2B) having a relatively high voltage level. For example, optimized power voltage may be applied to each of the plurality of light-emitting elements. For example, optimized high power voltage (i.e., the first power voltage ELVDD of FIGS. 2A and 2B) may be applied to each of the plurality of light-emitting elements. As power consumed to drive the pixel driving circuit portion (i.e., the first pixel driving circuit portion PCa, the second pixel driving circuit portion PCb, and the third pixel driving circuit portion PCc of FIG. 13) is proportional to the difference between the power voltages (i.e., ELVDD-ELVSS), and as described above, the difference between the power voltages (i.e., ELVDD-ELVSS) may be set differently depending on the driving voltage “V_{oled}” required for each of the plurality of light-emitting elements, power consumption of the display device may be improved.

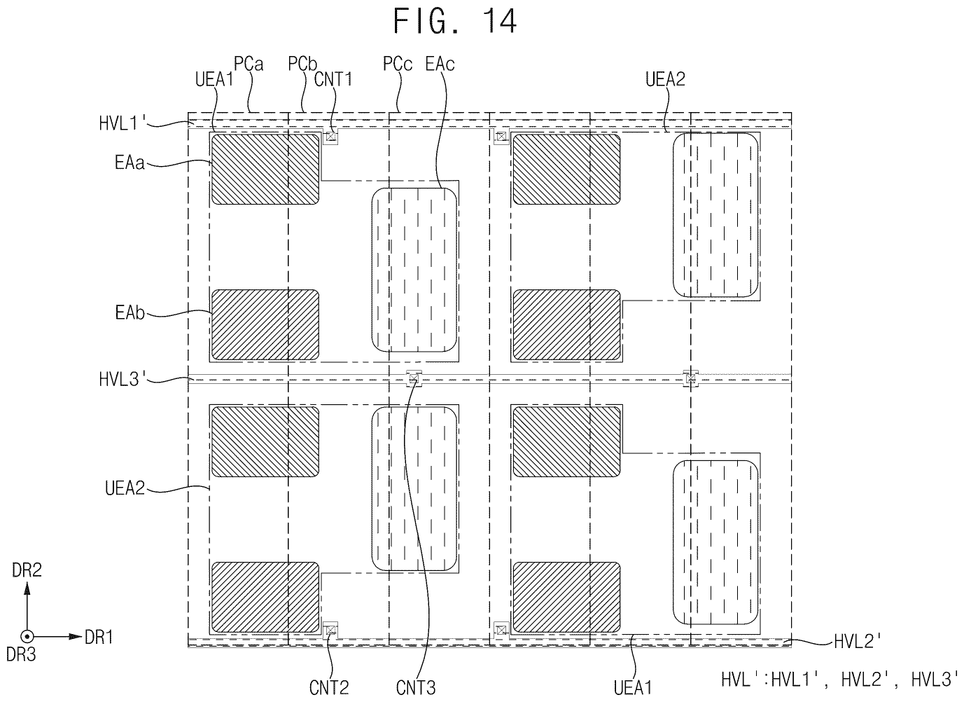

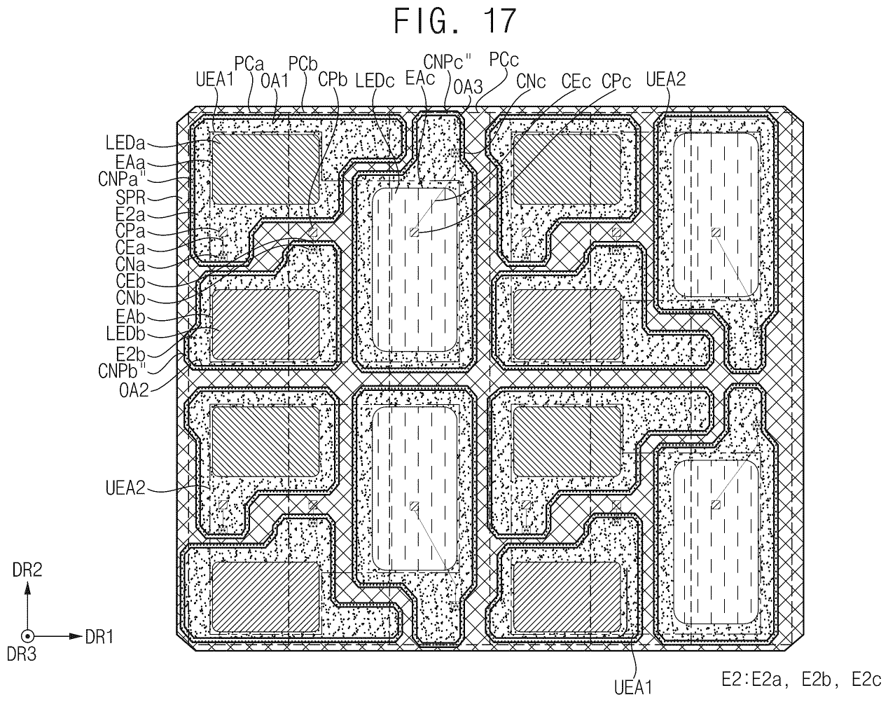

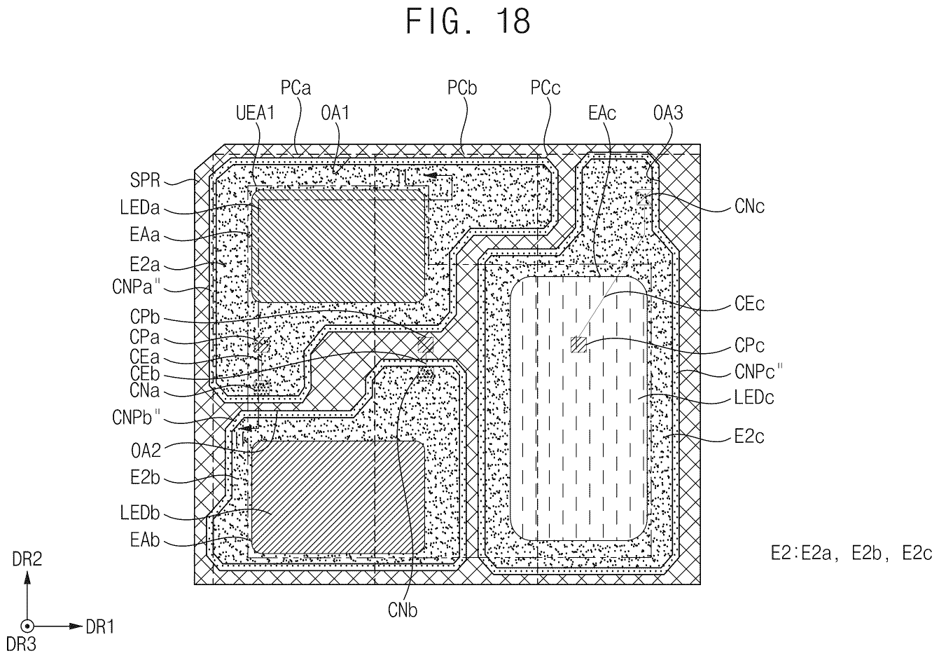

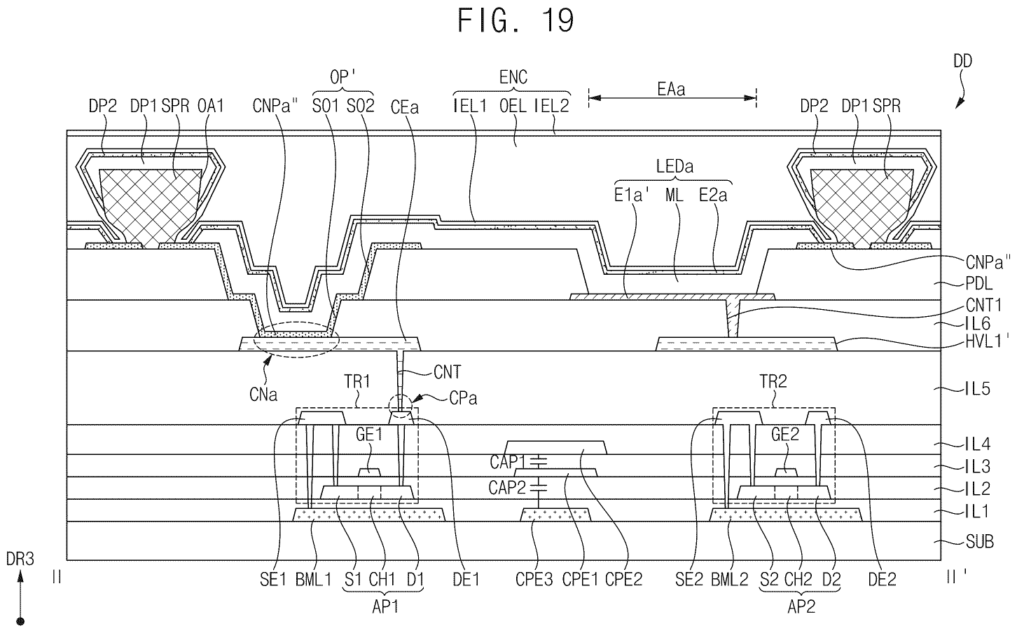

FIGS. 14, 15, 16, and 17 are plan views schematically illustrating still another example of a partial area of the display device of FIGS. 1A and 1B. FIG. 18 is an enlarged view illustrating one unit light-emitting area from among unit light-emitting areas of FIG. 17. FIG. 19 is a cross-sectional view taken along the line II-II′ of FIG. 18.

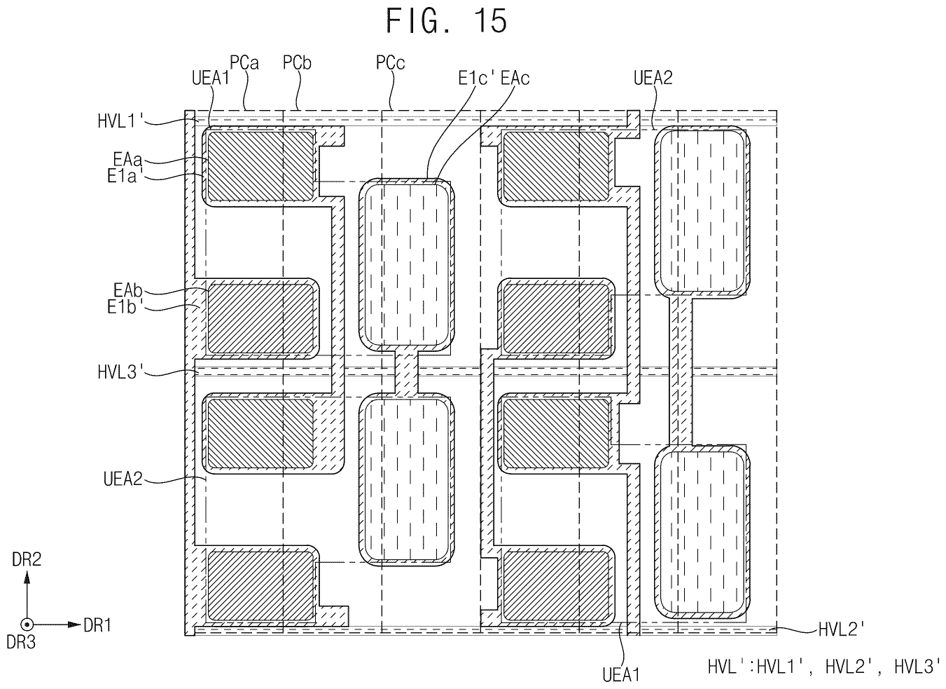

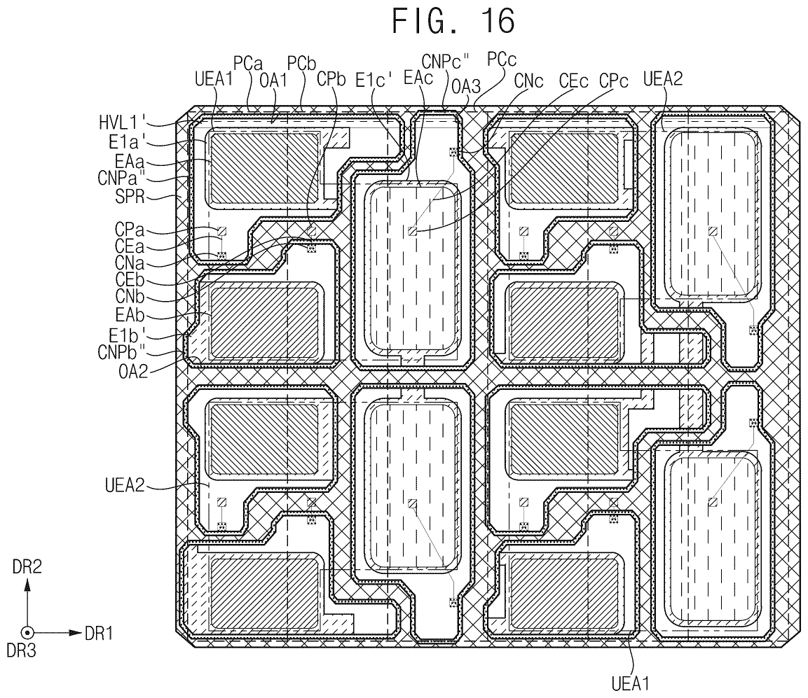

Specifically, in FIGS. 14, 15, 16, and 17, an area in which a total of four unit light-emitting areas UEA1 and UEA2 constituting a matrix of two rows and two columns is arranged may be illustrated. In addition, in FIG. 15, a plurality of first electrodes may be located on a plurality of components illustrated in FIG. 14. In addition, in FIG. 16, a separator SPR and a plurality of connection patterns may be located on a plurality of components illustrated in FIG. 15. In addition, in FIG. 17, second electrodes may be located on a plurality of components illustrated in FIG. 16. In addition, in FIG. 18, one of the first unit light-emitting areas UEA1 from among the unit light-emitting areas UEA1 and UEA2 may be enlarged. For convenience of explanation, FIGS. 14, 15, 16, 17, and 18 may illustrate some components illustrated in FIG. 19 to be omitted or emphasized.

Referring to FIG. 14, the display device (e.g., the display device DD of FIG. 1) may include a first pixel driving circuit portion PCa, a second pixel driving circuit portion PCb, a third pixel driving circuit portion PCc, and a power voltage line HVL″.

Each of the first pixel driving circuit portion PCa, the second pixel driving circuit portion PCb, and the third pixel driving circuit portion PCc may correspond to the pixel driving circuit portion PC″ described with reference to FIG. 2C. For example, each of the first pixel driving circuit portion PCa, the second pixel driving circuit portion PCb, and the third pixel driving circuit portion PCc may include at least one transistor and at least one capacitor. For example, each of the first pixel driving circuit portion PCa, the second pixel driving circuit portion PCb, and the third pixel driving circuit portion PCc may include a first capacitor CAP1 and a first transistor TR1 illustrated in FIG. 19.

In this case, the first transistor TR1 of FIG. 19 may be a transistor connected to the light-emitting element through a connection electrode and a connection pattern. For example, when each of the first pixel driving circuit portion PCa, the second pixel driving circuit portion PCb, and the third pixel driving circuit portion PCc is the pixel driving circuit portion PC″ of FIG. 2C, the first transistor TR1 may be the fifth transistor T5 of FIG. 2C, and the second transistor TR2 may be one of the first to fourth and sixth transistors T1, T2, T3, T4, and T6 of FIG. 2C. However, the present disclosure is not limited thereto.

In one or more embodiments, the first capacitor CAP1 of FIG. 19 may correspond to the first capacitor C1 of FIG. 2C, and the second capacitor CAP2 of FIG. 19 may correspond to the second capacitor C2 of FIG. 2C. However, the present disclosure is not necessarily limited thereto, and in one or more other embodiments, the first capacitor CAP1 of FIG. 19 may correspond to the second capacitor C2 of FIG. 2C, and the second capacitor CAP2 of FIG. 19 may correspond to the first capacitor C1 of FIG. 2C.

Components of the first transistor TR1, the second transistor TR2, the first capacitor CAP1, and the second capacitor CAP2 will be described in more detail with reference to FIG. 19.

In FIG. 14, it is illustrated that the first pixel driving circuit portion PCa, the second pixel driving circuit portion PCb, and the third pixel driving circuit portion PCc are sequentially arranged in a rectangular shape along the first direction DR1. However, the present disclosure is not limited thereto, and shapes and arrangements of the first pixel driving circuit portion PCa, the second pixel driving circuit portion PCb, and the third pixel driving circuit portion PCc may be variously changed according to one or more embodiments.

In one or more embodiments, the display device may include a first unit light-emitting area UEA1 and a second unit light-emitting area UEA2. The first unit light-emitting area UEA1 and the second unit light-emitting area UEA2 may be defined in a matrix form along the first direction DR1 and the second direction DR2. Although four unit light-emitting areas are illustrated in FIG. 14, unit light-emitting areas may be defined in a matrix form in the display area DA (e.g., the display area DA of FIGS. 1A and 1B) as a whole.

A first light-emitting area EAa, a second light-emitting area EAb, and a third light-emitting area EAc may be defined in each of the first unit light-emitting area UEA1 and the second unit light-emitting area UEA2. A first light-emitting element (e.g., the first light-emitting element LEDa of FIG. 17) may be located in the first light-emitting area EAa, a second light-emitting element (e.g., the second light-emitting element LEDb of FIG. 17) may be located in the second light-emitting area EAb, and a third light-emitting element (e.g., the third light-emitting element LEDc of FIG. 17) may be located in the third light-emitting area EAc.

Each of the first light-emitting area EAa, the second light-emitting area EAb, and the third light-emitting area EAc may be defined by a pixel opening of a pixel defining layer (e.g., a pixel defining layer PDL of FIG. 19) to be described later. For example, each of the first light-emitting area EAa, the second light-emitting area EAb, and the third light-emitting area EAc may be an area in which light is emitted by light-emitting element. For example, the first light-emitting area EAa may be an area in which light is emitted by the first light-emitting element. In addition, the second light-emitting area EAb may be an area in which light is emitted by the second light-emitting element. In addition, the third light-emitting area EAc may be an area in which light is emitted by the third light-emitting element.

In one or more embodiments, the first unit light-emitting area UEA1 and the second unit light-emitting area UEA2 may be classified based on an arrangement relationship of the first light-emitting element, the second light-emitting element, and the third light-emitting element (or an arrangement relationship of the first light-emitting area EAa, the second light-emitting area EAb, and the third light-emitting area EAc). For example, the arrangement relationship of the first light-emitting element, the second light-emitting element, and the third light-emitting element (or the first light-emitting area EAa, the second light-emitting area EAb, and the third light-emitting area EAc) may be the same in each first unit light-emitting area UEA1, and the arrangement relationship of the first light-emitting element, the second light-emitting element, and the third light-emitting element (or the first light-emitting area EAa, the second light-emitting area EAb, and the third light-emitting area EAc) may be the same in each second unit light-emitting area UEA2.

As illustrated in FIG. 14, in one or more embodiments, the first unit light-emitting area UEA1 and the second unit light-emitting area UEA2 may be alternately arranged along the first direction DR1 (i.e., a row direction) and the second direction DR2 (i.e., a column direction). However, the present disclosure is not limited thereto, and number of different unit light-emitting areas included in the display device or arrangement relationship of unit light-emitting areas may be variously changed according to one or more embodiments.

It may be illustrated that the first light-emitting area EAa, the second light-emitting area EAb, and the third light-emitting area EAc are arranged in an S-strip type. However, the present disclosure is not limited thereto, and an arrangement relationship of the first light-emitting area EAa, the second light-emitting area EAb, and the third light-emitting area EAc may be variously changed according to one or more embodiments.

The power voltage line HVL′ of FIG. 14 may correspond to the first power voltage line HVL of FIG. 2C. For example, the power voltage line HVL′ of FIG. 14 may apply the high power voltage (e.g., the first power voltage ELVDD of FIG. 2C) having a relatively high voltage level.

In one or more embodiments, the power voltage line HVL′ may include a first power voltage line HVL1′, a second power voltage line HVL2′, and a third power voltage line HVL3′. Each of the first power voltage line HVL1′, the second power voltage line HVL2′, and the third power voltage line HVL3′ may correspond to the first power voltage line HVL of FIG. 2C. For example, each of the first power voltage line HVL1′, the second power voltage line HVL2′, and the third power voltage line HVL3′ may extend in the first direction DR1 and may be arranged along the second direction DR2. For example, the third power voltage line HVL3′ may be spaced (e.g., spaced apart) from the first power voltage line HVL1′ in a direction opposite to the second direction DR2, and may be spaced (e.g., spaced apart) from the second power voltage line HVL2′ in the second direction DR2.

Referring further to FIGS. 15, 16, 17, and 18, the display device may include first electrodes E1a′, E1b′, and E1c′, a separator SPR, a first connection pattern CNPa″, a second connection pattern CNPb″, a third connection pattern CNPc″, a first connection electrode CEa, a second connection electrode CEb, and a third connection electrode CEc.

The second electrode layer E2 may be separated (or disconnected) into the second electrode E2a, the second electrode E2b, and the second electrode E2c by the separator SPR. The second electrode E2a, the second electrode E2b, and the second electrode E2c may be electrically independent from each other.

Each of the first light-emitting element LEDa, the second light-emitting element LEDb, and the third light-emitting element LEDc may correspond to the light-emitting element LED of FIG. 2C. For example, the first light-emitting element LEDa may include the first electrode E1a′, an intermediate layer (e.g., an intermediate layer ML of FIG. 19) located on the first electrode E1a′, and the second electrode E2a located on the intermediate layer. In addition, the second light-emitting element LEDb may include the first electrode E1b′, an intermediate layer located on the first electrode E1b′, and the second electrode E2b located on the intermediate layer. In addition, the third light-emitting element LEDc may include the first electrode E1c′, an intermediate layer located on the first electrode E1c′, and the second electrode E2c located on the intermediate layer. Each of the first electrode E1a′, the first electrode E1b′, and the first electrode E1c′ may function as an anode, and each of the second electrode E2a, the second electrode E2b, and the second electrode E2c may function as a cathode.

In one or more embodiments, the first electrode E1a′ may be continuously located over the first light-emitting area EAa included in the first unit light-emitting area UEA1 and the first light-emitting area included in the second unit light-emitting area UEA2. For example, the first electrode E1a′ may be continuously located over the first light-emitting area EAa included in the first unit light-emitting area UEA1 and the first light-emitting area included in the second unit light-emitting area UEA2 located in the second row and first column. However, the present disclosure is not necessarily limited thereto.

In one or more embodiments, the first electrode E1b′ may be continuously located over the second light-emitting area EAb included in the first unit light-emitting area UEA1 and the second light-emitting area included in the second unit light-emitting area UEA2. For example, the first electrode E1b′ may be continuously located over the second light-emitting area EAb included in the first unit light-emitting area UEA1 and the second light-emitting area included in the second unit light-emitting area UEA2 located in the second row and first column. However, the present disclosure is not necessarily limited thereto.

In one or more embodiments, the first electrode E1c′ may be continuously located over the third light-emitting area EAc included in the first unit light-emitting area UEA1 and the third light-emitting area included in the second unit light-emitting area UEA2. For example, the first electrode E1c′ may be continuously located over the third light-emitting area EAc included in the first unit light-emitting area UEA1 and the third light-emitting area included in the second unit light-emitting area UEA2 located in the second row and first column. However, the present disclosure is not necessarily limited thereto.

The first light-emitting element LEDa, the second light-emitting element LEDb, and the third light-emitting element LEDc may emit light of different colors from each other. For example, the first light-emitting element LEDa may emit red light, the second light-emitting element LEDb may emit green light, and the third light-emitting element LEDc may emit blue light. For example, the first light-emitting area EAa may emit red light, the second light-emitting area EAb may emit green light, and the third light-emitting area EAc may emit blue light. For example, the first light-emitting area EAa, the second light-emitting area EAb, and the third light-emitting area EAc may emit light of different colors from each other.

The first light-emitting element LEDa, the second light-emitting element LEDb, and the third light-emitting element LEDc may be connected to the first pixel driving circuit portion PCa, the second pixel driving circuit portion PCb, and the third pixel driving circuit portion PCc, respectively. For example, the first light-emitting element LEDa may be connected to the first pixel driving circuit portion PCa, the second light-emitting element LEDb may be connected to the second pixel driving circuit portion PCb, and the third light-emitting element LEDc may be connected to the third pixel driving circuit portion PCc. Accordingly, the first pixel driving circuit portion PCa and the first light-emitting element LEDa may constitute a single pixel, the second pixel driving circuit portion PCb and the second light-emitting element LEDb may constitute a single pixel, and the third pixel driving circuit portion PCc and the third light-emitting element LEDc may constitute a single pixel.

In one or more embodiments, the first power voltage line HVL1′ may apply a first power voltage to the first light-emitting element LEDa. For example, the first power voltage line HVL1′ may apply the first power voltage to the first electrode E1a′ of the first light-emitting element LEDa through a first contact hole CNT1. The second power voltage line HVL2′ may apply a second power voltage to the second light-emitting element LEDb. For example, the second power voltage line HVL2′ may apply the second power voltage to the first electrode E1b′ of the second light-emitting element LEDb through the second contact hole CNT2. The third power voltage line HVL3′ may apply a third power voltage to the third light-emitting element LEDc. For example, the third power voltage line HVL3′ may apply the third power voltage to the first electrode E1c′ of the third light-emitting element LEDc through the third contact hole CNT3.

In one or more embodiments, a voltage level of the first power voltage and a voltage level of the second power voltage may be different from each other. In addition, the voltage level of the second power voltage and a voltage level of the third power voltage may be different from each other. In addition, the voltage level of the first power voltage and the voltage level of the third power voltage may be different from each other.

In FIG. 2C, in order to provide sufficient driving current ID to the light-emitting element LED, the light-emitting element LED needs to have a sufficient driving voltage “V_{oled}”. The driving voltage “V_{oled}” may be determined by difference between the power voltages (i.e., ELVDD-ELVSS). The driving voltages “V_{oled}” required for each of the first light-emitting element LEDa, the second light-emitting element LEDb, and the third light-emitting element LEDc may be different from each other. Accordingly, the difference between the power voltages (i.e., ELVDD-ELVSS) required for each of the first light-emitting element LEDa, the second light-emitting element LEDb, and the third light-emitting element LEDc may be different from each other. According to one or more embodiments of the present disclosure, power voltages having different voltage levels from each other may be applied to each of a plurality of light-emitting elements. For example, the first power voltage may be applied to the first electrode E1a′ of the first light-emitting element LEDa, the second power voltage may be applied to the first electrode E1b′ of the second light-emitting element LEDb, and the third power voltage may be applied to the first electrode E1c′ of the third light-emitting element LEDc. Accordingly, difference between the power voltages (i.e., ELVDD-ELVSS) may be differently set depending on driving voltage “V_{oled}” required for each of the plurality of light-emitting elements. With respect to the display device illustrated in FIGS. 14, 15, 16, 17, and 18, the difference between the power voltages (i.e., ELVDD-ELVSS) may be determined by the voltage level of the high power voltage (i.e., the first power voltage ELVDD of FIG. 2C) having a relatively high voltage level. For example, optimized power voltage may be applied to each of the plurality of light-emitting elements. For example, optimized high power voltage (i.e., the first power voltage ELVDD of FIG. 2C) may be applied to each of the plurality of light-emitting elements. As power consumed to drive the pixel driving circuit portion (i.e., the first pixel driving circuit portion PCa, the second pixel driving circuit portion PCb, and the third pixel driving circuit portion PCc of FIG. 14) is proportional to the difference between the power voltages (i.e., ELVDD-ELVSS), and as described above, the difference between the power voltages (i.e., ELVDD-ELVSS) may be set differently depending on the driving voltage “V_{oled}” required for each of the plurality of light-emitting elements, power consumption of the display device may be improved.

As described above with respect to FIGS. 15, 16, 17, and 18, the display device may include the first connection electrode CEa, the second connection electrode CEb, the third connection electrode CEc, the first connection pattern CNPa″, the second connection pattern CNPb″, and the third connection pattern CNPc″. The first connection electrode CEa and the first connection pattern CNPa″ may connect the first light-emitting element LEDa to the first pixel driving circuit portion PCa, and the second connection electrode CEb and the second connection pattern CNPb″ may connect the second light-emitting element LEDb to the second pixel driving circuit portion PCb, and the third connection electrode CEc and the third connection pattern CNPc″ may connect the third light-emitting element LEDc to the third pixel driving circuit portion PCc.

Each of the first connection electrode CEa, the second connection electrode CEb, and the third connection electrode CEc may include a conductive material such as a metal, an alloy, a conductive metal oxide, a conductive metal nitride, a transparent conductive oxide, and/or the like. Examples of the conductive material that may be used in each of the first connection electrode CEa, the second connection electrode CEb, and the third connection electrode CEc may include gold (“Au”), silver (“Ag”), aluminum (“Al”), platinum (“Pt”), nickel (“Ni”), titanium (“Ti”), palladium (“Pd”), magnesium (“Mg”), calcium (“Ca”), lithium (“Li”), chromium (“Cr”), tantalum (“Ta”), tungsten (“W”), copper (“Cu”), molybdenum (“Mo”), scandium (“Sc”), neodymium (“Nd”), iridium (“Ir”), an alloy containing aluminum (“Al”,) an alloy containing silver (“Ag”), an alloy containing copper (“Cu”), an alloy containing molybdenum (“Mo”), aluminum nitride (“AlN”), tungsten nitride (“WN”), titanium nitride (“TiN”), chromium nitride (“CrN”), tantalum nitride (“TaN”), tin oxide (“SnO”), gallium oxide (“GaO”), Indium gallium zinc oxide (“IGZO”), indium tin zinc oxide (“ITZO”), indium tin oxide (“ITO”), indium zinc oxide (“IZO”), indium gallium oxide (“IGO”), zinc oxide (“ZnO”), indium oxide (“InO”), aluminum zinc oxide (“AZO”), and/or the like. These materials may be used alone or in combination with each other. In one or more embodiments, each of the first connection electrode CEa, the second connection electrode CEb, and the third connection electrode CEc may have a single layer structure or a multilayer structure in which a plurality of conductive layers are stacked.

In one or more embodiments, each of the first connection pattern CNPa″, the second connection pattern CNPb″, and the third connection pattern CNPc″ may include a transparent conductive oxide. Examples of the transparent conductive oxide that may be used in each of the first connection pattern CNPa″, the second connection pattern CNPb″, and the third connection pattern CNPc″ may be Indium gallium zinc oxide (“IGZO”), indium tin zinc oxide (“ITZO”), indium tin oxide (“ITO”), indium zinc oxide (“IZO”), indium gallium oxide (“IGO”), zinc oxide (“ZnO”), indium oxide (“InO”), tin oxide (“SnO”), gallium oxide (“GaO”), aluminum zinc oxide (“AZO”), and/or the like. These materials may be used alone or in combination with each other.

However, the present disclosure is not necessarily limited thereto, and each of the first connection pattern CNPa″, the second connection pattern CNPb″, and the third connection pattern CNPc″ may include a conductive material such as a metal, an alloy, a conductive metal nitride, and/or the like.

Examples of the conductive material that may be used in each of the first connection pattern CNPa″, the second connection pattern CNPb″, and the third connection pattern CNPc″ may be gold (“Au”), silver (“Ag”), aluminum (“Al”), platinum (“Pt”), nickel (“Ni”), titanium (“Ti”), palladium (“Pd”), magnesium (“Mg”), calcium (“Ca”), lithium (“Li”), chromium (“Cr”), tantalum (“Ta”), tungsten (“W”), copper (“Cu”), molybdenum (“Mo”), scandium (“Sc”), neodymium (“Nd”), iridium (“Ir”), an alloy containing aluminum (“Al”,) an alloy containing silver (“Ag”), an alloy containing copper (“Cu”), an alloy containing molybdenum (“Mo”), aluminum nitride (“AlN”), tungsten nitride (“WN”), titanium nitride (“TiN”), chromium nitride (“CrN”), tantalum nitride (“TaN”), and/or the like. These materials may be used alone or in combination with each other.

In one or more embodiments, each of the first connection pattern CNPa″, the second connection pattern CNPb″, and the third connection pattern CNPc″ may have a single layer structure or a multilayer structure in which a plurality of conductive layers are stacked.

The first connection electrode CEa may include a first circuit connection portion CPa and a first light-emitting connection portion CNa.

The first circuit connection portion CPa may be a portion of the first connection electrode CEa connected to the first pixel driving circuit portion PCa. For example, the first circuit connection portion CPa may be a portion of the first connection electrode CEa connected to a first transistor (e.g., a first transistor TR1 of FIG. 19) of the first pixel driving circuit portion PCa. Accordingly, a position of the first circuit connection portion CPa may correspond to a position of the first transistor of the first pixel driving circuit portion PCa. For example, a position of the first circuit connection portion CPa may correspond to a position of a contact hole (e.g., a contact hole CNT of FIG. 19) exposing the first transistor of the first pixel driving circuit portion PCa and defining through a fifth insulating layer (e.g., a fifth insulating layer IL5 of FIG. 19).

The first light-emitting connection portion CNa may be a portion of the first connection electrode CEa connected to the first connection pattern CNPa″. For example, the first light-emitting connection portion CNa may be a portion of the first connection electrode CEa exposed from a sixth insulating layer (e.g., a sixth insulating layer IL6 of FIG. 19) and a pixel defining layer (e.g., a pixel defining layer PDL of FIG. 19) in order to contact the first connection pattern CNPa″. Accordingly, a position of the first light-emitting connection portion CNa may correspond to a position of an opening penetrating (or, defining through) the pixel defining layer and the sixth insulating layer and exposing the first connection electrode CEa. The first light-emitting connection portion CNa may not overlap the first light-emitting area EAa in a plan view. For example, the first light-emitting connection portion CNa may be located between the first light-emitting area EAa and the separator SPR in a plan view.

The first connection pattern CNPa″ may be connected to the first connection electrode CEa. For example, the first connection pattern CNPa″ may contact the first light-emitting connection portion CNa of the first connection electrode CEa.

The first connection pattern CNPa″ may not overlap the first light-emitting area EAa in a plan view. In one or more embodiments, the first connection pattern CNPa″ may be around (e.g., may surround) at least a portion of the first light-emitting area EAa in a plan view. For example, the first connection pattern CNPa″ may have a closed ring shape that entirely surrounds the first light-emitting area EAa in a plan view. However, the present disclosure is not necessarily limited thereto.

The second electrode E2a of the first light-emitting element LEDa may be connected to the first connection pattern CNPa″. For example, the second electrode E2a of the first light-emitting element LEDa may contact the first connection pattern CNPa″. Accordingly, the first connection pattern CNPa″ may connect the first connection electrode CEa to the second electrode E2a of the first light-emitting element LEDa. As a result, the second electrode E2a of the first light-emitting element LEDa may be connected to the first pixel driving circuit portion PCa through the first connection electrode CEa and the first connection pattern CNPa″.

In one or more embodiments, a profile a the plan view of an area in which the second electrode E2a of the first light-emitting element LEDa contacts the first connection pattern CNPa″ may be substantially the same as or similar to a profile in a plan view of an edge of the first connection pattern CNPa″. For example, when the first connection pattern CNPa″ has a closed ring shape that entirely surrounds the first light-emitting area EAa in the plan view, an area in which the second electrode E2a of the first light-emitting element LEDa contacts the first connection pattern CNPa″ may have a closed ring shape in a plan view. For example, the second electrode E2a of the first light-emitting element LEDa and the first connection pattern CNPa″ may contact each other at a position that does not overlap the first light-emitting area EAa. Accordingly, the second electrode E2a of the first light-emitting element LEDa and the first pixel driving circuit portion PCa may be connected through the first connection pattern CNPa″ and the first connection electrode CEa without reducing light-emitting area of the first light-emitting area EAa.

The second connection electrode CEb may include a second circuit connection portion CPb and a second light-emitting connection portion CNb.

The second circuit connection portion CPb may be a portion of the second connection electrode CEb connected to the second pixel driving circuit portion PCb. For example, the second circuit connection portion CPb may be a portion of the second connection electrode CEb connected to the first transistor of the second pixel driving circuit portion PCb. Accordingly, a position of the second circuit connection portion CPb may correspond to a position of the first transistor of the second pixel driving circuit portion PCb. For example, a position of the second circuit connection portion CPb may correspond to a position of a contact hole exposing the first transistor of the second pixel driving circuit portion PCb and defining through the fifth insulating layer (e.g., the fifth insulating layer IL5 of FIG. 19).

The second light-emitting connection portion CNb may be a portion of the second connection electrode CEb connected to the second connection pattern CNPb″. For example, the second light-emitting connection portion CNb may be a portion of the second connection electrode CEb exposed from the sixth insulating layer and the pixel defining layer in order to contact the second connection pattern CNPb″. Accordingly, a position of the second light-emitting connection portion CNb may correspond to a position of an opening penetrating (or, defining through) the pixel defining layer and the sixth insulating layer and exposing the second connection electrode CEb. The second light-emitting connection portion CNb may not overlap the second light-emitting area EAb in a plan view. For example, the second light-emitting connection portion CNb may be located between the second light-emitting area EAb and the separator SPR in a plan view.

In one or more embodiments, the second connection electrode CEb may be spaced (e.g., spaced apart) from the first connection electrode CEa in a plan view. For example, the first connection electrode CEa and the second connection electrode CEb may be different electrodes that are distinguished from each other.

The second connection pattern CNPb″ may be connected to the second connection electrode CEb. For example, the second connection pattern CNPb″ may contact the second light-emitting connection portion CNb of the second connection electrode CEb.

The second connection pattern CNPb″ may not overlap the second light-emitting area EAb in a plan view. In one or more embodiments, the second connection pattern CNPb″ may be around (e.g., surround) at least a portion of the second light-emitting area EAb in a plan view. For example, the second connection pattern CNPb″ may have a closed ring shape entirely surrounding the second light-emitting area EAb in a plan view. However, the present disclosure is not necessarily limited thereto.

In one or more embodiments, the second connection pattern CNPb″ may be spaced (e.g., spaced apart) from the first connection pattern CNPa″. For example, the first connection pattern CNPa″ and the second connection pattern CNPb″ may be separate patterns that are distinguished from each other.

The second electrode E2b of the second light-emitting element LEDb may be connected to the second connection pattern CNPb″. For example, the second electrode E2b of the second light-emitting element LEDb may contact the second connection pattern CNPb″. Accordingly, the second connection pattern CNPb″ may connect the second connection electrode CEb to the second electrode E2b of the second light-emitting element LEDb. As a result, the second electrode E2b of the second light-emitting element LEDb may be connected to the second pixel driving circuit portion PCb through the second connection electrode CEb and the second connection pattern CNPb″.

In one or more embodiments, a profile in a plan view of an area in which the second electrode E2b of the second light-emitting element LEDb contacts the second connection pattern CNPb″ may be substantially the same as or similar to a profile in a plan view of an edge of the second connection pattern CNPb″. For example, when the second connection pattern CNPb″ has a closed ring shape that entirely surrounds the second light-emitting area EAb in a plan view, an area in which the second electrode E2b of the second light-emitting element LEDb contacts the second connection pattern CNPb″ may have a closed ring shape in a plan view. For example, the second electrode E2b of the second light-emitting element LEDb and the second connection pattern CNPb″ may contact each other at a position that does not overlap the second light-emitting area EAb in a plan view. Accordingly, the second electrode E2b of the second light-emitting element LEDb and the second pixel driving circuit portion PCb may be connected to each other through the second connection pattern CNPb″ and the second connection electrode CEb without reducing light-emitting area of the second light-emitting area EAb.

The third connection electrode CEc may include a third circuit connection portion CPc and a third light-emitting connection portion CNc.

The third circuit connection portion CPc may be a portion of the third connection electrode CEc connected to the third pixel driving circuit portion PCc. For example, the third circuit connection portion CPc may be a portion of the third connection electrode CEc connected to the first transistor of the third pixel driving circuit portion PCc. Accordingly, a position of the third circuit connection portion CPc may correspond to a position of the first transistor of the third pixel driving circuit portion PCc. For example, a position of the third circuit connection portion CPc may correspond to a position of a contact hole exposing the first transistor of the third pixel driving circuit portion PCc and penetrating (or, defining through) the fifth insulating layer.

The third light-emitting connection portion CNc may be a portion of the third connection electrode CEc connected to the third connection pattern CNPc″. For example, the third light-emitting connection portion CNc may be a portion of the third connection electrode CEc exposed from the sixth insulating layer and the pixel defining layer in order to contact the third connection pattern CNPc″. Accordingly, a position of the third light-emitting connection portion CNc may correspond to a position of an opening penetrating (or, defining through) the pixel defining layer and the sixth insulating layer and exposing the third connection electrode CEc. The third light-emitting connection portion CNc may not overlap the third light-emitting area EAc in a plan view. For example, the third light-emitting connection portion CNc may be located between the third light-emitting area EAc and the separator SPR in a plan view.

In one or more embodiments, the third connection electrode CEc may be spaced (e.g., spaced apart) from the first connection electrode CEa and the second connection electrode CEb in a plan view. For example, the first connection electrode CEa, the second connection electrode CEb, and the third connection electrode CEc may be different electrodes that are distinguished from each other.

The third connection pattern CNPc″ may be connected to the third connection electrode CEc. For example, the third connection pattern CNPc″ may contact the third light-emitting connection portion CNc of the third connection electrode CEc.

The third connection pattern CNPc″ may not overlap the third light-emitting area EAc in a plan view. In one or more embodiments, the third connection pattern CNPc″ may be around (e.g., may surround) at least a portion of the third light-emitting area EAc in a plan view. For example, the third connection pattern CNPc″ may have a closed ring shape that entirely surrounds the third light-emitting area EAc in a plan view. However, the present disclosure is not necessarily limited thereto.

In one or more embodiments, the third connection pattern CNPc″ may be spaced (e.g., spaced apart) from the first connection pattern CNPa″ and the second connection pattern CNPb″. For example, the first connection pattern CNPa″, the second connection pattern CNPb″, and the third connection pattern CNPc″ may be separate patterns that are distinguished from each other.

The second electrode E2c of the third light-emitting element LEDc may be connected to the third connection pattern CNPc″. For example, the second electrode E2c of the third light-emitting element LEDc may contact the third connection pattern CNPc″. Accordingly, the third connection pattern CNPc″ may connect the third connection electrode CEc to the second electrode E2c of the third light-emitting element LEDc. As a result, the second electrode E2c of the third light-emitting element LEDc may be connected to the third pixel driving circuit portion PCc through the third connection electrode CEc and the third connection pattern CNPc″.

In one or more embodiments, a profile in a plan view of an area in which the second electrode E2c of the third light-emitting element LEDc contacts the third connection pattern CNPc″ may be substantially the same as or similar to a profile in a plan view of an edge of the third connection pattern CNPc″. For example, when the third connection pattern CNPc″ has a closed ring shape that entirely surrounds the third light-emitting area EAc in a plan view, an area in which the second electrode E2c of the third light-emitting element LEDc contacts the third connection pattern CNPc″ may have a closed ring shape in a plan view. For example, the second electrode E2c of the third light-emitting element LEDc and the third connection pattern CNPc″ may contact each other at a position that does not overlap the third light-emitting area EAc in a plan view. Accordingly, the second electrode E2c of the third light-emitting element LEDc and the third pixel driving circuit portion PCc may be connected to each other through the third connection pattern CNPc″ and the third connection electrode CEc without reducing light-emitting area of the third light-emitting area EAc.

According to present disclosure, the second electrodes E2a, E2b, and E2c may contact the connection patterns CNPa″, CNPb″, and CNPc″ at positions that do not overlap the light-emitting regions EAa, EAb, and EAc, respectively, in a plan view. Accordingly, the second electrodes E2a, E2b, and E2c may contact the connection patterns CNPa″, CNPb″, and CNPc″ in a plan view without reducing light-emitting area.

In addition, according to present disclosure, the second electrodes E2a, E2b, and E2c may be connected to the pixel driving circuit portions PCa, PCb, and PCc through connection electrodes CEa, CEb, and CEc and connection patterns CNPa″, CNPb″, and CNPc″, respectively. Accordingly, restrictions by positions, shapes, and sizes of the light-emitting areas EAa, EAb, and EAc may be reduced in design of the pixel driving circuit portions PCa, PCb, and PCc. For example, even when at least some of the circuit connection portions CPa, CPb, and CPc overlap the light-emitting areas EAa, EAb, and EAc in a plan view, the second electrodes E2a, E2b, and E2c may be easily connected to the pixel driving circuit portions PCa, PCb, and PCc through connection electrodes CEa, CEb, and CEc and connection patterns CNPa″, CNPb″, and CNPc″. Accordingly, shape and arrangement of the pixel driving circuit portions PCa, PCb, and PCc may be designed independently of positions, shapes, and/or sizes of the light-emitting areas EAa, EAb, and EAc. Accordingly, degree of freedom in design of the pixel driving circuit portions PCa, PCb, and PCc may be improved.

In one or more embodiments, the first to third pixel driving circuit portions PCa, PCb, and PCc may be designed to be same to each other regardless of positions, shapes, sizes, and/or the like of the light-emitting areas EAa, EAb, and EAc. In addition, as described above, a position of the first circuit connection portion CPa may correspond to a position of the first transistor of the first pixel driving circuit portion PCa, a position of the second circuit connection portion CPb may correspond to a position of the first transistor of the second pixel driving circuit portion PCb, and a position of the third circuit connection portion CPc may correspond to a position of the first transistor of the third pixel driving circuit portion PCc. Accordingly, when the first to third pixel driving circuit portions PCa, PCb, and PCc have substantially the same size and are arranged along the first direction DR1, position of the first circuit connection portion CPa, position of the second circuit connection portion CPb, and position of the third circuit connection portion CPc may be aligned along the first direction DR1.

As illustrated in FIG. 17, shape and/or arrangement of each of the first to third connection electrodes CEa, CEb, and CEc may be the same in each first unit light-emitting area UEA1, and arrangement relationship between the first to third connection electrodes CEa, CEb, and CEc may be the same in each first unit light-emitting area UEA1. In addition, shape and/or arrangement of each of the first to third connection electrodes CEa, CEb, and CEc may be the same in each second unit light-emitting area UEA2, and arrangement relationship between the first to third connection electrodes CEa, CEb, and CEc may be the same in each second unit light-emitting area UEA2.

In addition, shape and/or arrangement of each of the first to third connection patterns CNPa″, CNPb″, and CNPc″ may be the same in each first unit light-emitting area UEA1, and the arrangement relationship between the first to third connection patterns CNPa″, CNPb″, and CNPc″ may be the same in each first unit light-emitting area UEA1. In addition, shape and/or arrangement of each of the first to third connection patterns CNPa″, CNPb″, and CNPc″ may be the same in each second unit light-emitting area UEA2, and arrangement relationship between the first to third connection patterns CNPa″, CNPb″, and CNPc″ may be the same in each second unit light-emitting area UEA2.

As described above, the display device DD may include the separator SPR.

The separator SPR may be located on a pixel defining layer (e.g., a pixel defining layer PDL of FIG. 19), the first connection pattern CNPa″, the second connection pattern CNPb″, and the third connection pattern CNPc″. In one or more embodiments, the separator SPR may include an organic insulating material. For example, the separator SPR may include a photosensitive resin (e.g., photoresist). However, the present disclosure is not necessarily limited thereto.

The separator SPR may overlap the first connection pattern CNPa″, the second connection pattern CNPb″, and the third connection pattern CNPc″ in a plan view. For example, the separator SPR may cover portions of the first connection pattern CNPa″, the second connection pattern CNPb″, and third connection patterns CNPc″ and areas between adjacent connection patterns. For example, at least a portion of the separator SPR may extend along edges of the first connection pattern CNPa″, the second connection pattern CNPb″, and the third connection pattern CNPc″ in a plan view. Accordingly, areas in which the second electrodes E2a, E2b, and E2c contact the first connection pattern CNPa″, the second connection pattern CNPb″, and the third connection pattern CNPc″, respectively, may be adjacent to or overlap an area in which the separator SPR is located in a plan view.

The second electrode layer E2 may be separated (or disconnected) into the second electrodes E2a, E2b, and E2c by the separator SPR. For example, the second electrode E2a of the first light-emitting element LEDa, the second electrode E2b of the second light-emitting element LEDb, and the second electrode E2c of the third light-emitting element LEDc may be electrically independent from each other by the separator SPR.

The separator SPR may define a first open area OA1, a second open area OA2, and a third open area OA3 corresponding to the second electrodes E2a, E2b, and E2c, respectively. For example, the separator SPR may have a mesh structure around (e.g., surrounding) the second electrodes E2a, E2b, and E2c in a plan view. The second electrode E2a of the first light-emitting element LEDa may be located in the first open area OA1 of the separator SPR, and the second electrode E2b of the second light-emitting element LEDb may be located in the second open area OA2 of the separator SPR, and the second electrode E2c of the third light-emitting element LEDc may be located in the third open area OA3 of the separator SPR.

In one or more embodiments, a shape in a plan view of the first open area OA1 may be substantially the same as a shape in a plan view of the second electrode E2a of the first light-emitting element LEDa, a shape in a plan view of the second open area OA2 may be substantially the same as a shape in a plan view of the second electrode E2b of the second light-emitting element LEDb, and a shape in a plan view of the third open area OA3 may be substantially the same as a shape in a plan view of the second electrode E2c of the third light-emitting element LEDc.

The first open area OA1, the second open area OA2, and the third open area OA3 of the separator SPR may correspond to the first connection pattern CNPa″, the second connection pattern CNPb″, and the third connection pattern CNPc″, respectively. For example, the first connection pattern CNPa″ may overlap the first open area OA1 in a plan view, the second connection pattern CNPb″ may overlap the second open area OA2 in a plan view, and the third connection pattern CNPc″ may overlap the third open area OA3 in a plan view.

Hereinafter, a cross-sectional structure of the display device DD with respect to the first light-emitting area EAa will be described in more detail with reference to FIG. 19. Following description of the cross-sectional structure of the display device DD may be equally applied to all light-emitting areas.

Referring further to FIG. 19, the display device DD may include a substrate SUB, a first lower conductive layer BML1, a second lower conductive layer BML2, a first transistor TR1, a second transistor TR2, a first capacitor CAP1, a second capacitor CAP2, a first connection electrode CEa, a first insulating layer IL1, a second insulating layer IL2, a third insulating layer IL3, a fourth insulating layer IL4, a fifth insulating layer IL5, a sixth insulating layer IL6, a pixel defining layer PDL, a first connection pattern CNPa″, a first light-emitting element LEDa, a separator SPR, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include a first capacitor electrode CPE1 and a third capacitor electrode CPE3. The first light-emitting element LEDa may include a first electrode E1a′, an intermediate layer ML, and a second electrode E2a.

As described above, the first transistor TR1, the second transistor TR2, the first capacitor CAP1, and the second capacitor CAP2 may be components included in the first pixel driving circuit portion PCa.

The substrate SUB may be a base of the display device DD. In one or more embodiments, examples of materials that may be used as the substrate SUB may include glass, quartz, silicon, polymer, and/or the like. These materials may be used alone or in combination with each other. In addition, the substrate SUB may have a single layer structure or a multilayer structure in which a plurality of layers including different materials are stacked.

The first lower conductive layer BML1, the second lower conductive layer BML2, and the third capacitor electrode CPE3 may be located on the substrate SUB. Each of the first lower conductive layer BML1, the second lower conductive layer BML2, and the third capacitor electrode CPE3 may include a conductive material such as a metal, an alloy, a conductive metal oxide, a conductive metal nitride, a transparent conductive oxide, and/or the like. These materials may be used alone or in combination with each other.

The first insulating layer IL1 may be located on the substrate SUB while covering the first lower conductive layer BML1, the second lower conductive layer BML2, and the third capacitor electrode CPE3. The first insulating layer IL1 may prevent metal atoms or impurities from being diffused from the substrate SUB into the first active pattern AP1 and/or the second active pattern AP2. The first insulating layer IL1 may include an insulating material. Examples of the insulating material that may be used as the first insulating layer IL1 may include silicon oxide, silicon nitride, and/or the like. These materials may be used alone or in combination with each other.

The first active pattern AP1 may be located on the first insulating layer IL1. In one or more embodiments, the first active pattern AP1 may overlap the first lower conductive layer BML1 in a plan view and/or in a cross sectional view (e.g., in the third direction DR3). The first active pattern AP1 may include an oxide semiconductor material, a silicon semiconductor material, and/or an organic semiconductor material. The first active pattern AP1 may include a first contact area S1, a second contact area D1, and a first channel area CH1 between the first contact area S1 and the second contact area D1. The first contact area S1 and the second contact area D1 may have higher conductivity than the first channel area CH1.

The second active pattern AP2 may be located on the first insulating layer IL1. In one or more embodiments, the second active pattern AP2 may overlap the second lower conductive layer BML2 in a plan view and/or in a cross sectional view (e.g., in the third direction DR3). The second active pattern AP2 may include an oxide semiconductor material, a silicon semiconductor material, and/or an organic semiconductor material. The second active pattern AP2 may include a third contact area S2, a fourth contact area D2, and a second channel area CH2 between the third contact area S2 and the fourth contact area D2. The third contact area S2 and the fourth contact area D2 may have higher conductivity than the second channel area CH2.

In one or more embodiments, each of the first active pattern AP1 and the second active pattern AP2 may include a silicon semiconductor material. However, the present disclosure is not limited thereto, and in one or more other embodiments, each of the first active pattern AP1 and the second active pattern AP2 may include an oxide semiconductor material. Examples of the oxide semiconductor material that may be used as the active pattern AP may include indium gallium zinc oxide (“IGZO”), zinc tin oxide (“ZTO”), indium tin zinc oxide (“ITZO”), and/or the like. These materials may be used alone or in combination with each other. However, the present disclosure is not necessarily limited thereto, and the first active pattern AP1 and the second active pattern AP2 may include different materials. For example, one of the first active pattern AP1 and the second active pattern AP2 may include an oxide semiconductor material, and other may include a silicon semiconductor material.

FIG. 19 may illustrate that the first active pattern AP1 and the second active pattern AP2 are located in (e.g., at) a same layer. However, the present disclosure is not necessarily limited thereto, and the first active pattern AP1 and the second active pattern AP2 may be located in different layers.

The second insulating layer IL2 may be located on the first insulating layer IL1 while covering the first active pattern AP1 and the second active pattern AP2. The second insulating layer IL2may include an insulating material. Examples of the insulating material that may be used as the second insulating layer IL2 may include silicon oxide, silicon nitride, silicon nitride oxide, and/or the like. These materials may be used alone or in combination with each other.

The first gate electrode GE1 may be located on the second insulating layer IL2. The first gate electrode GE1 may overlap the first channel area CH1 of the first active pattern AP1 in a plan view and/or in a cross sectional view (e.g., in the third direction DR3). The first gate electrode GE1 may include a conductive material such as a metal, an alloy, a conductive metal oxide, a conductive metal nitride, transparent conductive oxide, and/or the like. These materials may be used alone or in combination with each other. In one or more embodiments, the first gate electrode GE1 may contact the first lower conductive layer BML1.

The second gate electrode GE2 may be located on the second insulating layer IL2. The second gate electrode GE2 may overlap the second channel area CH2 of the second active pattern AP2 in a plan view and/or in a cross sectional view (e.g., in the third direction DR3). The second gate electrode GE2 may include a conductive material such as a metal, an alloy, a conductive metal oxide, a conductive metal nitride, a transparent conductive oxide, and/or the like. These materials may be used alone or in combination with each other. In one or more embodiments, the second gate electrode GE2 may contact the second lower conductive layer BML2.

The first capacitor electrode CPE1 may be located on the second insulating layer IL2. The first capacitor electrode CPE1 may overlap the third capacitor electrode CPE3 in a plan view and/or in a cross sectional view (e.g., in the third direction DR3). The first capacitor electrode CPE1 and the third capacitor electrode CPE3 may constitute the second capacitor CAP2. The first capacitor electrode CPE1 may include a conductive material such as a metal, an alloy, a conductive metal oxide, a conductive metal nitride, a transparent conductive oxide, and/or the like. These materials may be used alone or in combination with each other.

The third insulating layer IL3 may be located on the second insulating layer IL2 while covering the first gate electrode GE1, the second gate electrode GE2, and the first capacitor electrode CPE1. The third insulating layer IL3 may include an insulating material. Examples of the insulating material that may be used as the third insulating layer IL3 may include silicon oxide, silicon nitride, silicon nitride oxide, and/or the like. These materials may be used alone or in combination with each other.

The second capacitor electrode CPE2 may be located on the third insulating layer IL3. The second capacitor electrode CPE2 may overlap the first capacitor electrode CPE1 in a plan view and/or in a cross sectional view (e.g., in the third direction DR3). The first capacitor electrode CPE1 and the second capacitor electrode CPE2 may constitute the first capacitor CAP1. The second capacitor electrode CPE2 may include a conductive material such as a metal, an alloy, a conductive metal oxide, a conductive metal nitride, a transparent conductive oxide, and/or the like. These materials may be used alone or in combination with each other.

The fourth insulating layer IL4 may be located on the third insulating layer IL3 while covering the second capacitor electrode CPE2. The fourth insulating layer IL4 may include an insulating material. Examples of the insulating material that may be used as the fourth insulating layer IL4 may include silicon oxide, silicon nitride, silicon nitride oxide, and/or the like. These materials may be used alone or in combination with each other.

The first contact electrode SE1, the second contact electrode DE1, the third contact electrode SE2 and the fourth contact electrode DE2 may be located on the fourth insulation layer IL4. The first contact electrode SE1 may contact the first contact area S1 of the first active pattern AP1, the second contact electrode DE1 may contact the second contact area D1 of the first active pattern AP1, the third contact electrode SE2 may contact the third contact area S2 of the second active pattern AP2, and the fourth contact electrode DE2 may contact the fourth contact area D2 of the second active pattern AP2. Each of the first contact electrode SE1, the second contact electrode DE1, the third contact electrode SE2 and the fourth contact electrode DE2 may include a conductive material such as a metal, an alloy, a conductive metal oxide, a conductive metal nitride, a transparent conductive oxide, and/or the like. These materials may be used alone or in combination with each other.

In one or more embodiments, the first contact electrode SE1 may contact the first lower conductive layer BML1, and the third contact electrode SE2 may contact the second lower conductive layer BML2. However, the present disclosure is not necessarily limited thereto. For example, when the first gate electrode GE1 contacts the first lower conductive layer BML1, the first contact electrode SE1 may not contact the first lower conductive layer BML1. In addition, when the second gate electrode GE2 contacts the second lower conductive layer BML2, the third contact electrode SE2 may not contact the second lower conductive layer BML2.

The fifth insulation layer IL5 may be located on the fourth insulation layer IL4 while covering the first contact electrode SE1, the second contact electrode DE1, the third contact electrode SE2 and the fourth contact electrode DE2. For example, the fifth insulating layer IL5 may include an organic insulating material. Examples of the organic insulating material that may be used as the fifth insulating layer IL5 may include a photoresist, a polyacryl-based resin, a polyimide-based resin, a polyamide-based resin, a siloxane-based resin, an acrylic-based resin, an epoxy-based resin, and/or the like. These materials may be used alone or in combination with each other.

The first connection electrode CEa may be located on the fifth insulation layer IL5. As described above, the first connection electrode CEa may be connected to the first transistor TR1. For example, the first connection electrode CEa may contact the first transistor TR1 through a contact hole CNT penetrating (or, defining through) the fifth insulation layer IL5. Accordingly, position of the first circuit connection portion CPa may correspond to position of the contact hole CNT. In one or more embodiments, the first connection electrode CEa may have a single layer structure or a multilayer structure in which a plurality of conductive layers are stacked.

The first power voltage line HVL1′ may be located on the fifth insulating layer IL5. The first power voltage line HVL1′ may apply a first power voltage to the first electrode E1a′ of the first light-emitting element LEDa. In one or more embodiments, the first power voltage line HVL1′ may include a conductive material such as a metal, an alloy, a conductive metal oxide, a conductive metal nitride, a transparent conductive oxide, and/or the like. These materials may be used alone or in combination with each other.

As described above, the first transistor TR1 may be a transistor connected to a light-emitting element through a connection electrode and a connection pattern. For example, when the first pixel driving circuit portion PCa is the pixel driving circuit portion PC″ of FIG. 2C, the first transistor TR1 may be the fifth transistor T5 of FIG. 2C.

The sixth insulating layer IL6 may be located on the fifth insulating layer IL5 while partially covering the first connection electrode CEa and the first power voltage line HVL1′. For example, the sixth insulating layer IL6 may define a first sub-opening SO1 exposing at least a portion of the first connection electrode CEa. The sixth insulating layer IL6 may include an insulating material. For example, the sixth insulating layer IL6 may include an organic insulating material. Examples of the organic insulating material that may be used as the sixth insulating layer IL6 may include a photoresist, a polyacryl-based resin, a polyimide-based resin, a polyamide-based resin, a siloxane-based resin, an acrylic-based resin, an epoxy-based resin, and/or the like. These materials may be used alone or in combination with each other.

The first electrode E1a′ may be located on the sixth insulating layer IL6. The first electrode E1a′ may be connected to the first power voltage line HVL1′ through the first contact hole CNT1. The first electrode E1a′ may include a conductive material such as a metal, an alloy, a conductive metal oxide, a conductive metal nitride, a transparent conductive oxide, and/or the like. These materials may be used alone or in combination with each other.

The pixel defining layer PDL may be located on the sixth insulating layer IL6 and the first electrode E1a′ of the first light-emitting element LEDa. For example, the pixel defining layer PDL may include an insulating material. The pixel defining layer PDL may define a pixel opening exposing at least a portion of the first electrode E1a′. A first light-emitting area EAa may be defined by the pixel opening. The pixel defining layer PDL may further define a second sub-opening SO2 corresponding to the first sub-opening SO1 of the sixth insulating layer IL6. The second sub-opening SO2 may overlap the first sub-opening SO1 in a plan view and/or in a cross sectional view, and the first sub-opening SO1 and the second sub-opening SO2 may be spatially connected to each other. For example, an opening OP′ may be defined by the first sub-opening SO1 and the second sub-opening SO2, and the opening OP′ may expose at least a portion of the first connection electrode CEa.

The first connection pattern CNPa″ may be located on the first connection electrode CEa, the sixth insulating layer IL6, and the pixel defining layer PDL. As described above, the first connection pattern CNPa″ may be connected to the first connection electrode CEa. For example, the first connection pattern CNPa″ may contact the first connection electrode CEa through the opening OP′ penetrating (or, defining through) the sixth insulating layer IL6 and the pixel defining layer PDL. Accordingly, position of the first light-emitting connection portion CNa may correspond to position of the opening OP′. In one or more embodiments, the first connection pattern CNPa″ may have a single layer structure or a multilayer structure in which a plurality of conductive layers are stacked.

The separator SPR may be located on the pixel defining layer PDL and the first connection pattern CNPa″. The separator SPR may overlap the first connection pattern CNPa″ in a plan view and/or in a cross sectional view. For example, the separator SPR may cover a portion of the first connection pattern CNPa″.

The separator SPR may have a shape in which an upper portion width is greater than a lower portion width. For example, a side surface of the separator SPR connecting an upper surface of the separator SPR and a lower surface of the separator SPR may have an inverted tapered inclined surface. For example, a cross section of at least one portion of the separator SPR may be an inverted trapezoid.

In one or more embodiments, as illustrated in FIG. 19, a side surface of the separator SPR may have a plurality of inverted tapered inclined surfaces. For example, the separator SPR may have a double inverted tapered structure. Accordingly, separation (or disconnection) of the second electrode E2a of the first light-emitting element LEDa by the separator SPR may be more easily implemented.

The intermediate layer ML may be located on the first electrode E1a′, the pixel defining layer PDL, and the first connection pattern CNPa″. A portion of the intermediate layer ML may be located in the pixel opening of the pixel defining layer PDL. In one or more embodiments, the intermediate layer ML may include a first functional layer including an organic material, a light-emitting layer including a light-emitting material, and a second functional layer including an organic material located on the light-emitting layer. For example, the first functional layer may include a hole injection layer, a hole transport layer, and/or the like, and the second functional layer may include an electron transport layer, an electron injection layer, and/or the like.

A shadow area in which the intermediate layer ML is difficult to be deposited may exist around the separator SPR having the inverted tapered inclined surface. Accordingly, around the shadow area and/or in the shadow area, the intermediate layer ML may have a structure that is separated (or disconnected) by the separator SPR. For example, the first functional layer and the second functional layer included in the intermediate layer ML may have a structure that is separated (or disconnected) by the separator SPR. As the intermediate layer ML has a structure that is separated (or disconnected), the intermediate layer ML may not entirely cover the first connection pattern CNPa″. For example, the intermediate layer ML may expose a portion of the first connection pattern CNPa″ at a position adjacent to or overlapping the separator SPR in a plan view. Accordingly, the second electrode E2a of the first light-emitting element LEDa may contact the first connection pattern CNPa″.

The first dummy layer DP1 may be located on the separator SPR. The first dummy layer DP1 may be formed as the intermediate layer ML has a structure in which the intermediate layer ML is separated (or disconnected) by the separator SPR. For example, the first dummy layer DP1 may be formed in a same process as the intermediate layer ML. In one or more embodiments, the first dummy layer DP1 may be omitted.

The second electrode E2a of the first light-emitting element LEDa may be located on the intermediate layer ML. For example, the second electrode E2a of the first light-emitting element LEDa may include a conductive material such as a metal, an alloy, a conductive metal oxide, a conductive metal nitride, a transparent conductive oxide, and/or the like. These materials may be used alone or in combination with each other. In one or more embodiments, the second electrode E2a of the first light-emitting element LEDa may have a single layer structure. However, the present disclosure is not necessarily limited thereto, and the second electrode E2a of the first light-emitting element LEDa may have a multi-layer structure in which a plurality of conductive layers are stacked. For example, the second electrode E2a of the first light-emitting element LEDa may have a two-layer structure in which a first sub-electrode layer including a metal and a second sub-electrode layer including a transparent conductive oxide are stacked.

A shadow area where the second electrode E2a of the first light-emitting element LEDa is difficult to be deposited may exist around the separator SPR having the inverted tapered inclined surface. Accordingly, the second electrode E2a of the first light-emitting element LEDa may have a structure separated (or disconnected) by the separator SPR in the shadow area and/or around the shadow area. For example, as illustrated in FIG. 18, the second electrode layer E2 may be separated (or disconnected) into the second electrode E2a of the first light-emitting element LEDa located in the first open area OA1 of the separator SPR, the second electrode E2b of the second light-emitting element LEDb located in the second open area OA2 of the separator SPR, and the second electrode E2c of the third light-emitting element LEDc located in the third open area OA3 of the separator SPR. For example, the second electrodes E2a, E2b, and E2c may be electrically independent from each other.

As illustrated in FIG. 19, the second electrode E2a of the first light-emitting element LEDa may be connected to the first connection pattern CNPa″. For example, the second electrode E2a of the first light-emitting element LEDa may contact the first connection pattern CNPa″ at a position adjacent to or overlapping the separator SPR in the plan view. For example, when deposition angle of deposition process of forming the second electrode E2a of the first light-emitting element LEDa is greater than deposition angle of deposition process of forming the intermediate layer ML, the second electrode E2a of the first light-emitting element LEDa may be formed to contact the first connection pattern CNPa″ while covering disconnected side portion of the intermediate layer ML. As a result, the second electrode E2a of the first light-emitting element LEDa may be connected to the first transistor TR1 through the first connection pattern CNPa″ and the first connection electrode CEa.

The second dummy layer DP2 may be located on the separator SPR. For example, the second dummy layer DP2 may be located on the first dummy layer DP1. The second dummy layer DP2 may be formed as the second electrode E2a of the first light-emitting element LEDa has a structure in which the second electrode E2a of the first light-emitting element LEDa is separated (or disconnected) by the separator SPR. For example, the second dummy layer DP2 may be formed in a same process as the second electrode E2a of the first light-emitting element LEDa. In one or more embodiments, the second dummy layer DP2 may be omitted.

The encapsulation layer ENC may be located on the second electrode E2a of the first light-emitting element LEDa. The encapsulation layer ENC may entirely cover the second electrode E2a of the first light-emitting element LEDa, the first connection pattern CNPa″, the separator SPR, the first dummy layer DP1, and the second dummy layer DP2. In one or more embodiments, the encapsulation layer ENC may include a first inorganic encapsulation layer IEL1 including an inorganic insulating material, an organic encapsulation layer OEL located on the first inorganic encapsulation layer IEL1 and including an organic insulating material, and a second inorganic encapsulation layer IEL2 located on the organic encapsulation layer OEL including an inorganic insulating material.

Although not illustrated in FIG. 19, in one or more embodiments, a touch sensing layer may be located on the encapsulation layer ENC. For example, the touch sensing layer may include a plurality of touch electrode arrays for sensing a user's input in a capacitive manner, a touch pad portion, and a plurality of touch wires electrically connecting the touch pad portion to the touch electrode arrays. However, the present disclosure is not necessarily limited thereto. In one or more embodiments, the touch sensing layer may be omitted.

According to one or more embodiments of the present disclosure, the display device DD may include the connection electrodes CEa, CEb, and CEc, the connection patterns CNPa″, CNPb″, and CNPc″, and the separator SPR. Accordingly, the second electrode E2a located on the first electrode E1a′ (e.g., the anode) may be easily connected to the pixel driving circuit portions PCa, PCb, and PCc. The second electrode E2a located on the first electrode E1a′ may be connected to a drain electrode of the driving transistor (e.g., the first transistor T1 of FIG. 2C) of each of the pixel driving circuit portions PCa, PCb, and PCc through the connection electrodes CEa, CEb, and CEc and the connection patterns CNPa″, CNPb″, CNPc″. Accordingly, the gate-source voltage “V_{gs}” of the driving transistor may not be changed even when the light-emitting element is deteriorated. Therefore, a variation width of the driving current by deterioration of the light-emitting element may be reduced. Therefore, afterimage defects of the display device DD due to an increase in usage time may be reduced, and life of the display device DD may be improved.

The display device (e.g., the display device DD of FIG. 1A and the display device DDa of FIG. 1B) according to one or more embodiments may be applied to various electronic devices. An electronic device according to one or more embodiments may include the above-described display device, and may further include a module or device having other additional functions in addition to the display device.

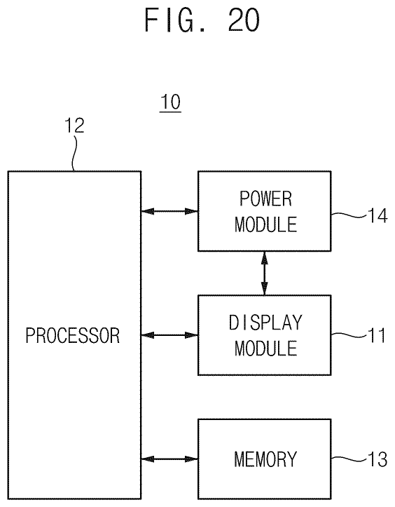

FIG. 20 is a block diagram illustrating an electronic device according to one or more embodiments.

Referring to FIG. 20, an electronic device 10 according to one or more embodiments may include a display module 11, a processor 12, a memory 13, and a power module 14.

The processor 12 may include a central processing unit (“CPU”), an application processor (“AP”), a graphic processing unit (“GPU”), a communication processor (“CP”), an image signal processor (“ISP”), and/or a controller.

Data information necessary for operation of the processor 12 or the display module 11 may be stored in the memory 13. When the processor 12 executes an application stored in the memory 13, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

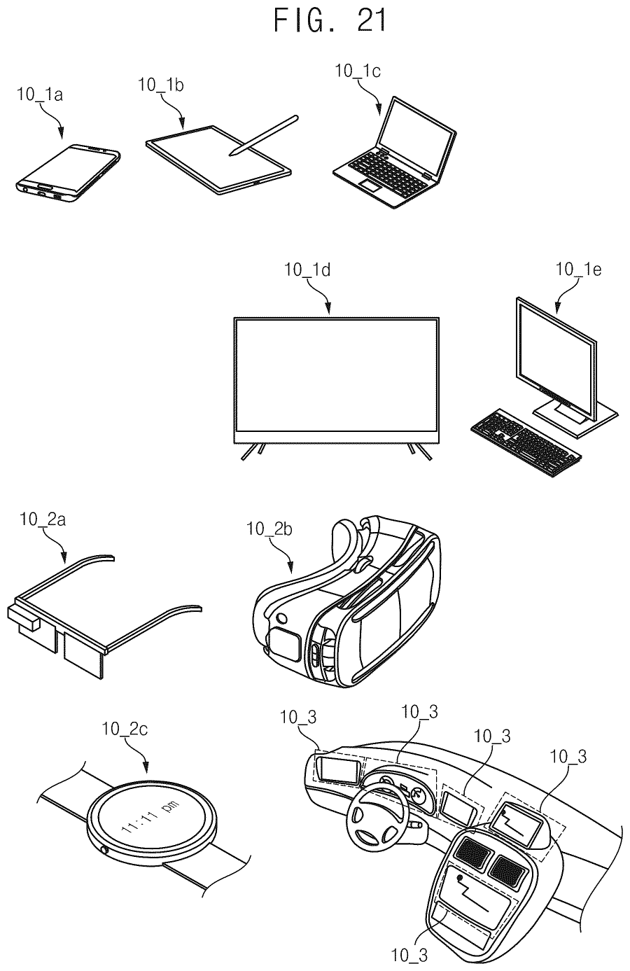

FIG. 21 is a schematic diagram of an electronic device according to one or more embodiments.

Referring to FIG. 21, various electronic devices to which display devices according to one or more embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) disposed on a dashboard, a room mirror display, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and scope of the present disclosure. Accordingly, all such modifications are intended to be included within the scope of the present disclosure as defined in the claims and their equivalents. Therefore, it is to be understood that the foregoing is illustrative of various embodiments and is not to be construed as limited to the specific embodiments disclosed, and that modifications to the embodiments, as well as other embodiments, are intended to be included within the scope of the appended claims and their equivalents.

What is claimed is:

1. A display device, including a first light-emitting area and a second light-emitting area spaced from the first light-emitting area in a plan view, wherein the second light-emitting area is configured to emit light of a different color from the first light-emitting area, the display device comprising:
a substrate;
a first light-emitting element located in the first light-emitting area on the substrate, wherein the first light-emitting element comprises a first electrode, an intermediate layer located on the first electrode of the first light-emitting element, and a second electrode located on the intermediate layer of the first light-emitting element;
a second light-emitting element located in the second light-emitting area on the substrate, wherein the second light-emitting element comprises a first electrode, an intermediate layer located on the first electrode of the second light-emitting element, and a second electrode located on the intermediate layer of the second light-emitting element;
a first power voltage line configured to apply a first power voltage to the second electrode of the first light-emitting element; and
a second power voltage line configured to apply a second power voltage to the second electrode of the second light-emitting element, wherein the second power voltage line is spaced from the first power voltage line in a plan view.

2. The display device of claim 1, wherein a voltage level of the first power voltage and a voltage level of the second power voltage are different from each other.

3. The display device of claim 1, further comprising:
a connection pattern spaced from the first light-emitting area in a plan view,
wherein the second electrode of the first light-emitting element is electrically connected to the first power voltage line through the connection pattern.

4. The display device of claim 3, wherein the connection pattern is around at least a portion of the first light-emitting area in a plan view.

5. The display device of claim 1, wherein the display device further includes a third light-emitting area spaced from each of the first light-emitting area and the second light-emitting area in a plan view and configured to emit light of a different color from each of the first light-emitting area and the second light-emitting area, and
wherein the display device further comprises:
a third light-emitting element located in the third light-emitting area on the substrate and comprising a first electrode, an intermediate layer located on the first electrode of the third light-emitting element, and a second electrode located on the intermediate layer of the third light-emitting element.

6. The display device of claim 5, wherein the first power voltage line is configured to apply the first power voltage to the second electrode of the third light-emitting element.

7. The display device of claim 5, further comprising:
a third power voltage line configured to apply a third power voltage to the second electrode of the third light-emitting element and is spaced from each of the first power voltage line and the second power voltage line in a plan view.

8. The display device of claim 7, wherein a voltage level of the first power voltage and a voltage level of the second power voltage are different from each other, and
wherein the voltage level of the second power voltage and a voltage level of the third power voltage are different from each other.

9. The display device of claim 1, further comprising:
a separator separating the second electrode of the first light-emitting element and the second electrode of the second light-emitting element from each other.

10. The display device of claim 9, wherein the separator is around each of the second electrode of the first light-emitting element and the second electrode of the second light-emitting element in a plan view.

11. The display device of claim 1, further comprising:
a pixel defining layer located on the substrate and covering a side portion of the first electrode of the first light-emitting element,
wherein the pixel defining layer defines an opening that is spaced from the first light-emitting area in a plan view.

12. The display device of claim 11, wherein the second electrode of the first light-emitting element and the second electrode of the second light-emitting element are separated from each other by the opening of the pixel defining layer.

13. The display device of claim 11, wherein, in a cross-sectional view, the first power voltage line comprises:
a first conductive layer;
a second conductive layer located on the first conductive layer; and
a third conductive layer located on the second conductive layer.

14. The display device of claim 13, wherein the second electrode of the first light-emitting element contacts the second conductive layer.

15. A display device, including a first light-emitting area and a second light-emitting area spaced from the first light-emitting area in a plan view, wherein the second light-emitting area is configured to emit light of a different color from the first light-emitting area, the display device comprising:
a substrate;
a first light-emitting element located in the first light-emitting area on the substrate, wherein the first light-emitting element comprises a first electrode, an intermediate layer located on the first electrode of the first light-emitting element, and a second electrode located on the intermediate layer of the first light-emitting element;
a second light-emitting element located in the second light-emitting area on the substrate, wherein the second light-emitting element comprises a first electrode, an intermediate layer located on the first electrode of the second light-emitting element, and a second electrode located on the intermediate layer of the second light-emitting element;
a first power voltage line configured to apply a first power voltage to the first electrode of the first light-emitting element; and
a second power voltage line configured to apply a second power voltage to the first electrode of the second light-emitting element, wherein the second power voltage line is spaced from the first power voltage line in a plan view.

16. The display device of claim 15, wherein a voltage level of the first power voltage and a voltage level of the second power voltage are different from each other.

17. The display device of claim 15, wherein the display device further includes a third light-emitting area spaced from each of the first light-emitting area and the second light-emitting area in a plan view and configured to emit light of a different color from each of the first light-emitting area and the second light-emitting area, and
wherein the display device further comprises:
a third light-emitting element located in the third light-emitting area on the substrate and comprising a first electrode, an intermediate layer located on the first electrode of the third light-emitting element, and a second electrode located on the intermediate layer of the third light-emitting element; and
a third power voltage line configured to apply a third power voltage to the first electrode of the third light-emitting element and is spaced from each of the first power voltage line and the second power voltage line in a plan view.

18. The display device of claim 15, further comprising:
a transistor located on the substrate and electrically connected to the second electrode of the first light emitting element.

19. The display device of claim 18, wherein a voltage level of the first power voltage and a voltage level of the second power voltage are different from each other.

20. An electronic device, including a first light-emitting area and a second light-emitting area spaced from the first light-emitting area in a plan view, wherein the second light-emitting area is configured to emit light of a different color from the first light-emitting area, the electronic device comprising:
a substrate;
a first light-emitting element located in the first light-emitting area on the substrate, wherein the first light-emitting element comprises a first electrode, an intermediate layer located on the first electrode of the first light-emitting element, and a second electrode located on the intermediate layer of the first light-emitting element;
a second light-emitting element located in the second light-emitting area on the substrate, wherein the second light-emitting element comprises a first electrode, an intermediate layer located on the first electrode of the second light-emitting element, and a second electrode located on the intermediate layer of the second light-emitting element;
a first power voltage line configured to apply a first power voltage to the second electrode of the first light-emitting element;
a second power voltage line configured to apply a second power voltage to the second electrode of the second light-emitting element, wherein the second power voltage line is spaced from the first power voltage line in a plan view; and
a memory configured to store data information.
